(19) United States
(12) Patent Application Publication
(10) Pub. No.: US 2026/0262354 A1
(43) Pub. Date: Sep. 3, 2026

(54) DISPLAY DEVICE, LED MODULE AND MANUFACTURING METHOD THEREOF

(71) Applicant: Century Technology (ShenZhen) Corp.,_LTD, Shen-zhen (CN)

(72) Inventors: Kuang-Hua LIU, Shen-zhen (CN); Deng-Kai CHANG, Shen-zhen (CN); Feng-Hsiang LIU, Shen-zhen (CN); Chi-Min HUANG, Shen-zhen (CN); An-Chou CHEN, Shen-zhen (CN); Wei-Chih CHANG, Shen-zhen (CN); Hsixg-Ju SUNG, Shen-zhen (CN); Chen-Fu MAI, Shen-zhen (CN); Ping LIU, Shen-zhen (CN); Meng-Chieh TAI, Shen-zhen (CN); Yi-Chou CHEN, Shen-zhen (CN); Jie XIAO, Shen-zhen (CN); Ze-Yuan LI, Shen-zhen (CN); Jun-Wen LIU, Shen-zhen (CN); Chan-Kuan HUANG, Shen-zhen (CN); Tuan-Fei GU, Shen-zhen (CN); Tai-Hsing LEE, Shen-zhen (CN); Rui LI, Shen-zhen (CN); Hui WANG, Shen-zhen (CN); Yuan XIONG, Shen-zhen (CN); Chun-Guang PANG, Shen-zhen (CN); Chih-Chung LIU, Shen-zhen (CN); Zan-Biao YANG, Shen-zhen (CN); Wen-Lin CHEN, Shen-zhen (CN)

(21) Appl. No.: 19/165,201

(22) PCT Filed: Mar. 15, 2024
(86) PCT No.: PCT/CN2024/081950

§ 371 Date: Sep. 15, 2025

(30) Foreign Application Priority Data
Mar. 21, 2023 (CN) 202310304110.6
Apr. 20, 2023 (CN) 202310438559.1
Apr. 20, 2023 (CN) 202310438563.8
Apr. 20, 2023 (CN) 202310462257.8
Apr. 24, 2023 (CN) 202310465784..4
Jun. 21, 2023 (CN) 202310751468.3
Jun. 26, 2023 (CN) 202310758460.X
Jan. 4, 2024 (CN) 202410011313.0
Jan. 4, 2024 (CN) 202410025059.X
Jan. 4, 2024 (CN) 202410027847.2
Jan. 19, 2024 (CN) 202410081001.7
Jan. 24, 2024 (CN) 202410102459.6
Jan. 24, 2024 (CN) 202410105952.3
Mar. 5, 2024 (CN) 202410252139..9
Mar. 5, 2024 (CN) 202410253958.5

(51) Int. Cl. H10H 29/49; H10H 29/01; H10H 29/853

(52) U.S. Cl. CPC H10H 29/49; H10H 29/0362; H10H 29/853

(57) ABSTRACT

A display device (10-70) is provided. The display device (10-70) comprises a display panel (100′), a scanning drive circuit (120′), and a data drive circuit (130′). The scanning unit (121a, 121_x) of the scanning drive circuit (120′) comprises a first module (MD1), a second module (MD2) and a third module (MD3). The first module (MD1) comprises a first transistor (M1) and a second transistor (M2), which have a first end, a second end, and a control end, respectively. The signal received by the first end of the first transistors (M1) changes in level at least once during each frame, and the signal received by the first end of the first transistors (M1) is maintained at a high level during periods when the signal received by the control end of the first transistors (M1) is at a high level.

### TECHNICAL FIELD

The present disclosure relates to the field of display technology, and particularly to a display device, an LED module and a manufacturing method thereof.

### BACKGROUND

In modern display technology, display devices play a crucial role. These devices are widely used in a variety of devices such as televisions, computer monitors, smartphones, and the like. The display panel is the core part of the display device and is responsible for generating the image visible to the user. Existing display panel technologies include liquid crystal display (LCD), organic light emitting diode (OLED), and quantum dot display (QLED) . . . etc. Among them, liquid crystal display technology relies on a backlight module to illuminate a display panel. The backlight module typically includes a light emitting diode (LED) as a light source, and a light guide plate to evenly distribute light. In addition, pixel arrays in the display panel are critical for generating high quality images. Each pixel contains red, green, and blue sub-pixels that work together to produce a colorful image. However, existing technologies often face challenges of energy efficiency and manufacturing cost while providing high resolution and high color accuracy.

In the manufacture and design of LEDs, the size of the LED varies depending on the field in which it is used, where large sized LEDs can be used in lighting or disinfection (e.g. UV LED), while small sized LEDs (e.g. mini-LED or micro-LED) can be used in the backlight module of a display or directly in a pixel as a display panel (e.g. self-luminous display panel such as OLED).

Even in the same application field, individual LED sizes may vary due to differences in technology and manufacturing processes. In addition, due to manufacturing process tolerances and material characteristics, it is also difficult to keep the environmental conditions of each LED completely consistent when it is set. Due to the above-mentioned differences, each LED generally has a height difference in the arrangement without being maintained at the same level, resulting in poor flatness of the LED module. The poor flatness problem further affects the yield and reliability of subsequent manufacturing processes.

In the backlight module design, the backlight module, whether direct-type or edge-type, basically consists of at least a light guide plate, a diffuser plate, and a reflector plate to direct and diffuse the light so that the light can be uniformly applied to each region of the display panel for better display.

The light guide plate, which is one of the key components backlight module, is typically made of a plastic material. However, the conventional light guide plate materials have various problems, and some of the major ones include poor optical performance, great processing difficulty, high manufacturing cost, heat resistance and stability considerations of the material itself. Further, since the backlight module must employ additional components such as a diffuser plate and a reflector plate to optimize the optical performance, these additional components increase the cost and manufacturing difficulty in the production process, and the assembly between the components may have reliability problems. On the other hand, if the backlight module employs a light guide plate made of a plastic material, it is also generally necessary to provide rigid support with a rigid stiffening plate attached to the light guide plate to prevent the light guide plate of the plastic material from bending due to the force and affecting the display effect, but the provision of a rigid stiffening plate as a structural stiffening may result in a significant increase in the cost of the backlight module.

On the other hand, the application of the quantum dot film in the backlight module is also very widespread, which can improve the brightness, color saturation, and contrast of the display screen. In currently common applications, the quantum dot film is typically fabricated using a sandwich structure, i.e., a layer of quantum dot material sandwiched between two separator films.

However, such a quantum dot film backlight module is easily affected by water and oxygen, so that the quantum dot film is liable to fail, and at the same time, there is an inability to meet reliability requirements such as a drastic change in temperature, so that it is difficult to apply in an on-board vehicle or other fields in which environmental changes are large. In general display applications, quantum dot film is also susceptible to water and oxygen, resulting in reduced life expectancy.

In the design of the display panel, a thin-film transistor (TFT) is a device used in the general display device as a switching element to control the operation of a pixel, in which a thin-film transistor can be roughly divided into two kinds of an amorphous silicon (a-Si) thin-film transistor and a poly-Si thin-film transistor according to the material composition of its active layer.

Amorphous silicon thin-film transistor has the advantage of low cost and relatively simple manufacturing process to be mainstream in the design of large size panels. In addition, amorphous silicon is more suitable for use in some portable devices because it can be manufactured at lower temperatures than polysilicon. However, current amorphous silicon thin-film transistor carrier has low mobility, typically only 0.2-0.5 cm²/V×S, and such component characteristics can lead to limitations on product applications.

On the other hand, packaging technology is a key link in the manufacture of display device, which affects the performance and reliability of the device. The main goal of packaging technology is to efficiently integrate the microelectronic components of the display screen onto the display panel. Among them, Chip on Glass (COG) packaging technology is a technology in which a drive circuit (i.e., a driver chip, or a driver IC) integrated in a display device is directly mounted onto a glass substrate so that the driving IC directly outputs a voltage or a signal required for a display module into each pixel. COG packaging technology is more sophisticated, cost effective, and easily adjustable, but relatively because of the need to dispose the driver IC on a glass substrate, limitations in IC size, routing requirements, and the like can make it difficult to achieve a narrow bezel design in a display device employing a COG package.

In COG packaging technology, the integrated design of a scan driver on a glass substrate may be referred to as Gate Driver on Panel (GOP) driving. In a design employing GOP driving, a scanning drive circuit (or gate drive circuit) is a circuit fabricated by the same manufacturing process as a thin-film transistor (TFT) in a pixel array on the basis that an external circuit provides only a few timing control signals, which can save an integrated circuit related to scan driving, and can achieve a reduction in the manufacturing cost of a liquid crystal display. In addition, since the GOP drive design requires less timing control signals to operate, the space requirements for signal routing of external circuitry can be optimized, resulting in increased effective display region.

As technology evolves, Chip on Film (COF) packaging technology emerges, which can directly package a driver IC on a flexible circuit board and bend the configuration on the back of a display panel. Since there is no need to dispose the driver IC on the glass substrate, the bezel region can be effectively reduced, so that the need for a narrow bezel is more easily met. However, while COF packaging technology can reduce the size of the bezel, it has a high technical threshold, relatively high manufacturing cost, and can also have limited throughput. Both of these techniques have limitations in achieving narrow frame designs, making it difficult to compromise cost and effectiveness.

In addition, in the existing scanning drive circuit design, no matter what kind of driving method is used, there is no way to avoid the need to maintain the driving of the circuit with a DC voltage. However, when a DC voltage is applied to a transistor in a circuit for a long time, it is easy to cause a shift in the characteristics of the transistor, so that a leakage current gradually increases. Over time, the display is abnormal, resulting in a limited lifetime of the display panel.

On the other hand, in the ULED/Mini-LED display panel, the ULED/Mini-LED display panel is difficult to make a single large-sized screen due to inherent limitations such as production yield, production cost, and color shift, so the spliced ULED/Mini-LED display is widely used to solve the problem of large-sized screen design. By the application of the spliced display, it is possible not only to drastically reduce the production cost of the large-sized screen, but also to satisfy the application requirements of maximizing the size. In addition, spliced displays can provide better brightness, color saturation, and contrast, as well as better freedom in size and specification selectivity.

However, a major problem with spliced displays is that the seam at the display panel splice is easily observed, causing the image to be cut by the black lines of the splicing seam, affecting the viewing experience.

### SUMMARY

An object of the present disclosure is to provide a display device, an LED module and a manufacturing method thereof, which can ensure surface flatness of the LED module.

An object of the present disclosure is to provide a quantum dot film and a display and a backlight module applying the same, which can avoid the problem of deterioration of the lifetime of the device due to the susceptibility to water oxygen.

An object of the present disclosure is to provide a thin-film transistor, a pixel array substrate, a display device and a manufacturing method thereof, which have good element characteristics, thereby improving display effect and lifetime of products.

An object of the present disclosure is to provide a display device and a drive circuit thereof for solving the problems mentioned in the background art, such as solving the design problem of a narrow bezel and/or the service life problem of a display device in the display panel of a COG package and a GOP package.

An object of the present disclosure is to provide a light guide plate and a backlight module thereof, which can achieve an optimized efficiency between display effect/light source conversion efficiency and structural protection, effectively simplify a manufacturing process of a light guide plate and reduce manufacturing cost and cycle, and reduce cost and expense of maintenance.

An object of the present disclosure is to provide a spliced display panel, a display, and a method of manufacturing the same, which can eliminate the visual impact of the tiling seam without visible tiling streaks or optical chromatic aberrations.

An embodiment of the present disclosure proposes a manufacturing method of an LED module, including the steps of: forming a first line layer on a substrate; disposing a plurality of light-emitting elements over the first line layer by an adhering part so that a first electrode of each light-emitting element is electrically connected to the first line layer; forming a protective layer on the substrate to cover the plurality of light-emitting elements, wherein a thickness of the protective layer is greater than or equal to a height of the plurality of light-emitting elements; removing the protective layer covering the second electrode of each of the light-emitting elements to form an opening between each of the plurality of light-emitting elements and the protective layer; and forming a second line layer over the protective layer, wherein the second line layer is electrically connected to the second electrode of each of the light-emitting elements through the opening.

An embodiment of the present disclosure proposes a manufacturing method of an LED module, including the steps of: forming a first line layer on a substrate; disposing a plurality of light-emitting elements over the first line layer by an adhering part so that a first electrode of each light-emitting element is electrically connected to the first line layer; applying a force to the plurality of light-emitting elements toward the substrate to embed at least a portion of the light-emitting element in the adhering part; filling an insulating material to gaps between the light-emitting elements to form a protective layer; and forming a second line layer over the protective layer so that the second electrode of each light-emitting element is electrically connected to the second line layer.

An embodiment of the present disclosure proposes a quantum dot film, including an active layer, a support layer, a bonding layer, and a waterproof layer. The active layer includes a plurality of quantum dots and is configured to excite light having a second wavelength based on the received light at the first wavelength. The support layer is used to carry the active layer. The bonding layer is disposed between the active layer and the support layer for providing a bonding force between the active layer and the support layer such that the active layer is disposed on the support layer through the bonding layer. The waterproof layer directly or indirectly covers at least part of the surface of the active layer. An embodiment of the present disclosure provides a thin-film transistor including a gate, an insulating layer, an active layer, a source, and a drain. The insulating layer is formed on the gate. The active layer is formed on the insulating layer. The source is formed on one of two ends of the active layer. The drain is formed on the other of two ends of the active layer. The active layer includes a first semiconductor material layer, a second semiconductor material layer, and a third semiconductor material layer in a sequentially stacked arrangement. The first semiconductor material layer is formed on the insulating layer and has an ordered lattice structure; the second semiconductor material layer is formed on the first semiconductor material layer and has a disordered lattice structure; and the third semiconductor material layer is formed on the two sides of the second semiconductor material layer, has a disordered lattice structure and is doped with N-type ions. A semiconductor oxide is substantially absent at an interface between the first semiconductor material layer and the second semiconductor material layer.

An embodiment of the present disclosure provides a thin-film transistor including a gate, an insulating layer, an active layer, a source, and a drain. The insulating layer is formed on the gate. The active layer is formed on the insulating layer. The source is formed on one of two ends of the active layer. The drain is formed on the other of two ends of the active layer. The active layer includes a first semiconductor material layer, a second semiconductor material layer, and a third semiconductor material layer in a sequentially stacked arrangement. The first semiconductor material layer is formed on the insulating layer and has an ordered lattice structure; the second semiconductor material layer is formed on the first semiconductor material layer and has a disordered lattice structure; and the third semiconductor material layer is formed on the two sides of the second semiconductor material layer, has a disordered lattice structure and is doped with N-type ions. The first semiconductor material layer is doped with Group 3A ions.

An embodiment of the present disclosure provides a thin-film transistor including a gate, an insulating layer, an active layer, a source, and a drain. The insulating layer is formed on the gate. The active layer is formed on the insulating layer. The source is formed on one of two ends of the active layer. The drain is formed on the other of two ends of the active layer. The active layer includes a first semiconductor material layer, a second semiconductor material layer, and a third semiconductor material layer in a sequentially stacked arrangement. The first semiconductor material layer is formed on the insulating layer and has an ordered lattice structure; the second semiconductor material layer is formed on the first semiconductor material layer and has a disordered lattice structure; and the third semiconductor material layer is formed on the two sides of the second semiconductor material layer, has a disordered lattice structure and is doped with N-type ions. A thickness ratio of the second semiconductor material layer to the third semiconductor material layer is between 5:8 and 8:5.

An embodiment of the present disclosure proposes a manufacturing method of a thin-film transistor, including the steps of: forming a first metal layer and an insulating layer covering the first metal layer on a substrate; forming an amorphous semiconductor thin film on the insulating layer; carrying out a thermal treatment on the amorphous semiconductor thin film to convert the amorphous semiconductor thin film into a first semiconductor material layer; forming second and third semiconductor material layers on the first semiconductor material layer to constitute an active layer, wherein a thickness ratio of the second semiconductor material layer to the third semiconductor material layer is between 5:8 and 8:5; forming a second metal layer on the active layer; and performing an etching process to expose the second semiconductor material layer at a channel region and dividing the second metal layer into a source and a drain.

An embodiment of the present disclosure proposes a manufacturing method of a thin-film transistor, including the steps of: forming a first metal layer and an insulating layer covering the first metal layer on a substrate; forming an amorphous semiconductor thin film on the insulating layer; performing ion implantation on the amorphous semiconductor thin film to implant group 3A ions into the amorphous semiconductor thin film; carrying out a thermal treatment on the amorphous semiconductor thin film implanted with the Group 3A ions to convert the amorphous semiconductor thin film to a first semiconductor material layer; forming second and third semiconductor material layers on the first semiconductor material layer to constitute an active layer; forming a second metal layer on the active layer; and performing an etching process to expose the second semiconductor material layer at a channel region and dividing the second metal layer into a source and a drain.

An embodiment of the present disclosure proposes a manufacturing method of a thin-film transistor, including the steps of: forming a first metal layer and an insulating layer covering the first metal layer on a substrate; forming an amorphous semiconductor thin film on the insulating layer; carrying out a thermal treatment on the amorphous semiconductor thin film to convert the amorphous semiconductor thin film into a first semiconductor material layer; forming second and third semiconductor material layers on the first semiconductor material layer to constitute an active layer; performing a carrier removal process to the active layer to reduce the quantity of carriers at a sidewall of the active layer; forming a second metal layer on the active layer; and performing an etching process to expose the second semiconductor material layer at the channel region and dividing the second metal layer into a source and a drain.

An embodiment of the present disclosure proposes a display device including a display panel, a data drive circuit, a connecting module, and a control circuit. The display panel includes a substrate and a pixel array. The data drive circuit is disposed on the substrate and electrically connected with the pixel array through a first transmission part. One end of the connecting module is disposed on the substrate and electrically connected with the data drive circuit through a second transmission part. The control circuit is coupled to the other end of the connecting module, and is electrically connected to the data drive circuit through the connecting module and the second transmission part. The data drive circuit includes a drive circuit board, a functional part, a first electric connection part, and a second electric connection part. The functional part is disposed on the drive circuit board. The first electric connection part is disposed on the drive circuit board at one side of the functional part, wherein the first electric connection part is electrically connected with the functional part and the first transmission part. The second electric connection part is disposed on the drive circuit board and located on the other side of the functional part, wherein the second electric connection part is electrically connected with the functional part and the second transmission part. The second electric connection part includes a first connection terminal and a second connection terminal, a distance between the second connection terminal to an edge of the drive circuit board being greater than a distance between the first connection terminal to the edge of the drive circuit board.

An embodiment of the present disclosure proposes a display device including a display panel, a scanning drive circuit, and a data drive circuit. The display panel includes a substrate and a pixel array. The scanning drive circuit is disposed on the substrate and electrically connected with the pixel array to generate a plurality of scanning signals to turn on the pixel array row by row. The data drive circuit is disposed on the substrate and electrically connected to the pixel array to provide a data drive signal in conjunction with the turn-on timing of the pixel array so that the display panel presents a corresponding image in response to the data drive signal. Wherein the scanning drive circuit includes a plurality of stages of first scanning units for electrically connected with one of odd-numbered rows of scanning lines and even-numbered rows of scanning lines in the pixel array, and a plurality of stages of second scanning units for electrically connected with the other of the odd-numbered rows of scanning lines and the even-numbered rows of scanning lines in the pixel array. Wherein at least one of the plurality of first scanning unit includes a first module for receiving scanning signals from the first two stages and the last two stages of the first scanning units and for generating a drive signal at a first node based thereon; a second module electrically connected with the first module via the first node, and deciding a pull-up time point of a scanning signal on a scan output end based on the drive signal, a first clock signal, and a reference signal; and a third module electrically connected with the second module and the scan output end, and deciding a pull-down time point of the scanning signal on the scan output end based on a second clock signal and the reference signal. Wherein the first module includes a first transistor and a second transistor, the first transistor and the second transistor having a first end, a second end, and a control end, respectively. The first end and the control end of the first transistor are electrically connected together to receive the scanning signals of the first two stages of the first scanning units.

An embodiment of the present disclosure proposes a scanning drive circuit for a display device, which includes a plurality of stages of first scanning units for electrically connected with one of odd-numbered rows of scanning lines and even-numbered rows of scanning lines in the pixel array, and a plurality of stages of second scanning units for electrically connected with the other of the odd-numbered rows of scanning lines and the even-numbered rows of scanning lines in the pixel array. Wherein at least one of the plurality of first scanning unit includes a first module for receiving scanning signals from the first two stages and the last two stages of the first scanning units and for generating a drive signal at a first node based thereon; a second module electrically connected with the first module via the first node, and deciding a pull-up time point of a scanning signal on a scan output end based on the drive signal, a first clock signal, and a reference signal; and a third module electrically connected with the second module and the scan output end, and deciding a pull-down time point of the scanning signal on the scan output end based on a second clock signal and the reference signal. Wherein the first module includes a first transistor and a second transistor, the first transistor and the second transistor having a first end, a second end, and a control end, respectively. The first end and the control end of the first transistor are electrically connected together to receive the scanning signals of the first two stages of the first scanning units.

An embodiment of the present disclosure proposes a data drive circuit for a display device, which includes a drive circuit board, a functional part, a first electric connection part, and a second electric connection part. The functional part is disposed on the drive circuit board. The first electric connection part is disposed on the drive circuit board at one side of the functional part, wherein the first functional part is configured to electrically connect the functional part and the display panel. The second electric connection part is disposed on the drive circuit board and on the other side of the functional part, wherein the second electric connection part is configured to electrically connect the functional part and a flexible circuit board. The second electric connection part includes a first connection terminal and a second connection terminal, a distance between the second connection terminal to an edge of the drive circuit board being greater than a distance between the first connection terminal to the edge of the drive circuit board. An embodiment of the present disclosure provides a light guide plate including an incident surface, a first surface, and a second surface. The first surface of the light guide plate is substantially perpendicular to the incident surface and serves as an exit surface of the light guide plate, wherein the first surface has a gloss level less than 1. The second surface of the light guide plate is located on the opposite side of the first surface, wherein the second surface has a gloss level greater than 95.

An embodiment of the present disclosure proposes a light guide plate including an incident surface, a first surface, a second surface, and a plurality of side surfaces. The first surface is substantially perpendicular to the incident surface and serves as an exit surface of the light guide plate. The second surface is located on the opposite side to the first surface, wherein the second surface has a gloss level greater than 95. The plurality of side surfaces are non-parallel to the first surface and are connected with the first surface and the second surface, wherein at least one of the plurality of side surfaces has a gloss level greater than 95.

An embodiment of the present disclosure provides a light guide plate including a body part and a reinforcing part. The body part has a first surface and a second surface. The reinforcing part is formed on at least one of the first surface and the second surface, and includes a plurality of columnar support units. The plurality of support units have light transmitting properties, have an elastic recovery rate of 95 or more, and are sequentially arranged and formed on the body part. The plurality of support units includes at least one support unit formed at a central region of the body part, and support units respectively formed at four corners of the body part.

An embodiment of the present disclosure proposes a light guide plate, including a body part. The body part includes a plurality of light guide units having a parallelogram configuration, wherein adjacent ones of the light guide units are mutually adhered and secured together by an adhering part such that the plurality of light guide units that are mutually adhered form a substantially continuous first surface and a second surface opposite to the first surface.

An embodiment of the present disclosure proposes a light guide plate, including a body part. The body part has a first surface and a second surface opposite to the first surface, wherein the body part has a positive curvature on a center point of the first surface, and the body part has a negative curvature on a center point of the second surface.

An embodiment of the present disclosure provides a backlight module including the aforementioned light guide plate and a light-emitting part. The light-emitting part is disposed toward the incident surface, including a plurality of light-emitting elements, wherein the plurality of light-emitting elements are arranged at fixed intervals.

An embodiment of the present disclosure proposes a backlight module adapted to provide a backlight for a display panel. The backlight module consists of a light guide plate and a light intensifying plate. The light guide plate includes an incident surface, a first surface, and a second surface. The first surface of the light guide plate is substantially perpendicular to the incident surface and serves as an exit surface of the light guide plate, wherein the first surface has a gloss level less than 1. The second surface of the light guide plate is located on the opposite side of the first surface, wherein the second surface has a gloss level greater than 95.

An embodiment of the present disclosure proposes a display panel including a substrate, a plurality of light-emitting elements, and a joint unit. The substrate has a display region and a non-display region surrounding the display region. The plurality of light-emitting elements are arranged in an array arrangement within the display region of the substrate, wherein adjacent ones of the light-emitting element have a first distance therebetween, and the non-display region is at least partially defined as a joint region. The joint unit is disposed on the substrate in the joint region to cover at least a portion of a sidewall of the substrate, wherein the sidewall has a second distance from a nearest light-emitting element. A thickness of the joint unit on the sidewall of the substrate plus the second distance is equal to half of the first distance.

In some embodiments of the present disclosure, the carrier removal process includes: patterning the active layer to form the sidewall; and over-etching the sidewall. The sidewall is a uniform plane continuously consisting of the sides of the first semiconductor material layer, the second semiconductor material layer, and the third semiconductor material layer.

In some embodiments of the present disclosure, the method of manufacturing a thin-film transistor further includes: performing an oxidation process to form a silicon oxide layer on the sidewall.

In some embodiments of the present disclosure, the carrier removal process comprises: patterning the active layer to form the sidewall; and performing ion implantation to implant group 3A ions at the sidewall.

In some embodiments of the present disclosure, a sum of thicknesses of the second semiconductor material layer and the third semiconductor material layer is between 1000 Å and 1500 Å.

In some embodiments of the present disclosure, the thickness of the second semiconductor material layer is between 500 Å and 600 Å, and the third semiconductor material layer has a corresponding thickness such that the sum of the thicknesses of the second semiconductor material layer and the third semiconductor material layer is 1300 Å. The present disclosure proposes a manufacturing method of a thin-film transistor, including: forming, on the first substrate, a first metal layer and an insulating layer overlying the first metal layer; forming an amorphous semiconductor thin film on the insulating layer; performing a thermal treatment on the amorphous semiconductor thin film to allow the amorphous semiconductor thin film to be converted into the first semiconductor material layer; performing an interfacial cleaning process on the first semiconductor material layer to remove semiconductor oxide native to a surface of the first semiconductor material layer; forming the second semiconductor material layer and the third semiconductor material layer on the first semiconductor material layer to constitute the active layer; forming a second metal layer on the active layer; and performing an etching process to expose the second semiconductor material layer at a channel region and dividing the second metal layer into the source and the drain.

In some embodiments of the present disclosure, the method of manufacturing the thin-film transistor further comprises: performing ion implantation on the amorphous semiconductor thin film to implant group 3A ions into the amorphous semiconductor thin film prior to performing the thermal treatment.

In some embodiments of the present disclosure, the method of manufacturing the thin-film transistor further comprises: performing an interfacial cleaning process on the first semiconductor material layer to remove native semiconductor oxide to the surface of the first semiconductor material layer prior to forming the second and third semiconductor material layers.

In some embodiments of the present disclosure, a plurality of reflective film structures are formed on an incident surface of the light guide plate, and the plurality of reflective film structures are arranged at fixed intervals, wherein a gloss level of each of the reflective film structures is greater than 95.

In some embodiments of the present disclosure, a plurality of reflective film structures are formed on the incident surface, each reflective film structure being formed in an interval region of adjacent light-emitting elements.

In some embodiments of the present disclosure, the plurality of support units includes a first support unit having a first height and a second support unit having a second height, wherein the first height is greater than the second height.

In some embodiments of the present disclosure, at least part of the plurality of light guide units has a rhombic structure, and at least another part has a triangular structure.

In some embodiments of the present disclosure, the curvature of both the first surface and the second surface is greater than 1500 R.

An embodiment of the present disclosure proposes a display, including: a plurality of display panels as described above, wherein the plurality of display panels are mutually spliced, and are synchronously driven to cooperatively display an image.

An embodiment of the present disclosure provides a pixel array substrate including a thin-film transistor manufactured by the manufacturing method of the thin-film transistor as described above.

An embodiment of the present disclosure proposes a display device, including the pixel array substrate as described above.

With one of the technical solutions described in the embodiments of the present disclosure, according to the display device, the LED module and the manufacturing method thereof, the upper surfaces of all light-emitting elements can be basically maintained at the same level, and there is no height difference, so that the subsequent manufacturing process will not be affected by the flatness of the LED module, thereby effectively improving the yield and reliability of the manufacturing process.

With one of the technical solutions described in this disclosure, the quantum dot film proposed in the embodiment of this disclosure can not only provide a preliminary water-blocking effect through the support layer and the bonding layer, but also use the water-blocking layer covering the active layer to further block moisture out of the active layer, so that the active layer is less susceptible to moisture, and the reliability of the backlight module and the display is greatly improved. In addition, because the water-blocking layer greatly improves the water resistance of the quantum dot film, there are more choices for the materials of the support layer and the bonding layer in the design of the quantum dot film to meet the design considerations, and at the same time, the cost requirements can be taken into account.

With one of the technical solutions described in the present disclosure, the thin-film transistor, the pixel array substrate, the display device and the manufacturing method thereof proposed in the embodiment of the present disclosure can eliminate the semiconductor oxide which is easy to cause bonding defects between the microcrystalline or polycrystalline silicon layer and the amorphous silicon layer in the active layer through specific interfacial cleaning treatment in the manufacturing process of the thin-film transistor, so that the thin films in the active layer can be well bonded without the problem of film peeling, and the element characteristics of the thin-film transistor such as carrier mobility and switching ratio can be effectively improved. In addition, the embodiment of this disclosure also proposes to improve the threshold voltage of the thin-film transistor by ion implantation of the active layer before the heat treatment step, so that the finished product can have better device characteristics.

With one of the technical solutions described in this disclosure, the display device and the scanning drive circuit thereof proposed by the embodiments of the present disclosure can reduce the non-scanning unit width of the display panel by omitting the number of signal lines by changing the circuit configuration of the display region, so as to achieve the effect of bezel width reduction.

With one of the technical solutions described in the present disclosure, the light guide plate proposed by the embodiment of the present disclosure and the backlight module thereof, structural reinforcement of the light guide plate is achieved by forming a pillar-shaped support unit structure on the body part of the light guide plate. The cost of the overall backlight module can be effectively controlled since no additional stiffening plates need to be provided. Further, by configuring the first support unit and the second support unit having a height difference, it is possible to form a step support on the light guide plate to achieve an optimized efficiency between the display effect and the structural protection.

On the other hand, in the light guide plate and backlight module thereof proposed by some embodiments of the present disclosure, constituting the light guide plate by a standard module having a parallelogram structure can effectively reduce the directivity of the light source, so that the light can be more uniformly diffused over the entire light guide plate and the backlight module can obtain a more uniform surface light source. In addition, the light guide plate formed by attaching the light guide units, even when pressed, can absorb the stress of the pressing through the adhering part without the risk of warping as in the conventional one-sided light guide plate. The risk of deformation of the light guide plate due to thermal expansion and moisture expansion can also be effectively reduced/eliminated. On the other hand, it is also possible to effectively simplify the manufacturing process of the light guide plate and reduce the manufacturing cost and cycle, as well as reduce the cost and expense of maintenance.

In the light guide plate and the backlight module thereof proposed by some embodiments of the present disclosure, by providing the light guide plate with the curved surface structure, it is possible to make the light source in the central region more uniformly diffused to the peripheral region, and thus higher conversion efficiency of the light source can be achieved.

With one of the technical solutions described in the present disclosure, embodiments of the disclosed display panel, display, and method of manufacturing the same preferably eliminate the visual impact of splice seams without visible splicing seams or optical chromatic aberrations by configuring the joint unit to equalize the distance of the light-emitting elements at the seams to the distance of the light-emitting elements within the panel. Furthermore, there is a significant advantage in terms of manufacturing costs, since there is no need to add additional components such as optical microstructures or light bars.

### BRIEF DESCRIPTION OF DRAWINGS

FIGS. 1A to 1D are schematic views of a display device according to various embodiments of the present disclosure;

FIGS. 2A and 2B illustrate configurations of LED modules according to various embodiments of the present disclosure;

FIG. 3 is a schematic cross-sectional structure of an LED module according to some embodiments of the present disclosure;

FIGS. 4A to 4G are schematic cross-sectional structures of LED modules according to various embodiments of the present disclosure;

FIGS. 5A and 5C are flow charts illustrating steps of a method of manufacturing an LED module according to various embodiments of the present disclosure;

FIGS. 6A to 6H are schematic flow diagrams of a method of manufacturing an LED module according to an embodiment of FIG. 5A;

FIGS. 7A to 7I are schematic flow diagrams of a method of manufacturing an LED module according to another embodiment of FIG. 5A;

FIGS. 8A to 8F are flow diagrams of a method of manufacturing an LED module according to an embodiment of FIGS. 5B and 5C;

FIG. 9 is a schematic cross-sectional view of a thin-film transistor according to some embodiments of the present disclosure;

FIGS. 10A to 10E are flow charts illustrating steps of a method of manufacturing a thin-film transistor according to various embodiments of the present disclosure;

FIGS. 11A to 11F are schematic flow diagrams of a method of manufacturing the thin-film transistor in accordance with FIG. 10A;

FIGS. 12A to 12F are schematic flow diagrams of a method of manufacturing the thin-film transistor in accordance with FIG. 10B;

FIGS. 13A to 13F are schematic flow diagrams of a method of manufacturing the thin-film transistor according to FIG. 10C;

FIG. 14 is an SEM photograph of a thin-film transistor manufactured by a manufacturing method according to an embodiment of the present disclosure and a comparative example;

FIG. 15 is a schematic breakover current diagram of a thin-film transistor manufactured by a manufacturing method according to an embodiment of the present disclosure and a comparative example;

FIG. 16 shows current-voltage characteristics at different ion implantation concentrations of a thin-film transistor manufactured by a manufacturing method according to an embodiment of the present disclosure;

FIG. 17 is a current-voltage characteristic curve of a thin-film transistor manufactured by a manufacturing method according to an embodiment of the present disclosure at different thicknesses of an active layer;

FIG. 18 is a current-voltage characteristic curve of a thin-film transistor manufactured through a carrier removal processing step according to an embodiment of the present disclosure and a comparative example;

FIG. 19 is a current-voltage characteristic curve of a thin-film transistor manufactured through a carrier removal processing step according to an embodiment of the present disclosure and a comparative example;

FIGS. 20A to 20E illustrate structural configurations of a backlight module according to various embodiments of the present disclosure;

FIGS. 21A to 21D illustrate configurations of a light guide plate according to various embodiments of the present disclosure;

FIGS. 22A and 22B are schematic illustrations of incident finish coating structures according to various embodiments of the present disclosure;

FIGS. 23A to 26 illustrate configurations of a light guide plate according to various embodiments of the present disclosure;

FIG. 27 is a schematic illustration of a backlight module according to some embodiments of the present disclosure;

FIG. 28 is a schematic illustration of a bonding layer of a quantum dot film according to some embodiments of the present disclosure;

FIGS. 29A to 29F illustrate cross-sectional structures of a quantum dot film according to various embodiments of the present disclosure;

FIG. 30 illustrates a quantum dot film waterproof layer material chemical structure according to various embodiments of the present disclosure;

FIG. 31 is a tabulation of mechanical properties of waterproof layer materials according to various embodiments of the present disclosure;

FIG. 32 is a graphical representation of light transmittance at different wavelengths for waterproof layer materials according to various embodiments of the present disclosure;

FIG. 33 is a flowchart showing the steps of a method of manufacturing a quantum dot film according to some embodiments of the present disclosure;

FIG. 34 is a schematic illustration of a spliced display device according to some embodiments of the present disclosure;

FIGS. 35A to 35D illustrate different embodiments of display panel configurations for the spliced display device of FIG. 34;

FIGS. 36A to 36D illustrate configurations of a spliced display device according to various embodiments of the present disclosure;

FIG. 37 is a flow chart showing the steps of a method of manufacturing a display panel according to some embodiments of the present disclosure;

FIG. 38 is a schematic illustration of a scanning drive circuit according to some embodiments of the present disclosure;

FIGS. 39A and 39B are circuit diagrams of an embodiment of a scanning drive circuit;

FIGS. 40A to 40D illustrate signal waveforms of the scanning drive circuit of FIGS. 39A and 39B;

FIGS. 41A to 41D are circuit schematics of a scanning drive circuit, according to some embodiments of the present disclosure;

FIG. 42 is a schematic illustration of a data drive circuit according to some embodiments of the present disclosure;

FIGS. 43A to 43C show configurations of a data drive circuit according to some embodiments of the present disclosure; and

FIGS. 44A to 44D are partially enlarged schematic views of the electric connection part of the data drive circuit according to different embodiments of the present disclosure.

### DESCRIPTION OF EMBODIMENTS

In order that the above objects, features and advantages of the present invention may be more clearly understood, specific embodiments of the present invention will now be described in detail with reference to the accompanying drawings. The following description of various embodiments of the subject matter of the present invention is for purposes of illustration and illustration only, and is not intended to be exhaustive or to limit the invention to particular embodiments. Based on the embodiments in the present disclosure, all other embodiments obtained by those of ordinary skill in the art without making inventive labor should belong to the scope of protection of the present invention.

It is noted that when an element is referred to as being “disposed on” another element, it can be directly on the other element or intervening elements may also be present. When an element is referred to as being “connected” to another element, it can be directly connected to the other element or intervening elements may be present. As used herein, the terms “vertical,” “horizontal,” “left,” “right,” “upper,” “lower,” and the like are merely intended to refer to relative positional relationships based on the drawings, and are not intended to limit the elements in which the terms are used to be implemented in a representative manner. When the absolute position of the object being described changes, the description of the relative position may also change accordingly.

Descriptions herein with reference to “substantially,” “approximately,” “about,” etc., are error ranges implied by possible unintended effects and deviations in manufacturing processes or material selection. The error range is a range that can encompass variations that do not significantly alter the material structure, configuration, properties, effects, such as a range of 0%-10% deviation, where the error range is clear to those skilled in the art. For example, stating that “two items are substantially parallel,” a relative disposition observed between the two items would still be read as being within the scope of “substantially parallel,” if substantially a slight drop in height is observed between the two items, but the drop is negligible (e.g., less than 10%) relative to the size of the items themselves and does not affect the effect.

All recitations herein in relation to particular values include, although not directly described, the meaning of “about” or “substantially”, i.e., the particular value encompasses a range of possible numerical errors to recognize possible unintended effects and deviations in manufacturing processes or material choices. The numerical error range can include numerical variations that do not significantly alter the structure, properties, or effects of the material, such as a range of 0% to 10% deviation, as will be apparent to one of ordinary skill in the art.

Unless defined otherwise, all technical and scientific terms used herein have the same meaning as commonly understood by one of ordinary skill in the art to which this disclosure belongs. The terminology used in the description of the disclosure herein is for the purpose of describing particular embodiments only and is not intended to be limiting of the disclosure. As used herein, the term “and/or” includes any and all combinations of one or more of the associated listed items.

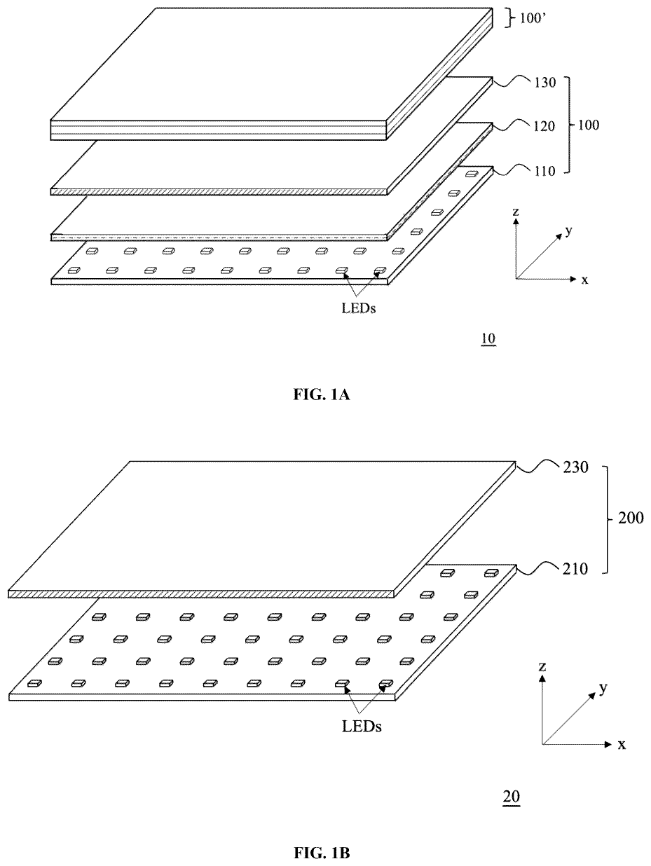

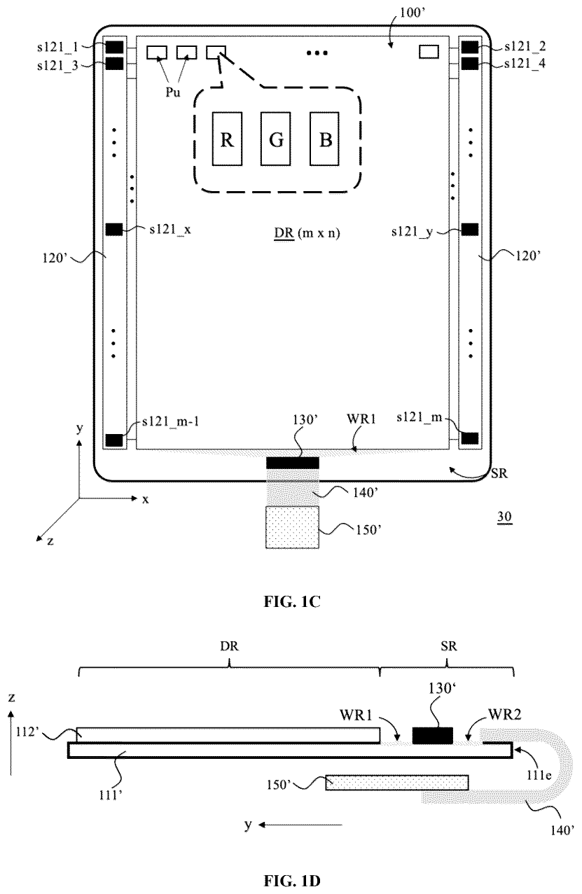

FIG. 1A and IB are schematic diagrams of a display device according to different embodiments of the present disclosure, wherein FIG. 1A is a schematic diagram of a configuration of a non-self-luminous display device, and FIG. 1B is a schematic diagram of a configuration of a self-luminous display device.

Referring first to FIG. 1A, the display device 10 of this embodiment may be, for example, a liquid crystal display device (LCD device) including a backlight module 100 and a display panel 100′, wherein the backlight module 100 and the display panel 100′ are disposed on the x-y plane, and the display panel 100′ is disposed on the backlight module 100 along the z-axis. The backlight module 100 serves to provide a sufficient brightness and uniformly distributed light source towards the display panel 100′. The display panel 100′ is configured to controllably adjust the passing light for rendering a corresponding image thereon. In this embodiment, the display device 10 may be any electronic device having a display function, such as a television, a screen, a notebook computer or a cellular phone, the present disclosure not being limited thereto.

The backlight module 100 includes a light-emitting layer 110, wherein the light-emitting layer 110 includes a plurality of light-emitting elements LEDs arranged in an array. The light-emitting elements LEDs may be used to emit light toward the display panel 100′. In some embodiments, the light-emitting elements LEDs may be white, red, green, or blue light emitting diodes (or alternatively, light emitting diodes having light emitting wavelengths in the white, red, green, or blue light segments), or combinations thereof, as the present disclosure is not limited thereto.

Further, in some embodiments, the backlight module 100 may further include a quantum dot film 120 and an optical adjustment layer 130, wherein the quantum dot film 120 is disposed on the light-emitting layer 110 and the optical adjustment layer 130 is disposed on the quantum dot film 120, i.e. the quantum dot film 120 is disposed between the light-emitting layer 110 and the optical adjustment layer 130. In embodiments where a quantum dot film 120 is provided, the light-emitting elements LEDs may for example be blue light emitting diodes.

The quantum dot film 120 is disposed on the light transmission path of the light-emitting layer 110, and functions to adjust the wavelength of a portion of the light emitted by the light-emitting elements LEDs, and to allow another portion of the light emitted by the light-emitting elements LEDs to pass directly through without adjustment. For example, in the case of light-emitting elements LEDs emitting light in the blue wavelength range (e.g. 400-520 nm), the quantum dot film 120 may adjust the wavelength of a first portion of received light to a red wavelength range (e.g., 610 nm to 720 nm), adjust the wavelength of a second portion of received light to a green wavelength range (e.g., 520 nm to 610 nm), and output a third portion of received light directly without adjustment, maintaining the blue wavelength range. Thus, the first to third portions of light emitted from the light-emitting layer 110 can be mixed to form white light after passing through the quantum dot film 120.

The optical adjustment layer 130 is also located on the light transmission path of the light-emitting layer 110 and serves to redirect the received light so that the transmitted light source is more uniform. In some embodiments, the optical adjustment layer 130 includes a plurality of optical microstructures (not shown) and/or optical films (not shown) to redirect light rays, although the present disclosure is not limited thereto.

The display panel 100′, for example, includes a pixel array substrate, a counter substrate, and a non-self-luminous display medium, wherein the pixel array substrate and the counter substrate are disposed opposite, and the non-self-luminous display medium is disposed between the pixel array substrate and the counter substrate. In some embodiments, the non-self-luminous display medium may be, for example, a liquid crystal, although the present disclosure is not limited thereto.

Referring to FIG. 1B, the display device 20 of this embodiment may be, for example, an organic light-emitting diode (OLED) display device, an Active Matrix/Organic Light Emitting Diode (AMOLED) display device, or other type of self-luminous display device including a self-luminous display panel 200 including a self-luminous pixel layer 210. The self-luminous pixel layer 210 includes a plurality of light-emitting elements LEDs (e.g., mini-LEDs or micro-LEDs), where individual or multiple light-emitting elements LEDs constitute pixels arranged in an array and controlled to adjust the emission state to present a corresponding image.

Further, in some embodiments, the self-luminous display panel 200 may further include an optical adjustment layer 230 disposed on the self-luminous pixel layer 210. The optical adjustment layer 230 is similar to the optical adjustment layer 130 described in the embodiment of FIG. 1A, and is configured to be disposed on the light transmission path of the self-luminous pixel layer 210, and to adjust the direction of light received.

In the above embodiments, the light-emitting layer 110 in the backlight module 100 or the self-luminous pixel layer 210 in the self-luminous display panel 200 all have an approximate structural configuration in which the light-emitting element array is disposed on a substrate, and thus may be collectively referred to as an LED module. In other words, the structural configuration of the LED module described later herein may be applied to the non-self-luminous display device 10 of FIG. 1A or the self-luminous display device 20 of FIG. 1B, the present disclosure not being limited thereto.

From the perspective of circuit configuration and display driving, as shown in FIG. 1C to ID, where FIG. 1C is a schematic view of a top configuration of the display device 30, and FIG. ID is a schematic view of a side configuration of the display device 30. For ease of explanation, FIG. 1C shows the internal components of the display device 30 spread out in the x-y plane, and FIG. 1D shows the configuration of the internal components of the display device 30 in the housing.

In this embodiment, the display device 30 may include a scanning drive circuit 120′ for driving the display panel 100′, a data drive circuit 130′, a connecting module 140′, and a control circuit 150′ in addition to the LED module described above. The display panel 100′ has a display region DR and a non-display region SR, wherein the display region DR is a region to display an image; the non-display region SR is a region where the display panel 100′ does not display an image. The non-display region SR will typically surround the display region DR and may also be considered as a border region of the display device 30. The scanning drive circuit 120′ and the data drive circuit 130′ are disposed in the non-display region SR of the display panel 100′. In the figure, the scanning drive circuit 120′ is exemplified by the non-display region SR disposed on the left and right sides of the display panel 100′, and the data drive circuit 130′ is exemplified by the non-display region SR disposed on the lower side of the display panel 100′, although the present disclosure is not limited thereto. One end of the connecting module 140′ is disposed on a side of the non-display region SR close to the data drive circuit 130′, and the control circuit 150′ is coupled to the other end of the connecting module 140′.

Specifically, the display panel 100′ may include a substrate 111′ and a pixel array 112′ located in the display region DR. The pixel array 112′ is disposed on the substrate 111′ and, for example, includes pixel units Pu arranged in an array of m×n, that is, m rows and n columns, where m, n may be natural numbers selected according to design requirements, and the present disclosure is not limited thereto.

In some embodiments, each pixel unit Pu may correspond to a light-emitting element, which may be, for example, a white light emitting diode or a blue light emitting diode, the present disclosure not being limited thereto. The light-emitting element may be a sub-millimeter light emitting diode (mini-LED), a micro light emitting diode (micro-LED), or an organic light emitting diode (OLED), although the present disclosure is not limited thereto. In other embodiments, the light-emitting elements LEDs may also be of other sizes and/or types. Depending on the selected type of the light-emitting element, the display panel 100′ may be, for example, a ULED panel, a mini-LED panel, a micro-LED panel or an OLED panel, the present disclosure not being limited thereto.

In some embodiments, each pixel unit Pu may include a plurality of sub-pixels, for example, a first sub-pixel R, a second sub-pixel G, and a third sub-pixel B. The first sub-pixel R, the second sub-pixel G, and the third sub-pixel B are respectively controlled to emit light having different wavelengths. For example, the first sub-pixel R may include a light-emitting element having a red wavelength range (e.g., 610-720 nm), the second sub-pixel G may include a light-emitting element having a green wavelength range (e.g., 520-610 nm), and the third sub-pixel B may include a light-emitting element having a blue wavelength range (e.g., 400-520 nm). In some embodiments, the light-emitting elements of the first sub-pixel R, the second sub-pixel G, and the third sub-pixel B may be a red light emitting diode (or a light emitting diode having a light-emitting wavelength in the red region), green light emitting diode (or a light emitting diode having a light-emitting wavelength in the green section), and a blue light emitting diode (or a light emitting diode having a light-emitting wavelength in the blue section), respectively. Similarly, the light-emitting element of each sub-pixel R/G/B may be a mini-LED or a micro-LED, although the present disclosure is not limited thereto.

The scanning drive circuit 120′ is electrically connected to the display panel 100′ through the wiring on the substrate 111′ in view of the electrical relationship between the elements. The data drive circuit 130′ is electrically connected to the display panel 100′ through the first transmission part WR1, and is electrically connected to the connecting module 140′ (the flexible circuit board 140′) through the second transmission part WR2. On the other hand, the control circuit 150′ is electrically connected to the data drive circuit 130′ through the connecting module 140′ and the second transmission part WR2. Here, the first transmission part WR1 and the second transmission part WR2 may be transmission lines formed at the substrate 111′.

The scanning drive circuit 120′ is configured to generate a scanning signal to turn on/enable pixels row by row according to the timing control signal. In this embodiment, the scanning drive circuit 120′ is illustrated as an example of two configurations for enabling odd and even rows of pixels, respectively, where the scanning drive circuit 120′ on the left side is exemplified by including the scanning unit sl21_1, sl21_3, . . . , sl21_m-1 respectively connected to the odd-numbered scanning lines, and the scanning drive circuit 120′ on the right side is exemplified by including the scanning unit sl21_2, sl21_4, sl21_m respectively connected to the even-numbered scanning lines, although the present disclosure is not limited thereto. In this embodiment, the scanning unit sl21_x represents any of the scanning unit sl21_1, sl21_3, . . . , sl21_m-1 on the left side, and the scanning unit sl21 y represents any of the scanning unit sl21_2, sl21_4, sl21_m on the right side. In other words, x may be any odd number less than m, and y may be any even number less than or equal to m, where m is an even number, although the present disclosure is not limited thereto.

The data drive circuit 130′ is configured to generate a drive signal to drive the pixel array 112′ according to data control signals. While the drawings of this embodiment depict a single data drive circuit 130′ as an illustration, the present disclosure is not limited thereto, the data drive circuit 130′ may be integrated into a plurality of driver chips in some embodiments, wherein the plurality of driver chips may cooperatively drive different portions/regions of pixels in the pixel array 112′.

More specifically, the same column of pixels in the pixel array 112′ would correspond to the same scanning line, and the same row of pixels would correspond to the same data line pixel array 112′. The pixel array 112′ may be electrically connected to the scanning drive circuit 120′ through a scanning line to receive a scanning signal, and electrically connected to the data drive circuit 130′ through a data line and the first transmission part WR1 to receive a data drive signal provided from the data drive circuit 130′. The data drive circuit 130′ provides a data drive signal in cooperation with the turn-on timing of the pixel array 112′ so that the pixel array 112′ adjusts the passing light according to the data drive signal for rendering a corresponding image in the display region DR.

The connecting module 140′ is configured to provide a signal transmission path between the data drive circuit 130′ and the control circuit 150′ such that data control signals generated by the control circuit 150′ can be transmitted to the data drive circuit 130′ through the connecting module 140′ and the second transmission part WR2. In some embodiments, the connecting module 140′ may be a flexible circuit board (hereinafter referred to as the flexible circuit board 140′) that is bendable, as shown in FIG. 1 D, and the flexible circuit board 140′ has a plurality of connection terminals on both ends of the flexible circuit board 140′, wherein the connection terminals on the side of the flexible circuit board 140′ adjacent to the data drive circuit 130′ are disposed on the substrate 111′, and those on the side of the flexible circuit board 140′ adjacent to the control circuit 150′ are disposed on the circuit board of the control circuit 150′. A portion of the flexible circuit board 140′ which is adjacent to a side of the data drive circuit 130′ and which is provided with connection terminals is attached to the substrate 111′, wherein the width of the attached portion is approximately the distance from the tip of the connection terminal of the flexible circuit board 140′ to the substrate edge 111e.

When the display device 30 is assembled, the flexible circuit board 140′ is bent so that the control circuit 150′ is disposed on the back side of the display panel 100′ (i.e., the other side of the substrate 111′ with respect to the display region DR). In other words, in the assembled state of the display device 30, the control circuit 150′, the substrate 111′, and the data drive circuit 130′ inside the display device 30 are sequentially arranged along the z-axis.

In the pixel array 112′ of the display panel 100′, a plurality of thin-film transistors (not shown) are included. The plurality of thin-film transistors are turned on or off in response to received signals for controlling the operation of the corresponding pixels to achieve the above-described effect of drive signal adjusting the light passing therethrough in accordance with the data for rendering the corresponding image in the display region DR. Embodiments of the thin-film transistor are further illustrated in the following embodiments.

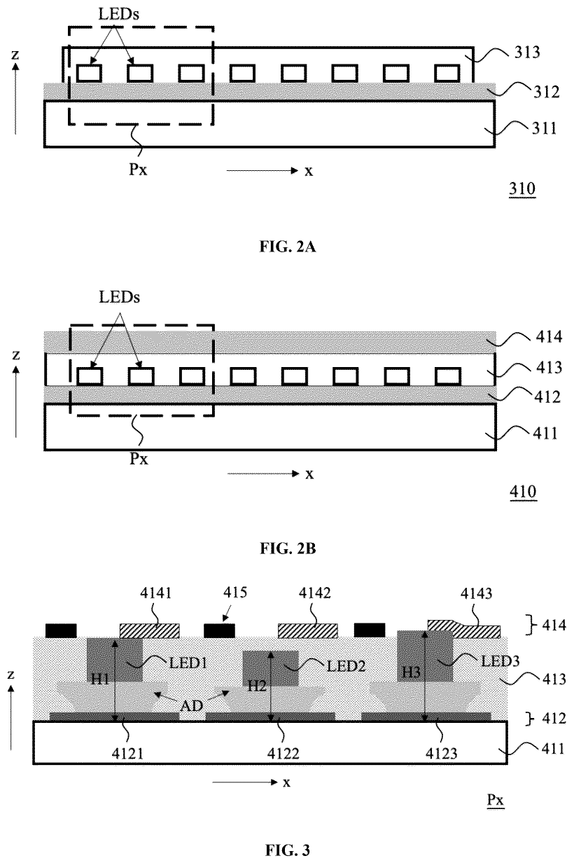

FIGS. 2A and 2B illustrate configurations of LED modules according to various embodiments of the present disclosure. Referring first to FIG. 2A, the LED module 310 of this embodiment includes light-emitting elements LEDs, a substrate 311, a line layer 312, and a protective layer 313. The line layer 312 is provided on the substrate 311. The light-emitting elements LEDs are disposed on the line layer 312 to receive a drive signal for controlling lighting thereof through the line layer 312, wherein each of the light-emitting elements LEDs has two electrodes, and the two electrodes are located on the same side of the light-emitting elements LEDs to be electrically connected to the line layer 312. A protective layer 312 covers light-emitting elements LEDs to avoid shorting between light-emitting elements LEDs.

Referring to FIG. 2B, the LED module 410 of this embodiment includes light-emitting elements LEDs, a substrate 411, a first line layer 412, a protective layer 413, and a second line layer 414. The first line layer 412 is disposed on the substrate 411. The light-emitting elements LEDs are disposed on a first line layer 412, wherein each light-emitting element LED has two electrodes positioned on opposite sides of the light-emitting element LED. The electrode (or the lower electrode) of each of the light-emitting elements LEDs near one side (or a lower side) of the first line layer 412 is electrically connected to the first line layer 412. The protective layer 413 covers at least a portion of a surface of each of the light-emitting elements LEDs for preventing a short circuit between light-emitting elements LEDs, wherein the protective layer 413 exposes at least an electrode (or the upper electrode) of another side (i.e., a side remote from the first line layer 412, or an upper side) of the light-emitting elements LEDs. The second line layer 414 is disposed on the protective layer 413, and is electrically connected with electrodes of the other side of light-emitting elements LEDs, wherein light-emitting elements LEDs may receive a drive signal controlling lighting thereof through the first line layer 412 and the second line layer 414.

Specifically, in the embodiment of FIG. 2A, the light-emitting elements LEDs may be, for example, lateral-packaged or flip-packaged light emitting diodes, wherein the electrodes of each light emitting diode are disposed on the same side, and thus may receive a drive signal through the line layer 312 located on the substrate 311. On the other hand, in the embodiment of FIG. 2B, the light-emitting elements LEDs may be, for example, vertical-packaged light emitting diodes (LEDs), wherein the electrodes of each LED are disposed on opposite sides so that a drive signal may be received through the first line layer 412 and the second line layer 414 located on either side of light-emitting elements LEDs.

In some embodiments, the light-emitting elements LEDs include, for example, a red/green/blue tri-color light-emitting element, and the tri-color light-emitting element is arranged in a sequential arrangement on the line layer 112, for example, in the order of red (R)→green (G)→blue (B), although the present disclosure is not limited thereto.

It should be noted here that FIG. 1C illustrates that the display panel 100′ and the peripheral circuitry separately constitute a display device 30 (or display), but the present disclosure is not so limited. In other embodiments, the display panel 100′ may be spliced to form a spliced display. This section is further illustrated in subsequent examples.

The design of the LED module part in the display device Oct. 20, 1930 is further explained below.

In LED module 410 applications using vertical-packaged light-emitting elements LEDs, the actual size and placement of each of the light-emitting elements LEDs may vary, resulting in the upper electrodes of each of the light-emitting elements LEDs being positioned higher and lower and not in the same plane, as shown in FIG. 3, which is a cross-sectional view of the LED module 410 in the region Px.

In this embodiment, the first line layer 412 includes lower electrode leads (or first electrode leads) 4121, 4122, and 4123 to be electrically connected to the lower electrodes of the light-emitting elements LED1, LED2, and LED3, respectively, through corresponding adhering parts AD. On the other hand, the second line layer 414 includes upper electrode leads (or second electrode leads) 4141, 4142, and 4143 to be electrically connected to the upper electrodes of the light-emitting elements LED1, LED2, and LED3, respectively.

In some embodiments, the LED module 410 may further include a light shielding part 415 disposed on the protective layer 413 and spaced apart from the upper electrode leads 4141-4143, for preventing the light emitted from the adjacent light-emitting elements LED1-LED3 from interacting with each other.

The light-emitting element LED1 on the left side in FIG. 3 is the configuration in the ideal state, that is, when the light-emitting element LED1 is provided on the substrate 411 through the adhering part AD and connected to the lower electrode lead 4121, the height H1 (i.e. the maximum distance from the bottom of the lower electrode lead 4121 to the top of the light-emitting element LED1) of the three of the lower electrode lead 4121, the adhering part AD and the light-emitting element LED1 is exactly substantially the same as the height of the protective layer 413, such that the upper electrode of the light-emitting element LED1 is exposed and located substantially flush with the upper edge of the protective layer 413 (i.e., the upper electrode and the upper side of the protective layer 413 are located substantially in the same plane). Therefore, in an ideal state, the upper electrode lead 4141 formed on the protective layer 413 can be easily electrically connected to the exposed upper electrode, and the upper electrode lead 4141 can still have a uniform line width (here, the width of the upper electrode lead 4141 in the x-z plane) to secure electrical signal transmission.

The light-emitting element LED2 and LED3 illustrate the configuration that may occur from time to time in practice. Viewed from the configuration of the light-emitting element LED2, the heights of the light-emitting element LED2 and the corresponding adhering part AD are both slightly less than the heights of the light-emitting element LED1 and its adhering part AD, so that the height H2 of the lower electrode lead 4122, the adhering part AD, and the light-emitting element LED2 as a whole will be less than the height of the protective layer 413 (i.e., approximately the height H1), such that the protective layer 413, when formed, will cover the upper electrode of the light-emitting element LED2. As such, when the upper electrode lead 4142 is formed on the protective layer 413, since the upper electrode of the light-emitting element LED2 is covered with the protective layer 413, the upper electrode lead 4142 cannot be effectively electrically connected to the upper electrode of the light-emitting element LED2, so that the light-emitting element LED2 cannot receive the drive signal for lighting. The configuration state of the light-emitting element LED2 may be considered an under-configured state.

Viewed in the configuration of the light-emitting element LED3, the height of the light-emitting element LED3 is slightly greater than the height of the light-emitting element LED1, so that the height H3 of the lower electrode lead 4123, the adhering part AD, and the light-emitting element LED3 as a whole will be greater than the height of the protective layer 413, so that the upper side of the light-emitting element LED3 will be beyond the upper side surface of the protective layer 413, leaving the upper electrode of the light-emitting element LED3 and the upper side surface of the protective layer 413 not on the same plane. As such, in forming the upper electrode lead 4143 on the protective layer 413, since the upper electrode of the light-emitting element LED3 is higher than the upper side surface of the protective layer 413, the upper electrode lead 4143 needs to be bent to extend to and be electrically connected to the upper electrode of the light-emitting element LED3, and the line width of the lead at the bend (here, the width of the upper electrode lead 4143 in the x-z plane) is thin, which easily causes the lead to break, so that the electric signal cannot be normally transmitted. The configuration state of the light-emitting element LED3 may be considered an over-configured state.

As can be seen from the above, in the general structural configuration of the LED module, since the thickness of the light-emitting elements LED1-LED3 may vary when actually manufactured, the lower electrode leads 4121-4123 and the corresponding adhering parts AD may be formed with different thicknesses/heights during the manufacturing process. The various manufacturing process and material differences, when accumulated in the LED module package, cause the upper electrodes of each of the light-emitting elements LED1-LED3 to have different heights (e.g., H1-H3), thereby causing the upper electrode leads 4141-4143 to be formed/disposed with the above-described poor connection.

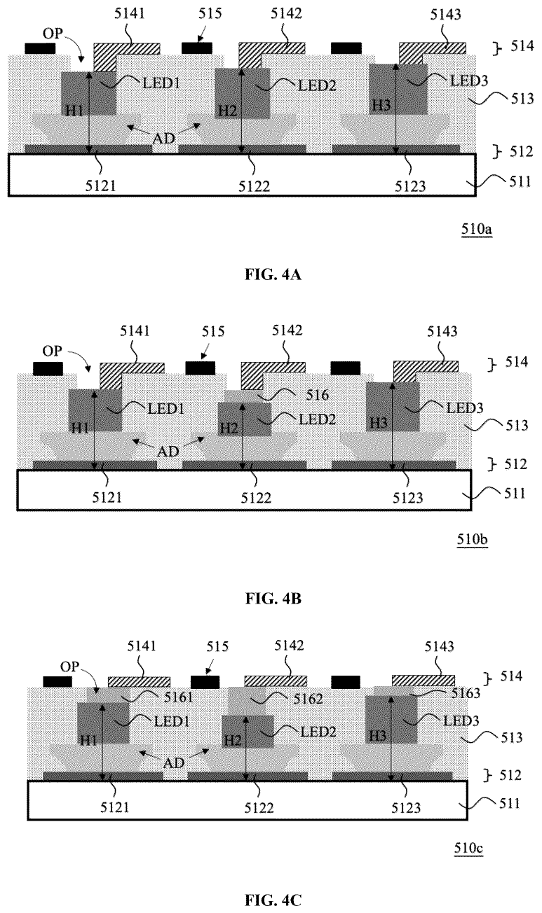

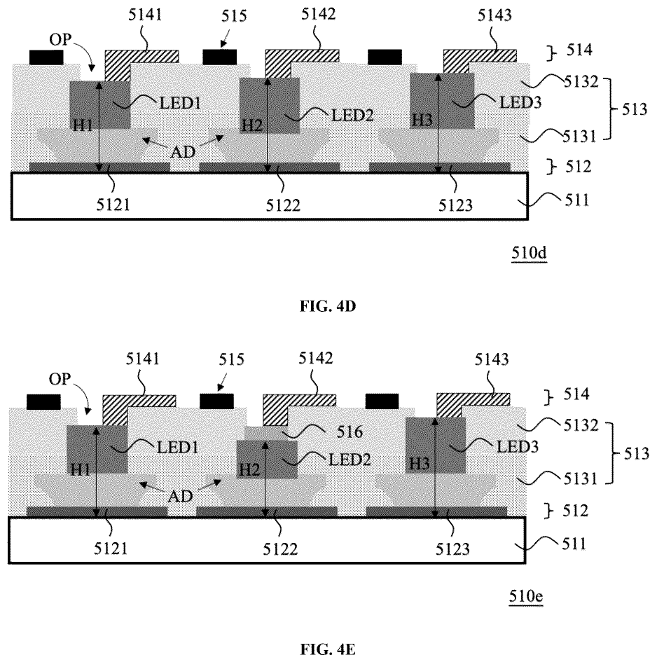

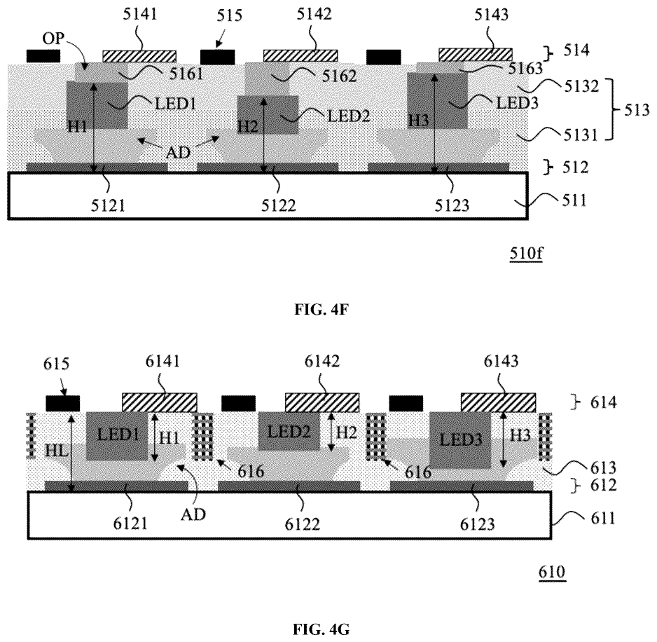

In order to solve the above problems, the present disclosure proposes various novel structural configurations to achieve the effect of planarizing the surface of the LED module, wherein FIGS. 4A to 4G are cross-sectional structural diagrams of LED modules according to various embodiments of the present disclosure. In some embodiments of this configuration, the thickness of the protective layer of the LED module, when formed, is designed to exceed the height of the light-emitting element and the corresponding lower electrode leads and junctions, so that the upper side surface of the protective layer is higher than the upper electrode of each light-emitting element. Next, the upper electrode covered with the protective layer may be exposed by using a specific manufacturing process (e.g., photolithography), and a structure is formed in which an opening is formed between the upper electrode and the protective layer of each light-emitting element. Thereby, the upper electrode lead can be electrically connected with the upper electrode within the opening through the opening, thereby realizing a planarized LED module structure (as in the FIGS. 4A-F embodiments). In another embodiment of the arrangement, the light-emitting element is forced towards the substrate during the setting, wherein the light-emitting element is displaced differently in response to its respective size/height, thus having a different substrate distance, so that the upper electrode of the light-emitting element is kept in the same plane. Thus, the LED module may form a flat surface to facilitate placement of upper electrode leads and electrical connection to each light-emitting element, thereby enabling a planarized LED module structure (as in the FIG. 4G embodiment). The structures of the embodiments of FIGS. 4A-4G are described below.

Referring first to FIG. 4A, the LED module 510a of this embodiment includes a substrate 511, a first line layer 512, a plurality of light-emitting elements LED1-LED3, a protective layer 513, a second line layer 514, and a light shielding part 515. The first line layer 512 is disposed on the substrate 511. The light-emitting elements LED1-LED3 are respectively disposed on the first line layer 512 through the corresponding adhering parts AD, to make the lower electrodes of the light-emitting elements LED1-LED3 electrically connected with the first line layer 512 through the adhering parts AD. The protective layer 513 is formed on the substrate 511, and covers the first line layer 512, the adhering parts AD, and the peripheral region of the light-emitting elements LED1-LED3, so as to prevent unintended shorting between adjacent light-emitting elements LED1-LED3, wherein the protective layer 513 exposes at least part or all of the upper electrodes of light-emitting elements LED1-LED3, and the protective layer 513 forms a height/thickness on the light-emitting element 511 that is greater than or equal to the corresponding height H1-H3 of any of the light-emitting elements LED1-LED3 to form an opening OP on at least one or more of the light-emitting elements LED1-LED3. The corresponding height H1-H3 of any one of the light-emitting elements LED1-LED3 refers to herein may, for example, be the sum of the heights/thicknesses of any one of the light-emitting elements LED1-LED3 and its corresponding first line layer 512 and adhering part AD. The second line layer 514 is disposed on the protective layer 513, and extends toward the opening OP to be electrically connected to the upper electrode of each of the light-emitting elements LED1-LED3 through the opening OP.

More specifically, the first line layer 512 includes lower electrode leads 5121-5123, and the second line layer 514 includes upper electrode leads 5141-5143. The lower electrodes of the light-emitting elements LED1-LED3 are electrically connected to the lower electrode leads 5121-5123, respectively, through the corresponding adhering parts AD, and the upper electrodes of the light-emitting elements LED1-LED3 are electrically connected to the upper electrode leads 5141-5143, respectively, in the corresponding openings OP. With the above arrangement, the light-emitting elements LED1-LED3 having different heights H1-H3 can achieve a better electrical connection effect through the upper electrode leads 5141-5143 extending to the opening OP without causing a poor connection situation as described in FIG. 3 because the light-emitting element is in an under-configured state (e.g., LED2) or an over-configured state (e.g., LED3). Furthermore, since the height difference of each of the light-emitting elements LED1-LED3 can be compensated to the same height by the upper electrode leads 5141-5143 extending to the opening, the entire upper electrode lead 5141 (including a partial line segment located on the upper side surface of the protective layer 513) can have a uniform line width. This ensures the transmission of electrical signals while avoiding manufacturing process risks such as broken wires, poor contact due to bent traces.

In other words, by the above-described structural configuration of FIG. 4A, the upper surfaces of all the light-emitting elements LED1-LED3 can be substantially maintained at the same level without high-low differences, so that subsequent manufacturing processes are not affected by the flatness of the LED module, thereby effectively improving manufacturing process yield and reliability.

In this embodiment, the substrate 511 may be a flexible or rigid substrate such as a printed circuit board, a glass substrate, or a thin film substrate, and the substrate 511 may be transparent or opaque depending on the material chosen and the type of application desired, and the present disclosure is not limited thereto.

In some embodiments, the material of the adhering part AD may be any material capable of providing an adhesive force to stably bond the light-emitting elements LED1-LED3 and the first line layer 512, such as a tin paste, an anisotropic conductive film (ACF), or the like with adhesive properties. Further, the bonding process for disposing the light-emitting elements LED1-LED3 on the first line layer 512 through the adhering part AD may be screen bonding, ink-jet printing (IJP) bonding, exposure development plus baking, or the like, and the present disclosure is not limited thereto.

Referring to FIG. 4B, the LED module 510b of this embodiment is substantially the same as the embodiment of FIG. 4A in that it includes a substrate 511, a first line layer 512, a plurality of light-emitting elements LED1-LED3, a protective layer 513, a second line layer 514, and a light shielding part 515. The description of the relevant elements/configurations may refer to the embodiment of FIG. 4A described above and will not be repeated here.

The main difference between this embodiment and the previous FIG. 4A embodiment is that the LED module 510b further includes a conducting extended part 516. The conducting extended part 516 is disposed within the corresponding opening OP of the light-emitting element LED2 and is electrically connected to the upper electrode of the light-emitting element LED2, wherein the height of the conducting extended part 516 is less than or equal to the depth of the opening OP of the light-emitting element LED2, and the upper electrode lead 5142 is electrically connected to the upper electrode of the conducting extended part LED2 through the conducting extended part 516.

Specifically, the light-emitting element LED2 of this embodiment is in an under-configured state (H2<H1), and because the height may be too low, the upper electrode lead 5142 cannot be directly connected to the upper electrode of the light-emitting element LED2 extending through the opening OP. In this case, the equivalent height of the light-emitting element LED2 (i.e., the sum of the height H2 and the height of the conducting extended part 516) can be pulled high by disposing the conducting extended part 516 so that the upper electrode lead 5142 can be electrically connected to the upper electrode of the light-emitting element LED2 through the conducting extended part 516.

It should be noted here that the conducting extended part 516 of this embodiment may be provided only in the opening of the light-emitting element having a too low height, and other light-emitting element which may be directly connected to the upper electrode lead may not need to have a similar arrangement.

Referring to FIG. 4C, the LED module 510c of this embodiment is substantially the same as the embodiments of FIGS. 4A and 4B, and includes a substrate 511, a first line layer 512, a plurality of light-emitting elements LED1-LED3, a protective layer 513, a second line layer 514, and a light shielding part 515. The description of the relevant elements/configurations can be referred to above with reference to the embodiments of FIG. 4A and FIG. 4B and will not be repeated here.

The main difference between this embodiment and the previous embodiment of FIG. 4B is that the LED module 510c includes a plurality of conducting extended parts 5161-5163 respectively corresponding to the light-emitting elements LED1-LED3, wherein the conducting extended parts 5161-5163 are respectively disposed within the opening OP of the light-emitting elements LED1-LED3 and electrically connected to the upper electrodes of the corresponding light-emitting elements LED1-LED3.

In this embodiment, each conducting extended part 5161-5163 fills the corresponding opening OP such that the upper side surface of the conducting extended part 5161-5163 and the upper side surface of the protective layer 513 lie substantially in the same plane. In other words, the height H1-H3 of each of the light-emitting elements LED1-LED3 plus the height of the corresponding conducting extended part 5161-5163 will be equal to the height of the protective layer 513.

It should be noted here that the conducting extended part 5161-5163 of this embodiment may be provided in the opening OP of each of the light-emitting elements LED1-LED3 such that the equivalent height of each of the light-emitting elements LED1-LED3 is equal to the height of the protective layer 513. In this manner, the upper electrode leads 5141-5143 formed on the protective layer 513 are extended in the horizontal direction to be connected to the conducting extended part 5161-5163, and the upper electrodes of the corresponding light-emitting elements LED1-LED3 are electrically connected through the conducting extended part 5161-5163. Therefore, the upper electrode leads 5141-5143 of this embodiment can maintain a uniform line width to achieve better electric signal transmission characteristics.

Referring to FIG. 4D, the LED module 510d of this embodiment is substantially the same as the embodiment of FIG. 4A, including a substrate 511, a first line layer 512, a plurality of light-emitting elements LED1-LED3, a protective layer 513, a second line layer 514, and a light shielding part 515. The description of the relevant elements/configurations may refer to the embodiment of FIG. 4A described above and will not be repeated here.

The main difference of this embodiment from the aforementioned embodiment of FIG. 4A is that the protective layer 513 of the LED module 510d includes a spacer part 5131 and a flat part 5132, wherein the spacer part 5131 is provided on the substrate 511, and covers the first line layer 512, the adhering part AD, and a partial region of the light-emitting elements LED1-LED3; the flat part 5132 is disposed on the spacer part 5131 to cover another partial region of the light-emitting elements LED1-LED3 and expose the upper electrodes of the light-emitting elements LED1-LED3. The sum of the heights of the spacer part 5131 and the flat part 5132 (i.e., the height of the protective layer 513) of this embodiment is set to be greater than or equal to the maximum height of the light-emitting elements LED1-LED3 to form an opening OP on at least one or a portion of the light-emitting elements LED1-LED3. The second line layer 514 is disposed on the flat part 5132, and is electrically connected to the light-emitting elements LED1-LED3 through the opening OP.

Specifically, compared to the aforementioned FIG. 4A embodiment, the protective layer 513 of this embodiment can be implemented using a two-layer structure, wherein the lower structure (spacer 5131) primarily provides insulating and supporting characteristics, while the upper structure (flat part 5132) primarily provides a planar upper surface, and is selected from a material that can be removed based on a particular manufacturing process, such that the upper electrode of light-emitting elements LED1-LED3 can be exposed after the removal manufacturing process. Therefore, the surface flatness of the LED module 510d can be further improved by the structural configuration of FIG. 4D.

In some embodiments, the spacer 5131 may be implemented with a material having filling and insulating properties, such as SiNx, SiOx, acrylic, epoxy, or silicon-based macromolecular organic polymer, and the present disclosure is not limited thereto. On the other hand, the flat part 5132 may be implemented using a material having a surface flatness that is preferable after coating, such as acryl, epoxy, or silicon-based macromolecular organic polymer, and the like, and the present disclosure is not limited thereto.

Referring to FIG. 4E, the LED module 510e of this embodiment is substantially the same as the embodiments of FIGS. 4B and 4D, and includes a substrate 511, a first line layer 512, a plurality of light-emitting elements LED1-LED3, a protective layer 513, a second line layer 514, a light shielding part 515, and a conducting extended part 516. The description of the relevant elements/configurations can be referred to above with reference to the embodiments of FIG. 4B and FIG. 4D and will not be repeated here.

The main difference between this embodiment and the aforementioned embodiment of FIG. 4B is that the protective layer 513 of the LED module 510e adopts a two-layer structure configuration as in FIG. 4D, which includes the spacer part 5131 and the flat part 5132, wherein the relevant configurations and materials for the spacer part 5131 and the flat part 5132 can be referred to the aforementioned embodiment of FIG. 4D, which will not be repeated here.

Referring to FIG. 4F, the LED module 510f of this embodiment is substantially the same as the embodiment of FIGS. 4C and 4D, and includes a substrate 511, a first line layer 512, a plurality of light-emitting elements LED1-LED3, a protective layer 513, a second line layer 514, a light shielding part 515, and a plurality of conducting extended parts 5161-5163. The description of the relevant elements/configurations can be referred to above with reference to the embodiment of FIG. 4C and FIG. 4D, and a description thereof will not be repeated here.

The main difference between this embodiment and the aforementioned embodiment of FIG. 4C is that the protective layer 513 of the LED module 510f adopts a two-layer structure configuration as in FIG. 4D, which includes the spacer part 5131 and the flat part 5132, wherein the relevant configurations and materials for the spacer part 5131 and the flat part 5132 can be referred to the aforementioned embodiment of FIG. 4D, which will not be repeated here.

FIG. 4G is a schematic cross-sectional structure of an LED module according to an embodiment of the present disclosure. Referring to FIG. 4G, the LED module 610 of this embodiment includes a substrate 611, a first line layer 612, a plurality of light-emitting elements LED1-LED3, a protective layer 613, a second line layer 614, a light shielding part 615, and a support part 616. The first line layer 612 is disposed on the substrate 611. The light-emitting elements LED1-LED3 are respectively disposed on the first line layer 612 through the corresponding adhering parts AD, to make the lower electrodes of the light-emitting elements LED1-LED3 electrically connected to the first line layer 612 through the adhering parts AD. The protective layer 613 is formed on the substrate 611, and covers the first line layer 612, the adhering part AD, and the peripheral region of the light-emitting elements LED1-LED3, so as to prevent unintended short-circuiting between the adjacent light-emitting elements LED1-LED3, wherein the protective layer 613 will expose at least part or all of the upper electrodes of the light-emitting elements LED1-LED3, and the protective layer 613 will form a height/thickness on the substrate 611 that is substantially equal to the corresponding height HL of the light-emitting elements LED1-LED3. The corresponding height HL of any one of the light-emitting elements LED1-LED3 refers to herein may, for example, be the sum of the heights/thicknesses of any one of the light-emitting elements LED1-LED3 and its corresponding first line layer 612 and adhering part AD. A second line layer 614 and a light shielding part 615 are disposed on the protective layer 613 and the upper electrodes of the light-emitting elements LED1-LED3, wherein the second line layer 614 is electrically connected to the upper electrode of each of the light-emitting elements LED1-LED3. Further, in the protective layer 613, a support part 616 is provided between the adjacent light-emitting elements LED1-LED3. The support part 616 is used to provide a supporting force against a force to define an upper electrode position of the light-emitting elements LED1-LED3 during a manufacturing process in which the force is applied to the light-emitting elements LED1-LED3, wherein an upper side of the support part 616 and the upper electrodes of the light-emitting elements LED1-LED3 lie substantially in the same plane. In this embodiment, the support part 616 is, for example, columnar, and has a height less than or equal to the lowest of the light-emitting elements LED1-LED3, although the present disclosure is not limited thereto.

More specifically, the first line layer 612 includes lower electrode leads 6121-6123, and the second line layer 614 includes upper electrode leads 6141-6143. The lower electrodes of the light-emitting elements LED1-LED3 are electrically connected to the lower electrode leads 6121-6123 through the corresponding adhering part AD, respectively, wherein each of the light-emitting elements LED1-LED3 is applied with a planar force toward the substrate 611 during setting, so that the lower electrode of the light-emitting elements LED1-LED3 is embedded in the adhering part AD. Each of the light-emitting elements LED1-LED3 will have a different depth of embedding in the adhering part AD in response to its size/height difference, so that each of the light-emitting elements LED1-LED3 will have a corresponding difference in distance from the substrate 611. For example, as shown in FIG. 4G, the height Hl of the light-emitting element LED1 is greater than the height H2 of the light-emitting element LED2, therefore, upon application of a force, the light-emitting element LED1 is spaced from the substrate 611 less than the light-emitting element LED2 is spaced from the substrate 611, so that the sum of the height HI of the light-emitting element LED1 and the corresponding distance from the substrate 611 is substantially the same as the sum of the height H2 of the light-emitting element LED2 and the corresponding distance from the substrate 611, i.e. equal to the height HL. Similarly, the height HI of the light-emitting element LED1 is less than the height H3 of the light-emitting element LED3, therefore upon application of a force, the light-emitting element LED1 is spaced from the substrate 611 by a greater distance than the light-emitting element LED3 is spaced from the substrate 611, such that the sum of the height H1 of the light-emitting element LED1 and the corresponding distance from the substrate 611 is substantially the same as the sum of the height H3 of the light-emitting element LED3 and the corresponding distance from the substrate 611.

With the above arrangement, the light-emitting elements LED1-LED3 having different heights H1-H3 will have different distances from the substrate, so that the corresponding sum height HL of each of the light-emitting elements LED1-LED3 is substantially uniform, thereby forming a flat surface on the LED module. As such, the poor connection situation as described in FIG. 3 will not occur because the light-emitting element is in an under-configured state (e.g., LED2) or an over-configured state (e.g., LED3). Furthermore, since the height difference H1-H3 of each of the light-emitting elements LED1-LED3 has been compensated to the same height HL by different distances from the substrate, the upper electrode leads 6141-6143 as a whole can have a uniform line width. Thus, the transmission of electrical signals can be ensured, while also avoiding the risk of manufacturing processes such as broken wires, poor contact due to bent traces.

In other words, by the above-described structural configuration of FIG. 4G, the upper surfaces of all the light-emitting elements LED1-LED3 can be substantially maintained at the same level without high-low differences, so that the subsequent manufacturing process is not affected by the flatness of the LED module, thereby effectively improving manufacturing process yield and reliability.

In this embodiment, the substrate 611 may be a flexible or rigid substrate such as a printed circuit board, a glass substrate, or a thin film substrate, and the substrate 611 may be transparent or opaque depending on the material selected and the type of application desired, although the present disclosure is not limited thereto.

In some embodiments, the material of the adhering part AD may be any material having an adhesive force capable of providing a stable bonding of the light-emitting elements LED1-LED3 and the first line layer 612, such as a tin paste, an anisotropic conductive film (ACF), or the like. Further, the bonding process of disposing the light-emitting elements LED1-LED3 on the first line layer 612 through the adhering part AD may be screen bonding, ink-jet printing (IJP) bonding, exposure development plus baking, or the like, although the present disclosure is not limited thereto.

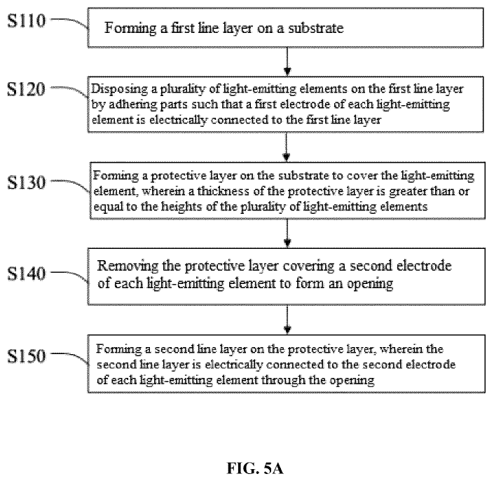

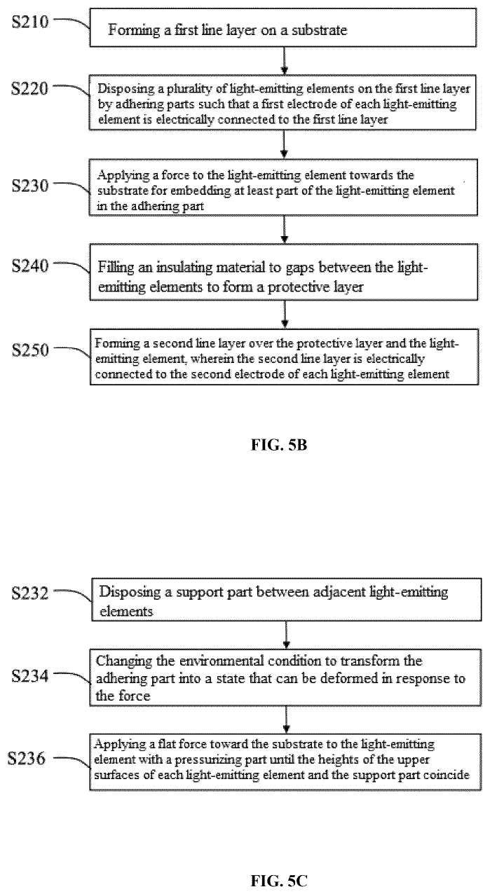

FIG. 5A is a flowchart illustrating steps of a method of manufacturing an LED module according to an embodiment of the present disclosure. The manufacturing method of the LED module of this embodiment may be applicable to manufacturing the LED modules 510a-510f as described in FIGS. 4A to 4F. Referring to FIG. 5A, the manufacturing method of the LED module of this embodiment includes the steps of: forming a first line layer (e.g., 512) on a substrate (e.g., 511) (step S110); disposing a plurality of light-emitting elements (e.g., LED1-LED3) on the first line layer by adhering parts (e.g., AD) such that a first electrode (e.g., a lower electrode of the light-emitting element) of each light-emitting element is electrically connected to the first line layer (step S120); forming a protective layer (e.g., 513) on the substrate to cover the light-emitting element, wherein a thickness of the protective layer is greater than or equal to a height of one of the plurality of light-emitting elements having the largest height (e.g., LED3) (step S130); removing the protective layer covering a second electrode (e.g., the upper electrode of the light-emitting element) of each light-emitting element to form an opening (e.g., OP) (step S140); and forming a second line layer (e.g., 514) on the protective layer, wherein the second line layer is electrically connected to the second electrode of each light-emitting element through the opening (step S150).

FIG. 5B is a flowchart illustrating steps of a method of manufacturing an LED module according to an embodiment of the present disclosure. The manufacturing method of the LED module of this embodiment may be applicable to manufacturing the LED module 610 as described in FIG. 4G. Referring to FIG. 5B, the manufacturing method of the LED module of this embodiment includes the steps of: forming a first line layer (e.g., 612) on a substrate (e.g., 611) (step S210); disposing a plurality of light-emitting elements (e.g., LED1-LED3) on the first line layer by adhering parts (e.g., AD) such that a first electrode (e.g., a lower electrode of the light-emitting element) of each light-emitting element is electrically connected to the first line layer (step S220); applying a force to the light-emitting element towards the substrate for embedding at least part of the light-emitting element in the adhering part (step S230) for allowing the upper side of the light-emitting element to be maintained in the same plane; filling an insulating material to gaps between the light-emitting elements to form a protective layer (e.g., 613) (step S240); and forming a second line layer (e.g., 614) over the protective layer and the light-emitting element, wherein the second line layer is electrically connected to the second electrode (e.g., the upper electrode of the light-emitting element) of each light-emitting element (step S250).

In some embodiments, step S230 described above may be further implemented using the step flow of FIG. 5C. Referring to FIG. 5C, in this embodiment, after step S220 of preliminarily disposing the light-emitting element on the first line layer by an adhering part, the support part (e.g., 616) is disposed between adjacent light-emitting elements (step S232), and the environmental condition is changed to transform the adhering part into a state (e.g., a liquid state or a molten state) that can be deformed in response to the force (step S234). In the above step S234, the state of the adhering part can be converted, for example, by subjecting the LED module to a thermal treatment, wherein the adhering part is, for example, tin paste, which is molten and can be deformed when pushed by light-emitting element to bring the light-emitting element closer to the substrate. After the state of the adhering part is changed, a flat force toward the substrate is applied to the light-emitting element with a pressurizing part until the heights of the upper surfaces of each light-emitting element and the support part coincide (Step S236).

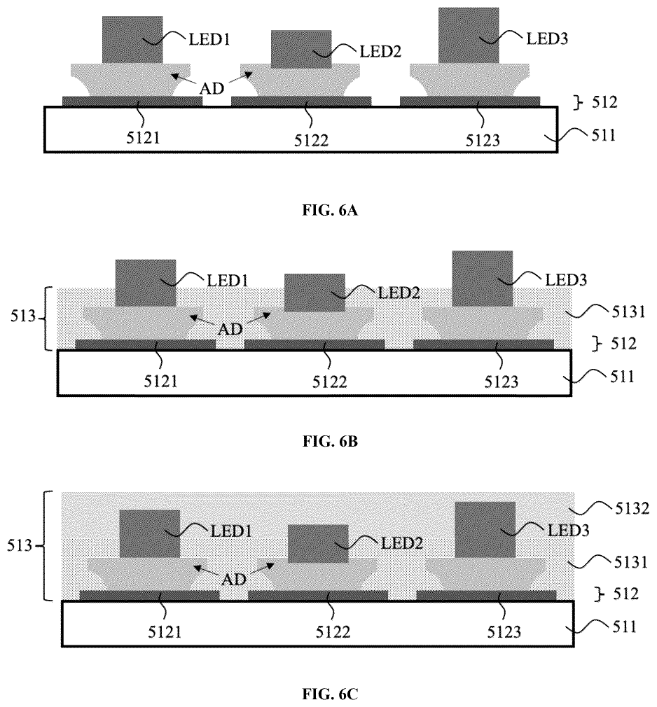

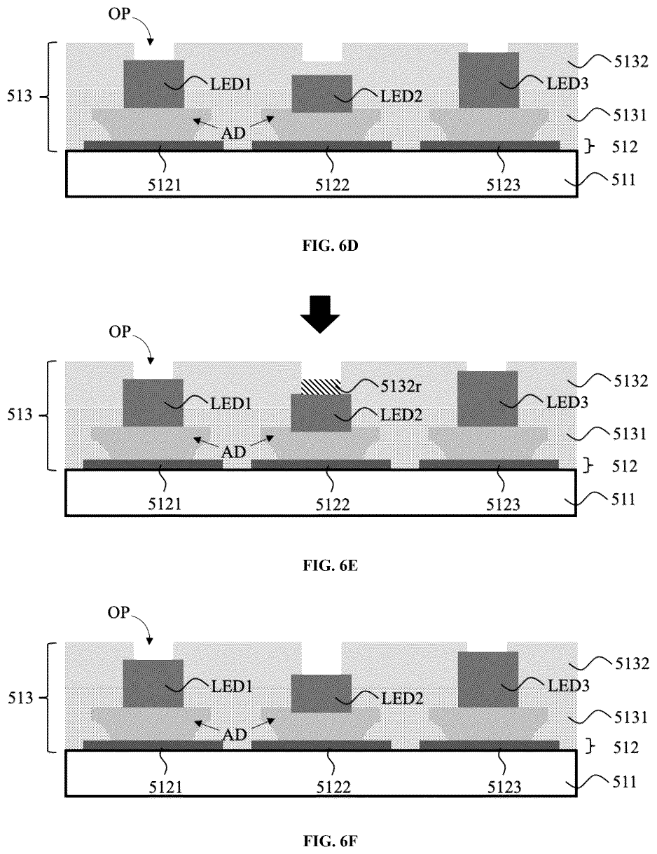

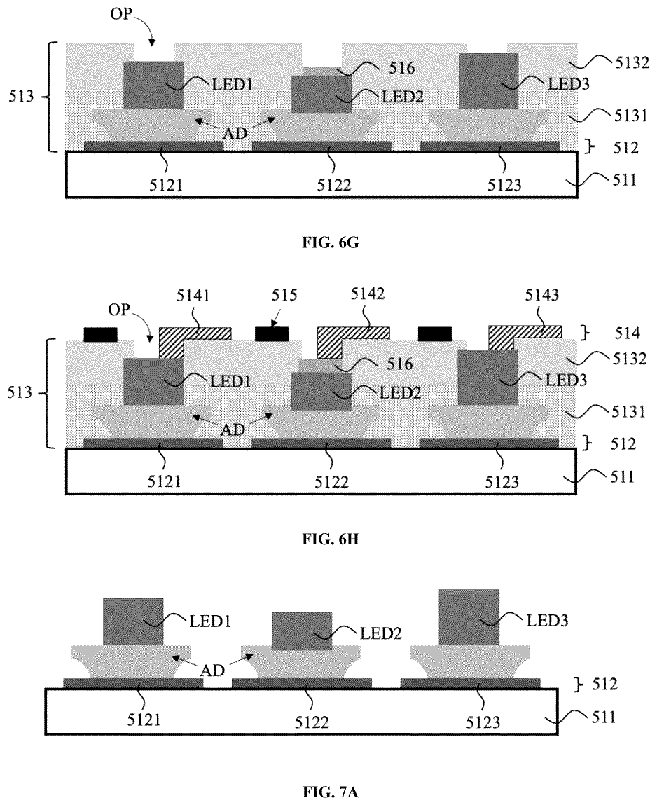

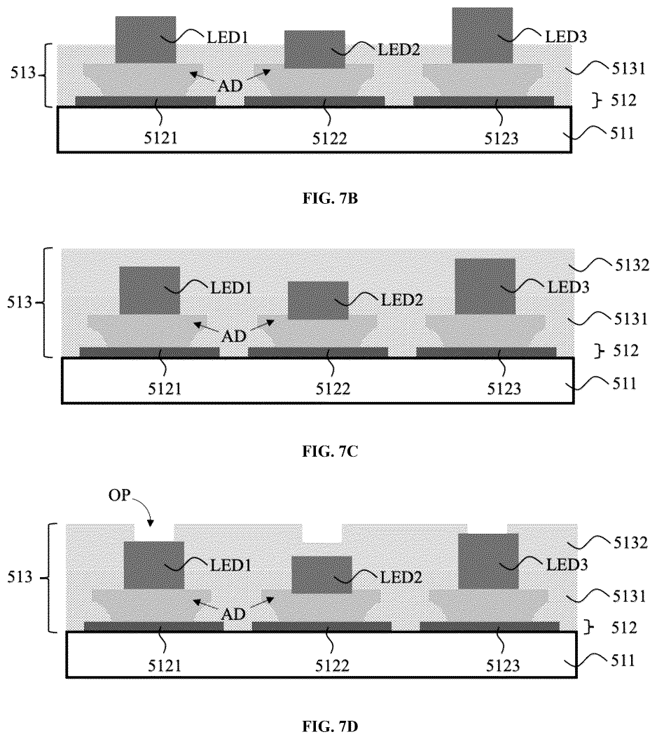

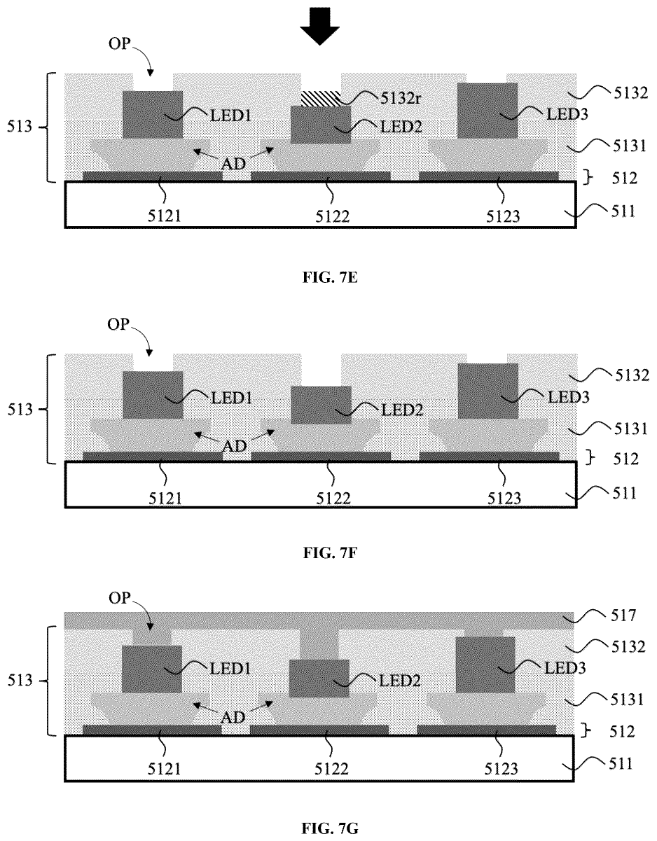

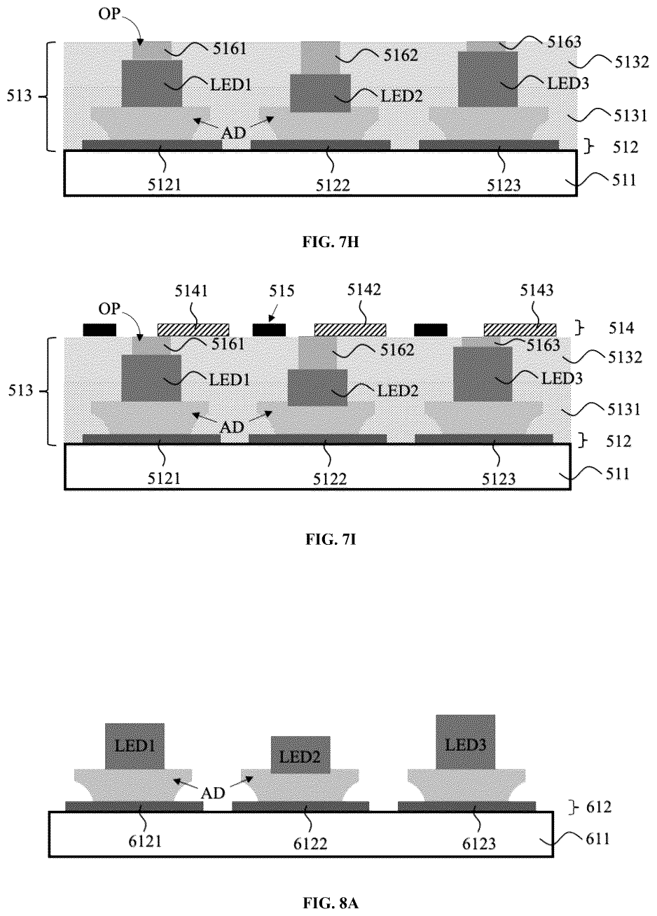

Next, a step flow for manufacturing an LED module 510e having the structural configuration of FIG. 4E based on the manufacturing method of FIG. 5A will be described with reference to FIGS. 6A to 6H, and a step flow for manufacturing an LED module 510f having the structural configuration of FIG. 4F based on the manufacturing method of FIG. 5A will be described with reference to FIGS. 7A to 71.

Referring to FIG. 6A, in steps S110 and S120, the lower electrode leads 5121-5123 of the first line layer 512 are formed on the substrate 511, and the light-emitting elements LED1-LED3 are disposed on the corresponding lower electrode leads 5121-5123 of the first line layer 512 through the corresponding adhering parts AD, respectively, so that the lower electrodes of the light-emitting elements LED1-LED3 and the lower electrode leads 5121-5123 are electrically connected.

In step S130, as shown in FIG. 6B, the spacer part 5131 in the protective layer 513 is first formed on the substrate 511, and cover the lower electrode leads 5121-5123, the adhering part AD, and partial regions of the light-emitting elements LED1-LED3 and fill the spaces between the light-emitting elements LED1-LED3. Next, as shown in FIG. 6C, a flat part 5132 in the protective layer 513 is further formed on the spacer part 5131 and covers the light-emitting elements LED1-LED3, wherein the thickness of the protective layer 513 (i.e., the thickness of the spacer part 5131 plus the thickness of the flat part 5132) is greater than or equal to the one (e.g., LED3) having the largest height among the light-emitting elements LED1-LED3.

In step S140, the flat part 5132 may be removed from its portion covering the upper electrodes of the light-emitting elements LED1-LED3 by a removal manufacturing process (e.g., a photolithography manufacturing process) to expose the upper electrodes of the light-emitting elements LED1-LED3. In this embodiment, as exemplified by the extreme case where the electrode positions of the light-emitting elements LED1-LED3 are not uniform in height, the light-emitting element LED2 in the lower position may not expose the upper electrode after the removal manufacturing process due to a thicker thickness of the flat part 5132 overlying the electrode of the light-emitting element LED2.

In this case, the act of detecting and removing the residual covering material may be further performed in step S140, as shown in FIGS. 6E and 6F. The flat part 5132r remaining to cover the upper electrode of the light-emitting element LED2 can be determined by inspection and removed purposely. For example, automatic optical inspection (AOI) equipment may be used in some applications to determine which positions of the upper electrode are not exposed by autofocus and depth-of-field algorithms, and then remove the remaining flat part 5132r overlying the upper electrode using a laser to form a complete opening and expose the upper electrode of the lower light-emitting element LED2.

In step S150, since the light-emitting element LED2 has been calibrated to be lower, a conducting extended part 516 electrically connected to the upper electrode of the light-emitting element LED2 is first formed in the opening OP of the light-emitting element LED2 in step S150, as shown in FIG. 6G. Next, a second line layer 514 for connecting upper electrodes of the light-emitting elements LED1-LED3 and a light shielding part 515 are formed on the flat part 5132, and the upper electrode leads 5141-5143 of the second line layer 514 are extended to be connected to the light-emitting elements LED1-LED3 through the corresponding openings OP so that the upper electrodes of the light-emitting elements LED1-LED3 are electrically connected to the corresponding upper electrode leads 5141-5143, wherein the upper electrode leads 5142 of the light-emitting element LED2 are electrically connected to the upper electrode of the light-emitting element LED2 through the conducting extended part 516 due to the lower position of the light-emitting element LED2, as shown in FIG. 6H. The structural configuration of the LED module 510e as shown in FIG. 4E was successfully fabricated so far.

After the above description, those skilled in the art may also realize the structural configurations of FIGS. 4A, 4B, and 4D by omitting specific actions of the above steps. For example, to fabricate the LED module 510a as illustrated in FIG. 4A, it is only necessary to implement the single-layer structure in the step of forming the protective layer 513, and omit the action of forming the conducting extended part 516 in the step S150. For another example, to fabricate the LED module 510b as illustrated in FIG. 4B, it is only necessary to implement a single-layer structure in the step of forming the protective layer 513. As another example, to fabricate the LED module 510d as illustrated in FIG. 4D, it is only necessary to omit the action of forming the conducting extended part 516 in step S150.

Hereinafter, the step flow for manufacturing the LED module 510f shown in FIG. 4F is further described with reference to FIGS. 7A to 71, wherein FIGS. 7A to 7F corresponding to steps S110 to S140 are similar/identical to the aforementioned FIGS. 6A to 6F, so that the related description may refer to the above-described embodiments, and the description will not be repeated here.

The main difference between this embodiment and the previous embodiment of FIGS. 6A-6H is that after forming the structure in which the upper electrode is exposed with the opening OP (as shown in FIG. 7F), an additional conductive layer 517 is formed on the flat part 5132 at step S150, wherein the conductive layer 517 fills the opening OP of each of the light-emitting elements LED1-LED3 and has a certain height on the flat part 5132, as shown in FIG. 7G. The conductive layer 517 may be implemented in a metallic material, for example.

Next, the conductive layer 517 may be subjected to a surface cleaning manufacturing process (e.g., a chemical/mechanical polishing manufacturing process) to remove a portion of the conductive layer 517 on an upper side of the flat part 5132 and expose an upper surface of the flat part 5132; the portions of the conductive layer 517 filled in the openings OP are left, forming the conducting extended part 5161-5163 of the light-emitting elements LED1-LED3, respectively, as shown in FIG. 7H.

Next, a second line layer 514 for connecting upper electrodes of the light-emitting elements LED1-LED3 and a light shielding part 515 are formed on the flat part 5132, and upper electrode leads 5141-5143 of the second line layer 514 are connected to the light-emitting elements LED1-LED3 through the corresponding conducting extended part 5161-5163 so that the upper electrodes of the light-emitting elements LED1-LED3 are electrically connected to the corresponding upper electrode leads 5141-5143, as shown in FIG. 7I. The structural configuration of the LED module 510f as shown in FIG. 4F was successfully fabricated.

In view of the above description, those skilled in the art may also implement the structural configuration of FIG. 4C by omitting certain actions of the above steps. For example, to fabricate the LED module 510c as illustrated in FIG. 4C, it is only necessary to implement a single-layer structure in the step of forming the protective layer 513.

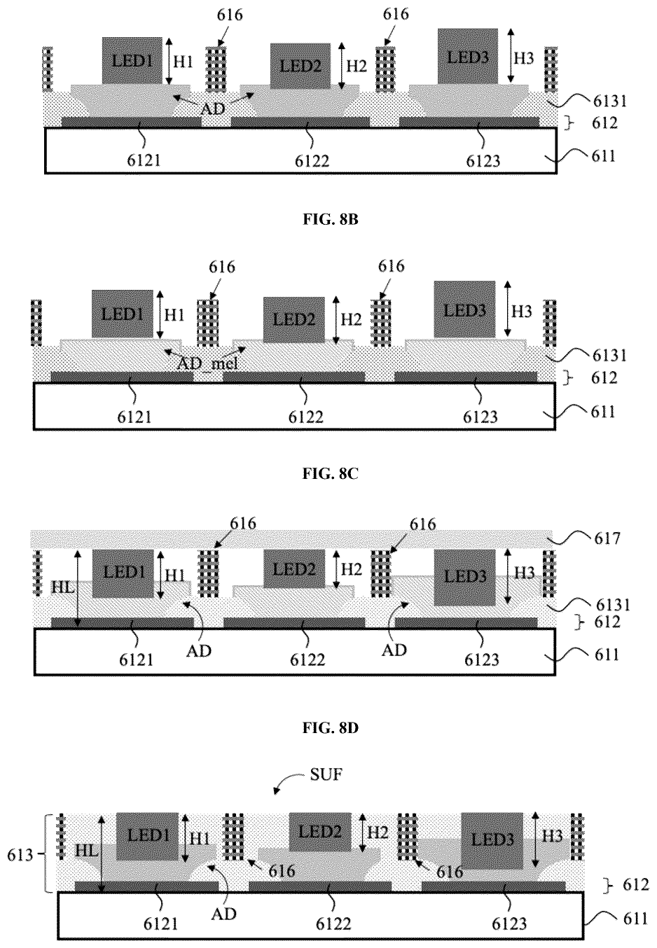

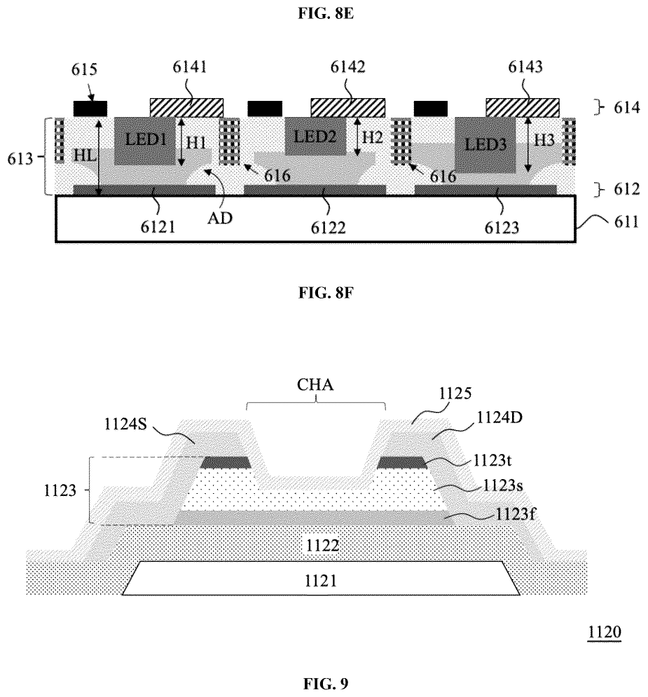

A step flow for manufacturing the LED module 610 having the structural configuration of FIG. 4G based on the manufacturing method of FIGS. 5B and 5C is described below with reference to FIGS. 8A to 8F.

Referring to FIG. 8A, in steps S210 and S220, the lower electrode leads 6121-6123 in the first line layer 612 are formed on the substrate 611, and the light-emitting elements LED1-LED3 are disposed on the corresponding lower electrode leads 6121-6123 of the first line layer 612 through the corresponding adhering parts AD, respectively, so that the lower electrodes of the light-emitting elements LED1-LED3 and the lower electrode leads 6121-6123 are electrically connected.

In step S230, as shown in FIG. 8B, first, an insulating material is filled between the adhering parts AD, and a spacer part 6131 has been formed on the substrate 611 to cover at least a partial region of the lower electrode leads 6121-6123 and the adhering parts AD, wherein the insulating material has not been filled between the light-emitting elements LED1-LED3 at the present step. Next, the support part 616 would be provided between the adjacent light-emitting elements LED1-LED3 and on the spacer part 6131, wherein the height of the support part 616 would be slightly less than the height H2 of the light-emitting element LED2, such that the light-emitting elements LED1-LED3 would be displaced towards the substrate 611 when subjected to a force without the force being counteracted by the support part 616 before it has not yet acted on the light-emitting element LED2 whose height is the lowest.

Upon completion of the support part 616 arrangement, the LED module is heated to transition the state of the adhering part AD to the molten adhering part AD_mel, as shown in FIG. 8C. In some embodiments, the adhering part AD is tin paste, and the step S234 may be to put the LED module into a reaction chamber for vacuum processing, and heat the LED module under vacuum to re-flow the tin paste. The pressure range of the vacuum treatment may be, for example, less than 100 Pascal (pa), and the temperature of the heating may be, for example, between 100° C. and 300° C. The selections of the vacuum level and temperature may ensure that the state of the adhering part AD is transformed into a state that is deformable in response to a force without compromising the material/component properties.

Next, as shown in FIG. 8D, a pressurizing part 617 is used to apply a force to the light-emitting elements LED1-LED3 toward the substrate 611 to displace the light-emitting elements LED1-LED3 toward the substrate 611. During the application of force, the adhering part in a molten state, AD_mel, overflows outwardly by being pressed by the light-emitting elements LED1-LED3; in this case, the support part 616 acts as a barrier to prevent the adhering part AD from shorting with the adjacent light-emitting element/adhering part. The pressurizing part 617 continues to apply the force toward the substrate 611 until it abuts against the support part 616 and the force is counteracted by the support part 616, so that the heights of the upper surfaces of the light-emitting elements LED1-LED3 and the support part 616 are substantially uniform (step S236), that is, the overall height of each of the light-emitting elements LED1-LED3 is substantially the height HL. In this embodiment, the pressurizing part 617 may be made of, for example, glass or metal, which has a certain degree of rigidity and is not easily deformable, and may be shaped as a flat plate with a flat surface, although the present disclosure is not limited thereto.

Upon completion of step S230, the pressurizing part 617 is removed, and the LED module is left to resume the original state of the adhering part AD. Next, in step S240, an insulating material is further filled into the gap between the light-emitting elements LED1-LED3 and the support part 616 to form a protective layer 613 integrally with the insulating material previously filled as the spacer part 6131. Therein, the upper surface of the protective layer 613 will also be substantially flush with the light-emitting elements LED1-LED3 and the support part 616, thereby forming a flat module surface SUF, as shown in FIG. 8E.

Next, a second line layer 614 for connecting upper electrodes of the light-emitting elements LED1-LED3 and a light shielding part 615 are formed on the module surface SUF, and upper electrode leads 6141-6143 of the second line layer 614 are electrically connected to the light-emitting elements LED1-LED3, as shown in FIG. 8F. The structural configuration of the LED module 610 as shown in FIG. 4G was successfully fabricated so far.

It should be noted here that the above-described structural configuration may be applied to only a partial region or the entire region of the LED module. In other words, it is within the scope of the present disclosure to disclose and protect any LED module having at least a partial region of its light-emitting element in accordance with the above-described structural configuration or fabricated by the above-described method.

The structural design of the display panel 100′ in the display device 10/30 is further described below.

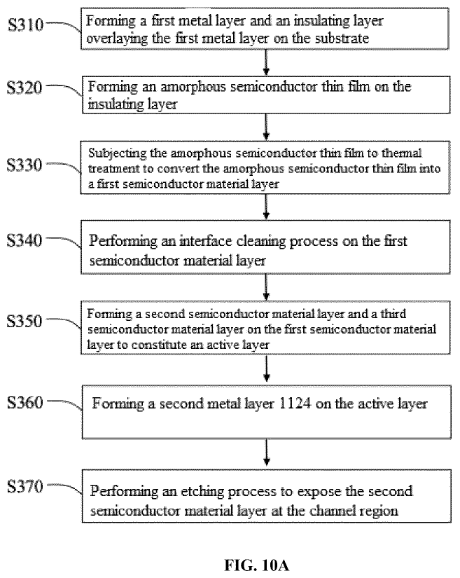

In some embodiments, the structural configuration of the thin-film transistor described above with reference to the embodiments of FIGS. 1C and 1D may be as shown in FIG. 9, wherein FIG. 9 is a cross-sectional structural diagram of a thin-film transistor according to an embodiment of the present disclosure. Referring to FIG. 9, the thin-film transistor 1120 includes a gate 1121, an insulating layer 1122, an active layer 1123, a source 1124S, and a drain 1124D. The gate 1121, the insulating layer 1122, and the active layer 1123 are sequentially arranged in a stack from bottom to top (based on the illustrated direction), in which the source 1124S and the drain 1124D are formed on two ends of the active layer 1123, respectively, and a middle region of the active layer 1123 is etched to form a channel region CHA.

The gate 1121, the source 1124S, and the drain 1124D may be formed of, for example, molybdenum (Mo), aluminum (Al), titanium (Ti), copper (Cu), or a stacked combination thereof, although the present disclosure is not limited thereto. The insulating layer 1122 may be a non-metallic dielectric material, such as silicon dioxide (SiOx), silicon nitride (SiNx), or a stacked combination thereof, although the present disclosure is likewise not limited thereto.

The active layer 1123 of this embodiment has a three-layer stacked structure at both end portions, which includes a first semiconductor material layer 1123f, a second semiconductor material layer 1123s, and a third semiconductor material layer 1123t sequentially stacked from bottom to top. The first semiconductor material layer 1123f is formed on the insulating layer 1122 and has an ordered lattice structure, such as microcrystalline silicon or polycrystalline silicon. The second semiconductor material layer 1123s is formed on the first semiconductor material layer 1123f, and has a disordered lattice structure, such as amorphous silicon (a-Si). A third semiconductor material layer 1123t is formed on the two sides of the second semiconductor material layer 1123s, wherein the third semiconductor material layer 1123t has a disordered lattice structure, and is doped with N-type ions. In other words, on both ends of the active layer 1123, the second semiconductor material layer 1123s and the third semiconductor material layer 1123t may both be consisting of amorphous silicon, with a difference that the third semiconductor material layer 1123t has a higher N-type ion concentration than the second semiconductor material layer 1123s does.

On the other hand, the thickness of the active layer 1123 within the channel region CHA may be smaller than the thickness outside (i.e., both end portions) of the channel region CHA, and the active layer 1123 within the channel region CHA may be subjected to an etching process to remove the third semiconductor material layer 1123t and the second semiconductor material layer 1123s may be exposed. In other words, there will only be a two-layer structure of the first semiconductor material layer 1123f and the second semiconductor material layer 1123s within the channel region CHA.

The thin-film transistor 1120 having the active layer 1123 consisting of the structure of the first to third semiconductor material layers 1123f to 1123t described above has higher carrier mobility than a conventional amorphous silicon thin-film transistor. With the structure in this example, the carrier mobility can be increased to 6 to 8 cm²/V×SM; in some embodiments, when the drain-source voltage is 10 V, the breakover current can reach 10⁻⁵ A, which is more than 10 times that of a conventional amorphous silicon thin-film transistor.

In addition, in this embodiment, the native semiconductor oxide (e.g., SiOx) between the first semiconductor material layer 1123f and the second semiconductor material layer 1123s is mostly removed such that there is substantially no semiconductor oxide present at the interface between the first semiconductor material layer 1123f and the second semiconductor material layer 1123s. Thus, substantially good bonding between the first semiconductor material layer 1123f and the second semiconductor material layer 1123s is possible without film peeling, and such that element characteristics such as carrier mobility and switching ratio of the thin-film transistor 1120 can be effectively improved.

It should be noted here that the carrier mobility of the thin-film transistor 1120 is significantly improved over a conventional amorphous silicon thin-film transistor, but the threshold voltage may be relatively low. In some embodiments, in order that the electrical property of the thin-film transistor 1120 may be more optimized, the first semiconductor material layer 1123f may also be doped with Group 3A ions (i.e., Boron group) by way of ion implantation in the manufacturing process, wherein the doped Group 3A ions form covalent bonds with the semiconductor material in the first semiconductor material layer 1123f and then provide holes to shift the current-voltage characteristic curve of the thin-film transistor to the right, so that the threshold voltage can be raised, thereby effectively improving the problem of lower threshold voltage. In some embodiments, the ion concentration of Group 3A ions implanted in the first semiconductor material layer 1123f may be between 10¹²-10¹³ ions/cm³, although the present disclosure is not limited thereto. In embodiments where boron ions are implanted, the ion concentration may be, for example, 2×10¹², 4×10¹² or 6×10¹², and the implantation energy may be, for example, 10-20 keV, and the chamber may be, for example, ambient temperature, although the present disclosure is likewise not limited thereto.

In addition to this, the thin-film transistor generally having the structure of FIG. 9 may have a high leakage current (Ioff) compared to a conventional amorphous silicon thin-film transistor due to the side walls of its active layer having more broken links and carrier after etching. In the case where the leakage current is high, the display to which the thin-film transistor is applied has problems of poor contrast, whitening, flickering and the like when displaying a picture. In some embodiments, in order that the electrical property of the thin-film transistor 1120 may be more optimized, the active layer 1123 may be formed with a carrier removal process to reduce the number of free ions at the sidewall of the active layer 1123, thereby reducing the leakage current at the sidewalls.

The source 1124S and the drain 1124D are formed on two ends of the active layer 1123, respectively, and extend from a side surface of the active layer 1123 to cover a portion of the insulating layer 1122. More specifically, the source 1124S and the drain 1124D contact the top of the third semiconductor material layer 1123t (i.e., the side away from the second semiconductor material layer 1123s) and the sidewalls of the first semiconductor material layer 1123f, the second semiconductor material layer 1123s, and the third semiconductor material layer 1123t (i.e., the side of the active layer 1123 away from the channel region CHA), respectively, and contacts the top of the insulating layer 1122 (i.e., the side away from the gate 1121) via the extension of the sidewall.

In some embodiments, the thin-film transistor 1120 may further include a functional layer 1125 overlying the surface of the element, wherein the functional layer 1125 may be formed, for example, on a partial region or all of the exposed surfaces of the source 1124S, the drain 1124D, and the active layer 1123. In some embodiments, the functional layer 1125 may be, for example, a protective film of silicon nitride (SiN) or the like, although the present disclosure is not limited thereto.

It should also be noted that the breakover current of the thin-film transistor 1120 may instead be lower than a conventional amorphous silicon thin-film transistor if the drain source is applied with a low voltage (e.g., less than 1 V) due to the high signal transmission impedance between the source 1124S and the drain 1124D. In other words, where the drain-to-source voltage (Vds) of the thin-film transistor 1120 is lower, its switching ratio is lower than possible compared to conventional amorphous silicon thin-film transistor.

In some embodiments, by adjusting the thickness ratio of the second semiconductor material layer 1123s and the third semiconductor material layer 1123t during the manufacturing process, the problem that the breakover current of the drain-source electrode is low at a low voltage can be improved. For example, the second semiconductor material layer 1123s and the third semiconductor material layer 1123t can have a thickness ratio between 5:8 and 8:5 when the sum of the thicknesses is fixed.

In some embodiments, the sum of the thicknesses of the second semiconductor material layer 1123s and the third semiconductor material layer 1123t is approximately 1300 Å, where the thicknesses of the second semiconductor material layer 1123s are 500 Å, 600 Å, 700 Å, and 800 Å, the thicknesses of the third semiconductor material layer 1123t can be sequentially designed to be 800 Å, 700 Å, 600 Å, and 500 Å to maintain the breakover current magnitude with a low source-drain voltage. This section will be further described later with experimental results.

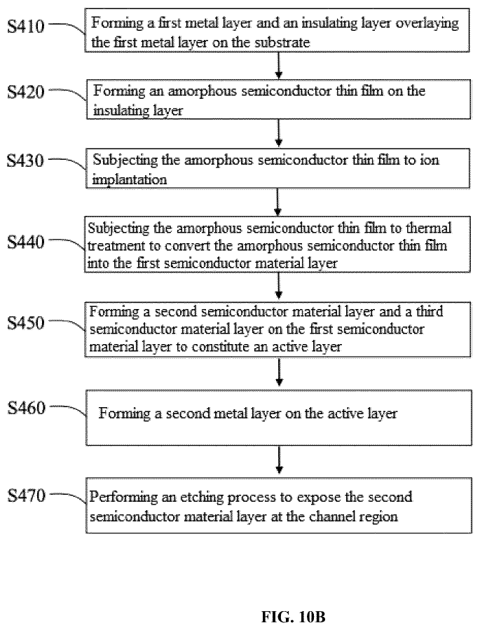

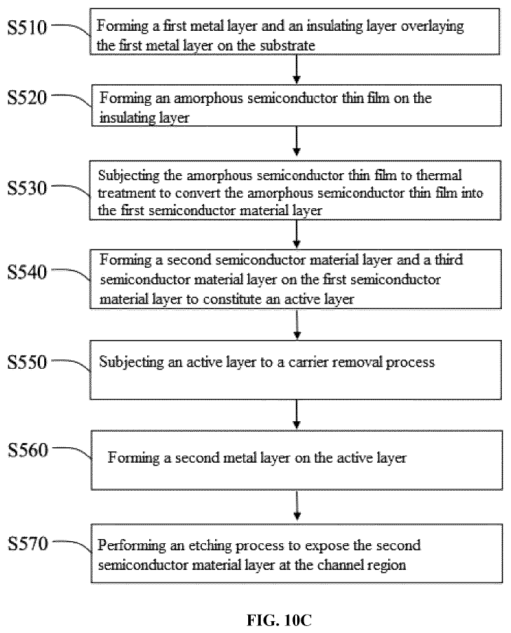

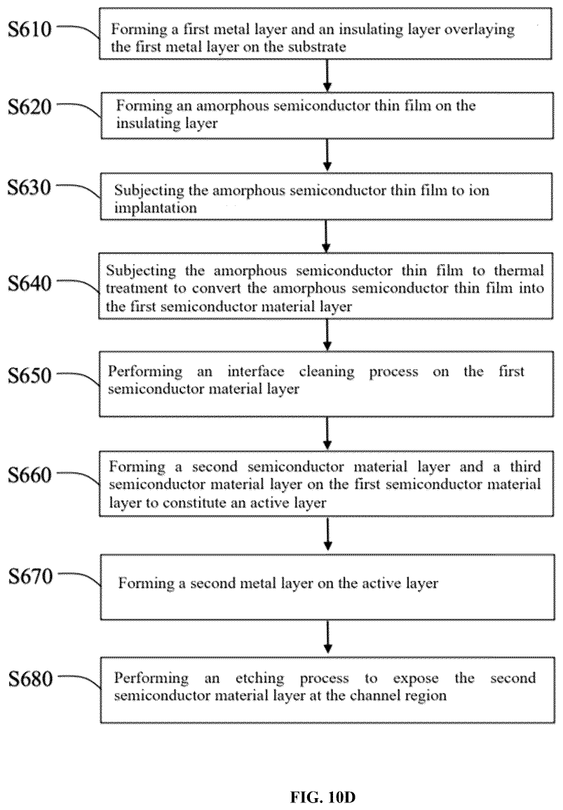

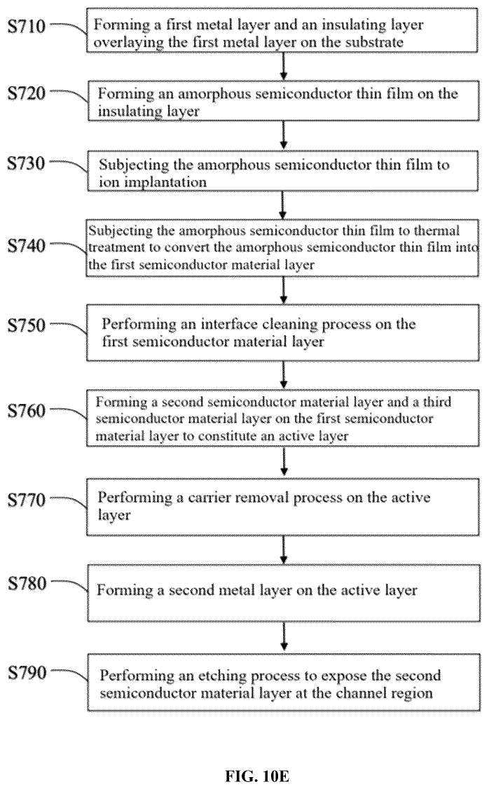

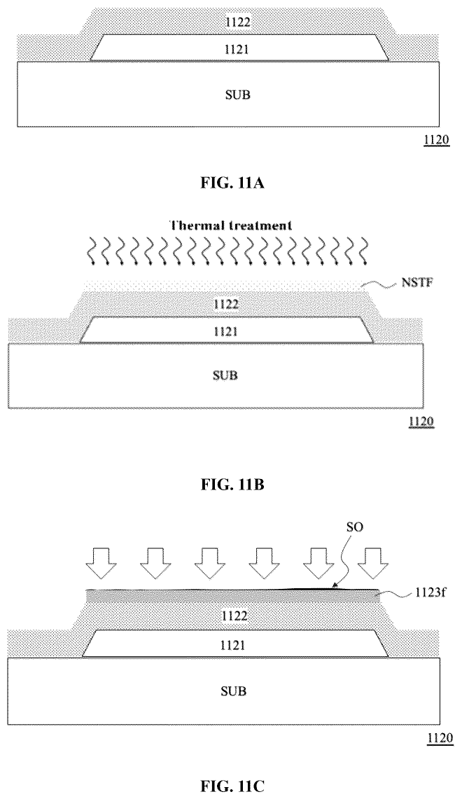

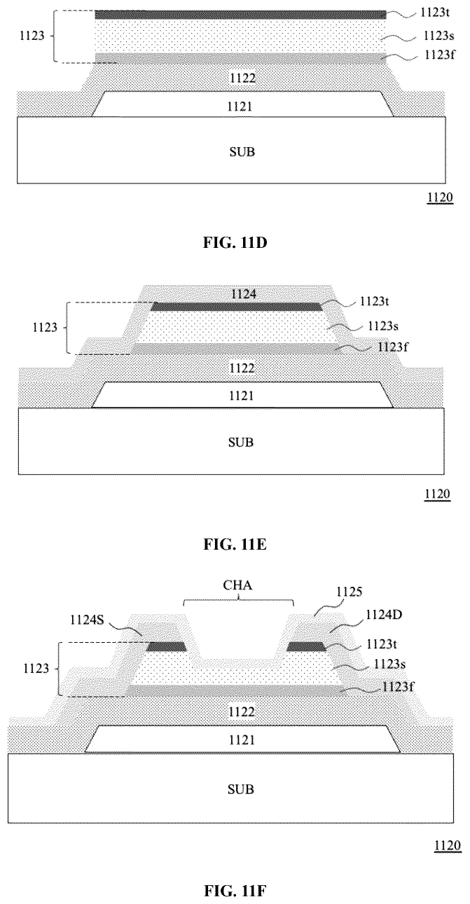

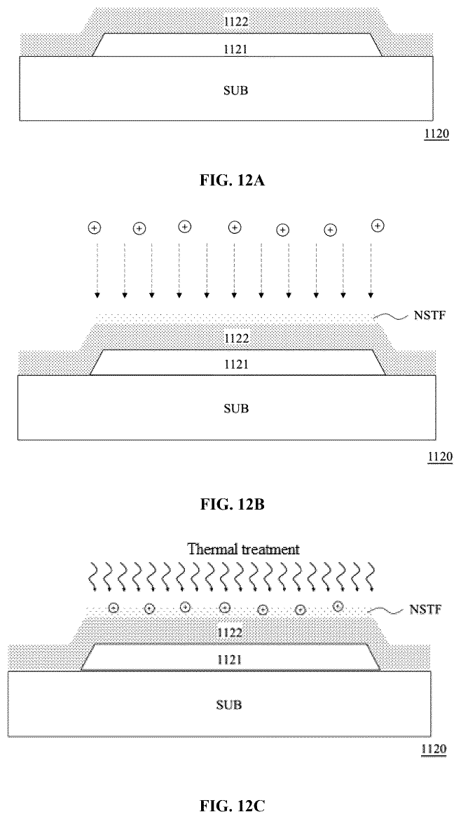

FIG. 10A is a flowchart illustrating the steps of a manufacturing method of a thin-film transistor according to an embodiment of the present disclosure, wherein the manufacturing method of FIG. 10A can be used to manufacture the thin-film transistor 1120 according to the embodiment of FIG. 9. A manufacturing flow of the thin-film transistor 1120 is described below with reference to FIGS. 11A to 11F, which are schematic flow diagrams of a manufacturing method according to the thin-film transistor of FIG. 10A.

Referring to FIGS. 10A and 11A, first, a first metal layer 1121 and an insulating layer 1122 overlaying the first metal layer 1121 are formed on the substrate SUB (step S310), wherein the first metal layer 1121 is used as a gate of the thin-film transistor 1120.

Next, referring to FIGS. 10A, 11B, and 11C, an amorphous semiconductor thin film NSTF is formed on the insulating layer 1122 (step S320), and the amorphous semiconductor thin film NSTF is subjected to thermal treatment to convert the amorphous semiconductor thin film NSTF into a first semiconductor material layer 1123f having an ordered lattice structure (step S330).

In some embodiments, the amorphous semiconductor thin film NSTF is, for example, amorphous silicon. The thermal treatment may be, for example, an Excimer Laser Annealing (ELA) technique of irradiating the amorphous silicon with an excimer laser to achieve a manufacturing process of modifying the amorphous silicon into microcrystalline silicon or polycrystalline silicon having an ordered lattice structure, i.e., the first semiconductor material layer 1123f, although the present disclosure is not limited thereto.

After the amorphous semiconductor thin film NSTF is converted into the first semiconductor material layer 1123f, this embodiment further performs an interface cleaning process on the first semiconductor material layer 1123f to remove the native semiconductor oxide SO to the surface of the first semiconductor material layer 1123f (step S340).

In some embodiments, the interface cleaning process may be performed by a surface treatment manufacturing process, such as a wet etching (e.g., chemical treatment), a dry etching (e.g., plasma treatment), or the like. In the interface cleaning treatment using the wet etching, a chemical solution corrosive to the semiconductor oxide SO, such as a diluted Buffered Oxide Etch (BOE), a diluted hydrofluoric acid (HF), or a chemical solution mixing hydrofluoric acid and ammonium fluoride (NH₄F), may be used, although the present disclosure is not limited thereto.

In an embodiment in which the interface cleaning process is performed using a chemical liquid having corrosive properties, the chemical solution may be diluted to an etch rate of 5 to 15 Å/sec for the semiconductor oxide SO and the interface cleaning process may be performed for a time between 5-30 seconds to avoid corrosion of the insulating layer 1122 and/or the first semiconductor material layer 1123f while removing the semiconductor oxide SO. In some embodiments, if the chemical liquid is HF or BOE, the dilution concentration may be, for example, 1% to 2%, although the present disclosure is not limited thereto.

Referring next to FIGS. 10A and 11D, after the interface cleaning process is completed, a second semiconductor material layer 1123s and a third semiconductor material layer 1123t are formed on the first semiconductor material layer 1123f (step S350), wherein the first to third semiconductor material layers 1123f-1123t sequentially stacked from bottom to top constitute the active layer 1123 of the thin-film transistor 1120. In this embodiment, the second semiconductor material layer 1123s is, for example, consisting of amorphous silicon, and the third semiconductor material layer 1123t is, for example, consisting of n-doped amorphous silicon, although the present disclosure is not limited thereto.

In some embodiments, in order to ensure that the semiconductor oxide SO cleaned in step S340 is not formed again in the manufacturing process, the time interval between the execution of step S340 and step S350 needs to be set to be less than 1 hour. That is, the step of forming the second and third semiconductor material layers 1123s-1123t is to be performed within one hour after completion of the interface cleaning process.

In some embodiments, the second semiconductor material layer 1123s is formed to a thickness between 500 Å and 800 Å, and the third semiconductor material layer 1123t is formed to a corresponding thickness such that the sum of the thicknesses of the second semiconductor material layer 1123s and the third semiconductor material layer 1123t is approximately between 1000 Å and 1500 Å. In some preferred embodiments, the second semiconductor material layer 1123s is formed to a thickness between 500 Å and 600 Å, and the third semiconductor material layer 1123t is formed to a corresponding thickness such that the sum of the thicknesses of the second semiconductor material layer 1123s and the third semiconductor material layer 1123t is approximately 1300 Å, although the present disclosure is not limited thereto.

Referring next to FIGS. 10A and 11E, after the active layer 1123 is formed, the active layer 1123 may then be patterned, and a second metal layer 1124 is formed on the patterned active layer 1123 (step S360).

Referring next to FIGS. 10A and 11F, after forming the second metal layer 1124, the element is subjected to an etching process to expose the second semiconductor material layer 1123s of the channel region CHA and to divide the second metal layer 1124 into left and right two portions by the channel region CHA (step S370), wherein the second metal layer 1124 on the left side serves as a source 1124S of the thin-film transistor 1120 and the second metal layer 1124 on the right side serves as a drain 1124D of the thin-film transistor 1120.

In some embodiments, a functional layer 1125 covering the surface of the source 1124S, the drain 1124D, and the channel region CHA may be further formed on the element after step S370 as per design or element requirements.

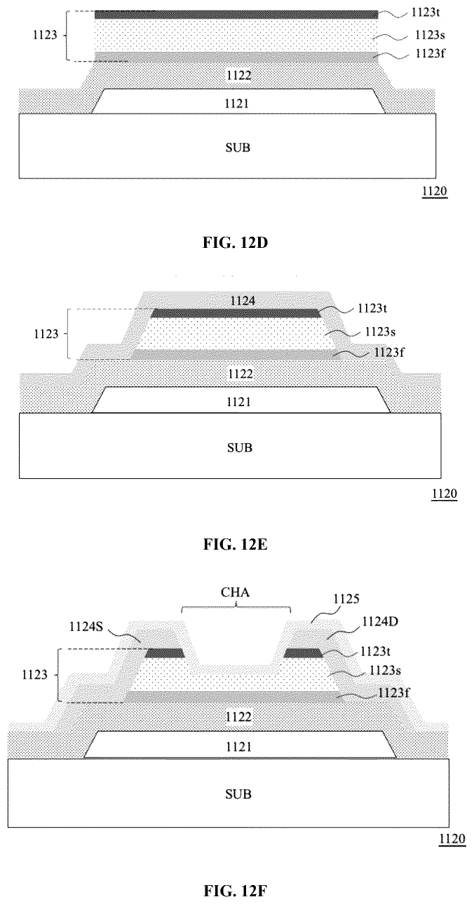

FIG. 10B is a flowchart of steps of a manufacturing method of a thin-film transistor according to another embodiment of the present disclosure, wherein the manufacturing method of FIG. 10B can be used to manufacture the thin-film transistor 1120 according to the embodiment of FIG. 9. A manufacturing flow of the thin-film transistor 1120 is described below with reference to FIGS. 12A to 12F, which are schematic flow diagrams of a manufacturing method according to the thin-film transistor of FIG. 10B.

Referring to FIGS. 10B and 12A, first, a first metal layer 1121 and an insulating layer 1122 overlaying the first metal layer 1121 are formed on the substrate SUB (step S410), wherein the first metal layer 1121 is used as a gate of the thin-film transistor 1120.

Referring to FIGS. 10B and 12B, an amorphous semiconductor thin film NSTF is formed on the insulating layer 1122 (step S420), and the amorphous semiconductor thin film NSTF is subjected to ion implantation (step S430) to implant Group 3A ions into the amorphous semiconductor thin film NSTF.

Next, referring to FIGS. 10B and 12C, the amorphous semiconductor thin film NSTF implanted with Group 3A ions is subjected to thermal treatment to convert the amorphous semiconductor thin film NSTF into the first semiconductor material layer 1123f (step S440).

In other words, the manufacturing method of this embodiment before performing the thermal treatment is mainly different from the aforementioned embodiment of FIG. 10A in that this embodiment dopes Group 3A ions into the amorphous semiconductor thin film NSTF by performing the step S430 of performing ion implantation on the amorphous semiconductor thin film.

In some embodiments, the amorphous semiconductor thin film NSTF may be, for example, amorphous silicon, and the ions implanted into the amorphous semiconductor thin film NSTF may be, for example, boron ions (B+). The thermal treatment may be, for example, an Excimer Laser Annealing (ELA) technique of irradiating amorphous silicon doped with boron ions with an excimer laser to achieve a manufacturing process of modifying the amorphous silicon into microcrystalline silicon or polycrystalline silicon having an ordered lattice structure, i.e., the first semiconductor material layer 1123f, although the present disclosure is not limited thereto.

Referring next to FIGS. 10B and 12D, after the thermal treatment is completed, a second semiconductor material layer 1123s and a third semiconductor material layer 1123t are formed on the first semiconductor material layer 1123f (step S450), wherein the first to third semiconductor material layers 1123f-1123t sequentially stacked from bottom to top constitute the active layer 1123 of the thin-film transistor 1120. In this embodiment, the second semiconductor material layer 1123s is, for example, consisting of amorphous silicon, and the third semiconductor material layer 1123t is, for example, consisting of n-doped amorphous silicon, although the present disclosure is not limited thereto.

Referring next to FIGS. 10B and 12E, after the active layer 1123 is formed, the active layer 1123 may then be patterned, and a second metal layer 1124 is formed on the patterned active layer 1123 (step S460).

Referring next to FIGS. 10B and 12F, after forming the second metal layer 1124, the element is subjected to an etching process to expose the second semiconductor material layer 1123s of the channel region CHA and to divide the second metal layer 1124 into left and right two portions by the channel region CHA (step S470), with the second metal layer 1124 on the left side as the source 1124S of the thin-film transistor 1120 and the second metal layer 1124 on the right side as the drain 1124D of the thin-film transistor 1120.

In some embodiments, after step S470, a functional layer 1125 covering the surface of the source 1124S, drain 1124D, and channel region CHA may be further formed on the element as per design or element requirements.

Compared to traditional thin-film transistor manufacturing processes, the purpose of step S430 of this embodiment is to adjust the threshold voltage value instead of being used as a region for configuring the source/drain, therefore, the ion concentration of implantation/doping does not need to be too high, nor is it necessary to subsequently perform Rapid Thermal Annealing (RTA) manufacturing process on the first semiconductor layer 1123f again in order to activate the ions, effectively simplifying the complexity of the manufacturing process.

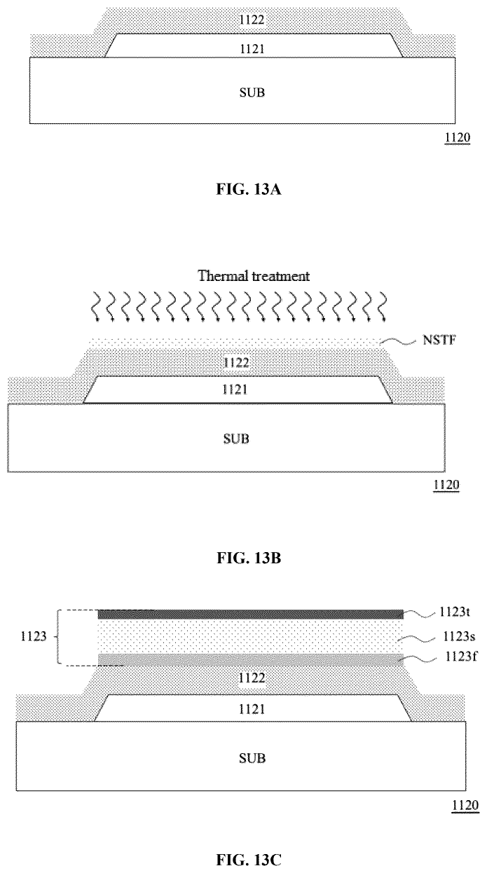

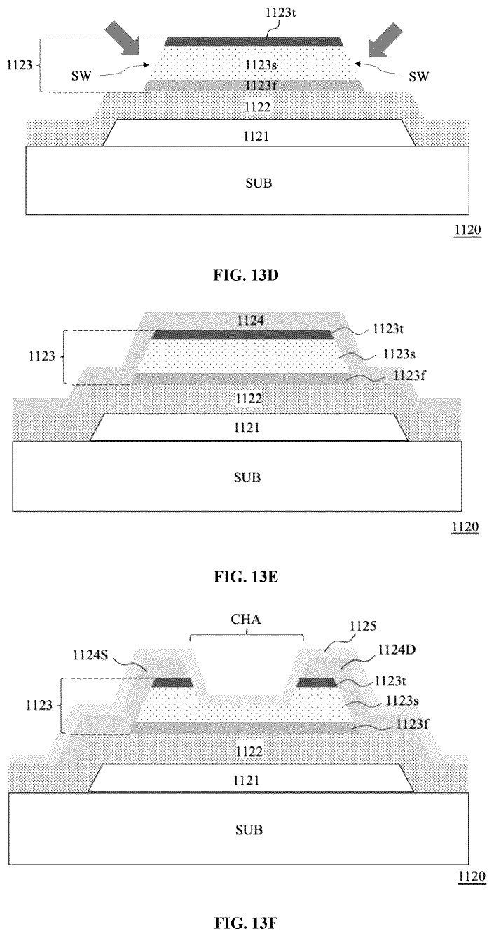

FIG. 10C is a flowchart of steps of a manufacturing method of a thin-film transistor according to yet another embodiment of the present disclosure, wherein the manufacturing method of FIG. 10C can be used to manufacture the thin-film transistor 1120 according to the embodiment of FIG. 9. A manufacturing flow of the thin-film transistor 1120 is described below with reference to FIGS. 13A to 13F, which are schematic flow diagrams of a manufacturing method according to the thin-film transistor of FIG. 10C.

Referring to FIGS. 10C, 13A, and 13B, first, a first metal layer 1121 and an insulating layer 1122 overlaying the first metal layer 1121 are formed on the substrate SUB (step S510), wherein the first metal layer 1121 is used as a gate of the thin-film transistor 1120. Next, an amorphous semiconductor thin film NSTF is formed on the insulating layer 1122 (step S520), and the amorphous semiconductor thin film NSTF is subjected to thermal treatment to convert the amorphous semiconductor thin film NSTF into the first semiconductor material layer 1123f having an ordered lattice structure (step S530).

In some embodiments, the amorphous semiconductor thin film NSTF is, for example, amorphous silicon. The thermal treatment may be, for example, an Excimer Laser Annealing (ELA) technique of irradiating the amorphous silicon with an excimer laser to achieve a manufacturing process of modifying the amorphous silicon into microcrystalline silicon or polycrystalline silicon having an ordered lattice structure, i.e., the first semiconductor material layer 1123f, although the present disclosure is not limited thereto.

Referring next to FIGS. 10C and 13C, after the thermal treatment is completed, a second semiconductor material layer 1123s and a third semiconductor material layer 1123t are formed on the first semiconductor material layer 1123f (step S540), wherein the first to third semiconductor material layers 1123f-1123t sequentially stacked from bottom to top constitute the active layer 1123 of the thin-film transistor 1120. In this embodiment, the second semiconductor material layer 1123s is, for example, consisting of amorphous silicon, and the third semiconductor material layer 1123t is, for example, consisting of n-doped amorphous silicon, although the present disclosure is not limited thereto.

Referring next to FIGS. 10C and 13D, after the active layer 1123 is formed, the active layer 1123 may then be subjected to a carrier removal process (step S550).

In some embodiments, the carrier removal process S550 is performed, for example, by first patterning the active layer 1123 so that the active layer 1123 forms a sidewall SW consisting of, for example, uniform continuous planes of the first semiconductor material layer 1123f, the second semiconductor material layer 1123s, and the third semiconductor material layer 1123t. After completion of the patterning process, the sidewalls SW of the active layer 1123 after the patterning process are further subjected to over-etching or ion implantation to reduce carrier generation of the sidewalls SW of the active layer 1123.

In some embodiments, a normal direction of the side wall SW and a normal direction of the substrate SUB are not parallel; in some embodiments, an included angle of a normal direction of the side wall SW and a normal direction of the substrate SUB is less than 45 degrees, although the present disclosure is not limited thereto.

In some embodiments, after completing the patterning process, the step S550 of the carrier removal process may further include performing an oxidation process on the side wall SW, wherein the oxidation process may be performed by feeding oxygen gas, and by reasonably controlling the time of passing oxygen gas to form a uniform and thin silicon oxide layer on the surface of the side wall SW to further reduce the leakage current at the side wall SW. In some embodiments, the thickness of the silicon oxide layer formed on the sidewall SW surface may be, for example, between 10 A to 30 A, although the present disclosure is not limited thereto.

Referring next to FIGS. 10C and 13E, after the active layer 1123 is formed, the active layer 1123 may then be patterned, and a second metal layer 1124 is formed on the patterned active layer 1123 (step S560).

Please next refer to FIGS. 10C and 13F, after forming the second metal layer 1124, the element is subjected to an etching process to expose the second semiconductor material layer 1123s of the channel region CHA and to divide the second metal layer 1124 into left and right two portions by the channel region CHA (step S570), with the second metal layer 1124 on the left side as the source 1124S of the thin-film transistor 1120 and the second metal layer 1124 on the right side as the drain 1124D of the thin-film transistor 1120.

In some embodiments, a functional layer 1125 covering the surface of the source 1124S, the drain 1124D, and the channel region CHA may be further formed on the element after step S570, as per design or element requirements.

Compared with the conventional thin-film transistor manufacturing process, the step S550 of this embodiment aims to reduce the quantity of carriers at the side wall SW of the active layer 1123, thereby effectively reducing the leakage current of the thin-film transistor 1120, thus effectively improving the switching ratio of the thin-film transistor 1120.

Specifically, in the embodiment of step S550, if a flow of patterning treatment followed by over-etching is employed, the total etching time of the patterning treatment plus the over-etching treatment may be, for example, 60 seconds to 130 seconds, although the present disclosure is not limited thereto.

It should be noted here that, in the above-described flow patterning treatment followed by over-etching, it may be a step in which the over-etching is achieved by extending the etching time of the patterning treatment. In other words, the patterning process and the over-etching process may be one continuous process that cannot be clearly distinguished from the perspective of an actual manufacturing process. The emphasis of the over-etching process is to still further etch the side wall SW after the patterning of the active layer 1123 is completed to reduce the quantity of carriers, while the effect is achieved by appropriately extending the etching time. Therefore, although the difference of steps and flows may not be distinguished in appearance, it can be judged whether to execute the over-etching treatment by the time for which the etching is extended.

In some embodiments, if the step S550 of the carrier removal process is a flow to perform patterning on the active layer 1123 first so that the active layer 1123 forms a sidewall SW, followed by ion implantation of the sidewall SW, the ion implantation may be, for example, implantation of group 3A ions (e.g., boron ions) with a light dose and light energy such that the group 3A ions provide holes in the active layer 1123 to acquire free electrons, thereby reducing the leakage current at the sidewall SW.

In some embodiments, the ion implantation process for the sidewall SW may be performed at an ion concentration between 5×10¹² and 5×10¹³ ions/cm³, at an implantation energy of, for example, 10-20 keV, and at an ambient temperature chamber, although the present disclosure is not limited thereto.

FIG. 10D is a flowchart of steps of a manufacturing method of a thin-film transistor according to yet another embodiment of the present disclosure, wherein the manufacturing method of FIG. 10D may be used to manufacture the thin-film transistor 1120 as described in the embodiment of FIG. 9.

Referring to FIG. 10D, this embodiment is substantially the same as the previous embodiment of FIG. 10A and/or FIG. 10B, but differs from the embodiment of FIG. 10A in that the first semiconductor material layer 1123f is doped with Group 3A ions by performing an ion implantation operation S630 as described in step S430 of FIG. 10B before performing the thermal treatment step S640. Viewed from another perspective, this embodiment differs from the embodiment of FIG. 10B in that it further performs an interface cleaning process step S650, as described in step S340 of FIG. 10A, after performing the thermal treatment step S640, such that the native semiconductor oxide SO on the first semiconductor material layer 1123f is cleaned.

In addition to this, reference may be made to the aforementioned step S310 in FIG. 10A and step S410 in FIG. 10B for the related description of step S610 in this embodiment, reference may be made to the aforementioned step S320 of FIG. 10A and step S420 of FIG. 10B for the related description of step S620 of this embodiment, reference may be made to the aforementioned step S430 of FIG. 10B for the related description of the step S630 of this embodiment, reference may be made to the aforementioned step S330 of FIG. 10A and the step S440 of FIG. 10B for the related description of the step S640 of this embodiment, reference may be made to the aforementioned step S340 of FIG. 10A for the related description of the step S650 of this embodiment, reference may be made to the aforementioned steps S350 to S370 of FIG. 10A and S450 to S470 of FIG. 10B for the related description of the steps S660 to S680 of this embodiment. The repeated parts will not be repeated here.

More specifically, this embodiment is compared to the aforementioned manufacturing method flow of FIGS. 10A and 10B, not only the manufacturing process of ion implantation is performed (step S630), such that the threshold voltage characteristic is improved, but also an interface cleaning process (step S650) is further performed after the amorphous semiconductor thin film (NSTF) doped with Group 3A ions is converted into the polycrystalline or microcrystalline first semiconductor material layer (1123f) to improve the bonding strength between the first semiconductor material layer 1123f and the second semiconductor material layer 1123s, so that the element characteristics of the thin-film transistor as a whole are better.

FIG. 10E is a flowchart of steps of a manufacturing method of a thin-film transistor according to yet another embodiment of the present disclosure, wherein the manufacturing method of FIG. 10E can be used to manufacture the thin-film transistor 1120 as described in the embodiment of FIG. 9.

Referring to FIG. 10E, this embodiment is substantially the same as the previous embodiment of FIG. 10D, and the difference from the embodiment of FIG. 10D is that this embodiment further performs the carrier removal process as described in the step S550 of FIG. 10C before the step S780 of forming the second metal layer, so that the quantity of carriers on the side wall of the active layer is reduced.

In addition, reference may be made to the aforementioned steps S610-S660 of FIG. 10D for the related description of the steps S710-S760 of this embodiment, reference may be made to the aforementioned step S550 of FIG. 10C for the related description of the step S770 of this embodiment, reference may be made to the aforementioned steps S670 and S680 of FIG. 10D for the related description of the steps S780 and S790 of this embodiment. The repeated parts will not be repeated here.

More specifically, compared with the aforementioned manufacturing method flow of FIG. 10C, this embodiment further performs a carrier removal process on the side wall of the active layer after the active layer is subjected to the patterning process (step S770), for reducing the quantity of carriers at the side wall of the active layer, so that the leakage current of the thin-film transistor is reduced, thereby further improving the switching ratio.

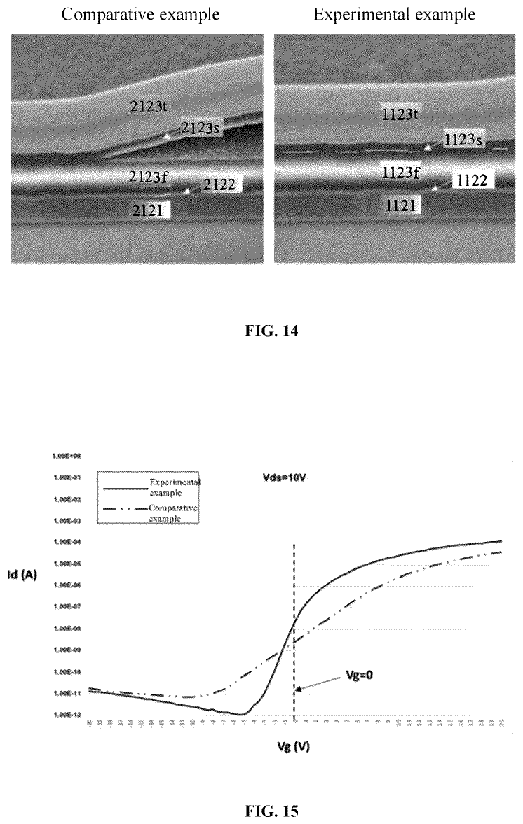

FIG. 14 is an SEM photograph of a thin-film transistor manufactured by a manufacturing method according to an embodiment of the present disclosure and a comparative example. Referring to FIG. 14, the comparative example on the left side is the thin-film transistor fabricated by the manufacturing flow without the step S340 of the interface removal process, which includes a gate 2121, an insulating layer 2122, and an active layer consisting of first to third semiconductor layers 2123f-2123t. As can be seen from the photographs of the experimental comparison results, there is no film peeling between the first semiconductor material layer 1123f and the second semiconductor material layer 1123s in the thin-film transistor manufactured by the manufacturing method of FIG. 10A compared to the comparative example.

FIG. 15 is a schematic breakover current diagram of an experimental example and a comparative example of a thin-film transistor manufactured by a manufacturing method according to an embodiment of the present disclosure. Referring to FIG. 15, it can be seen from the experimental data shown in FIG. 15 that the switching ratio of the experimental example of the thin-film transistor manufactured by the process flow of FIG. 10A is significantly higher than the switching ratio of the comparative example not subjected to the interface cleaning process (step S340).

In addition, in some experimental examples, the carrier mobility of the thin-film transistor produced by the process flow of FIG. 10A can reach 11.12 cm²/V×S. In contrast, in the comparative example not subjected to the interface cleaning treatment (step S340), the carrier mobility may be affected by defects to be only about 1.29 cm²/V×S.

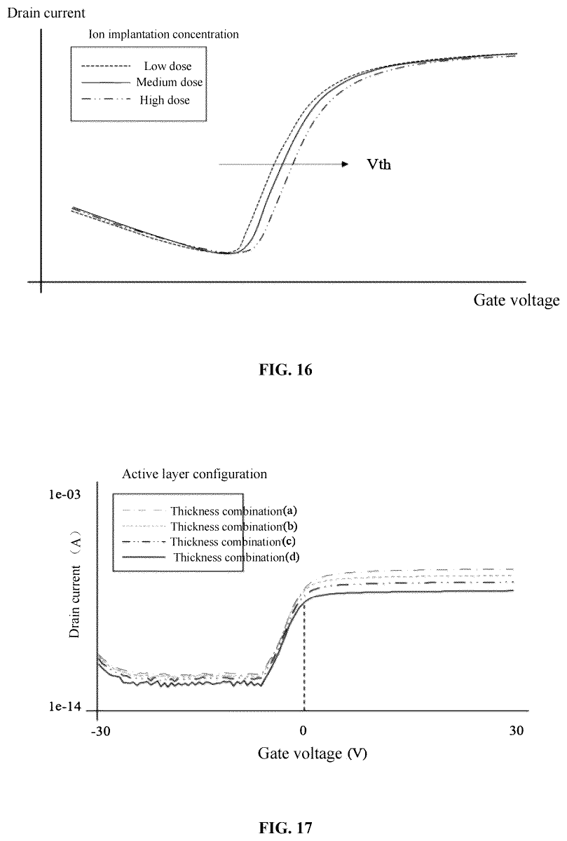

FIG. 16 shows current-voltage characteristics at different ion implantation concentrations of a thin-film transistor manufactured by a manufacturing method according to an embodiment of the present disclosure. As can be seen from the characteristic curve of FIG. 16, as the concentration of group 3A ions implanted in step S430/S630/S730 of the above manufacturing method increases, the threshold voltage of the thin-film transistor also increases. In summary, the thin-film transistor, the pixel array substrate, the display device and the manufacturing method thereof proposed by the embodiment of the present disclosure can make the semiconductor oxide which is likely to cause bonding defects substantially absent between the microcrystalline or polycrystalline silicon layer (such as the first semiconductor material layer) and the amorphous silicon layer (such as the second semiconductor material layer) in the active layer through specific interface cleaning treatment in the manufacturing process of the thin-film transistor, so that the thin films in the active layer can be well bonded without the problem of film peeling, and the component characteristics such as carrier mobility and switching ratio of the thin-film transistor 1120 can be effectively improved. In addition, the embodiments of the present disclosure also propose to increase the threshold voltage of the thin-film transistor by performing ion implantation on the active layer prior to the thermal treatment, so that the finished product can have better and good component characteristics.

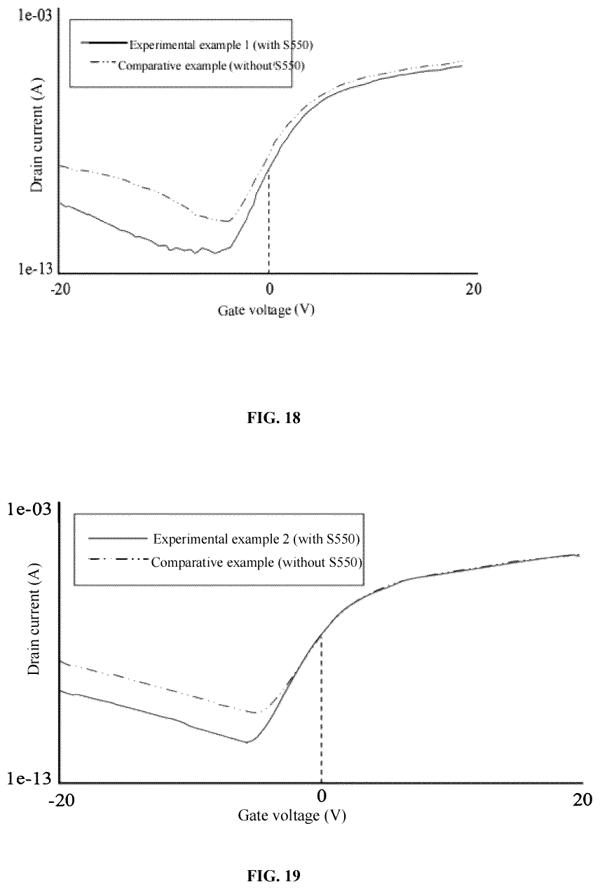

FIG. 17 shows current-voltage characteristics at different thicknesses of an active layer of a thin-film transistor manufactured by a manufacturing method according to an embodiment of the present disclosure, wherein FIG. 16 shows breakover current-gate voltage for the active layer at four different thickness combinations (a)-(d) with an applied drain-source voltage of 0.5 V. As can be seen from the characteristic curve of FIG. 16, with the sum of the thicknesses of the second semiconductor material layer 1123s and the third semiconductor material layer 1123t fixed at 1300 Å, there is a significant increase in the breakover current as the thickness of the second semiconductor material layer 1123s decreases from 800 Å (combination (d)) to 500 Å (combination (a)) and the thickness of the third semiconductor material layer 1123t correspondingly increases from 500 Å to 800 Å. Therefore, through the above experimental results, it was found that even at a low voltage of a drain-source voltage of 0.5 V, the breakover current can reach about 10⁻⁶ A and the cutoff current is not significantly affected, so that the switching ratio can be effectively boosted.

FIG. 18 is a graph showing current-voltage characteristics of a thin-film transistor manufactured by a carrier removal process and a comparative example, wherein the carrier removal process is performed by adopting a flow of a patterning process, an over-etching process, and an oxidation process. Referring to FIG. 18, it can be seen from the experimental comparison results that the experimental example of the thin-film transistor prepared by the step S550 of carrier removal process has significantly better cutoff current (Ioff) characteristics, i.e., lower leakage current, than the comparative example (without the step S550).

FIG. 19 shows current-voltage characteristics of a thin-film transistor manufactured by a carrier removal process and a comparative example, wherein the carrier removal process is performed by adopting a flow of a patterning process and an ion implantation process. Referring to FIG. 19, it can be seen from the experimental comparison results that the experimental example of the thin-film transistor prepared by the step S550 of the carrier removal process has significantly better cut-off current characteristics than the comparative example (without the step S550).

The design of the backlight module portion in the display device 10/30 is further described below.

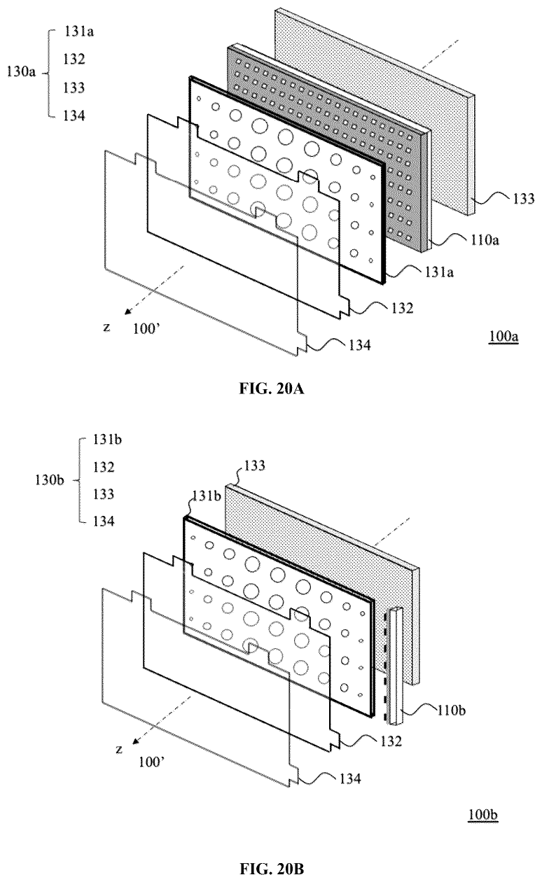

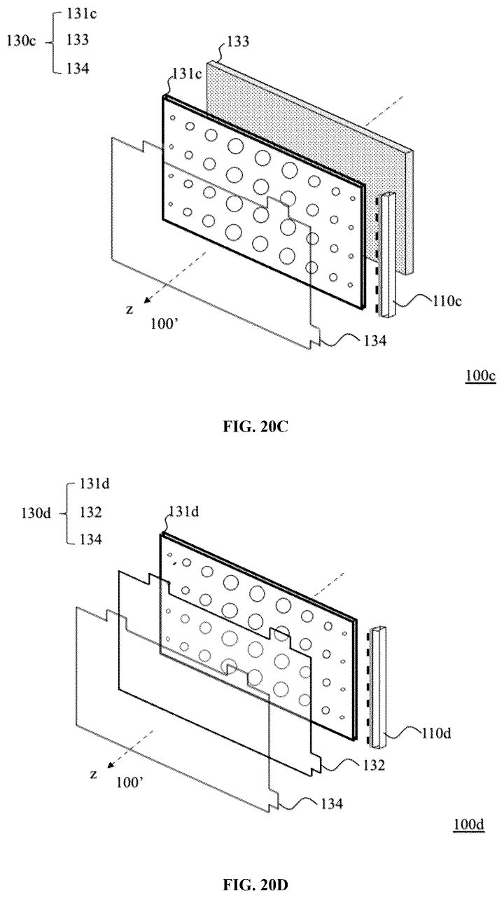

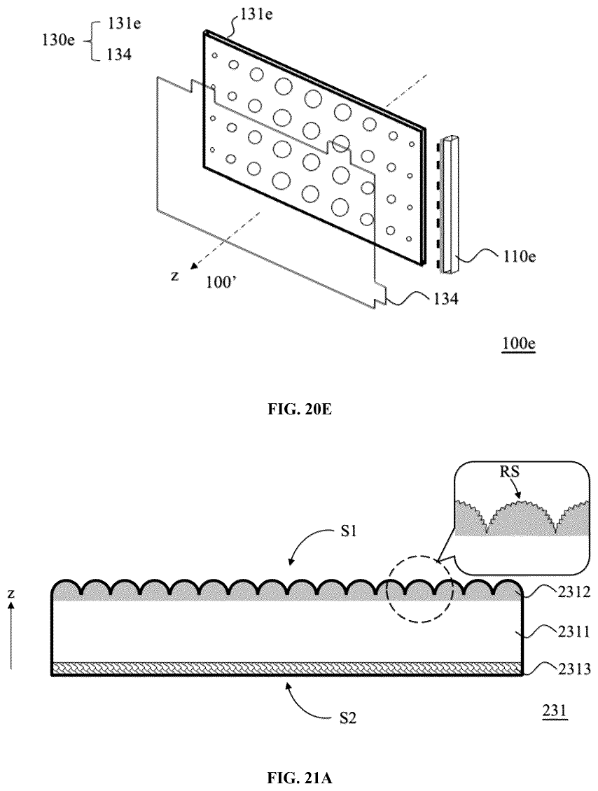

FIGS. 20A to 20C illustrate structural configurations of a backlight module according to various embodiments of the present disclosure, where FIG. 20A illustrates a structural configuration of a direct-type backlight module 100a, and FIGS. 20B and 20C illustrate structural configurations of edge-type backlight module 100b and 100c.

Referring to FIG. 20A, a backlight module 100a includes a light-emitting part 110a and an optical adjustment layer 130a, wherein the optical adjustment layer 130a includes a light guide plate 131a, a diffuser plate 132, and a reflector plate 133. In this embodiment, the diffuser plate 132, the light guide plate 131a, the light-emitting part 110a, and the reflector plate 133 are arranged in order on the z-axis from a side close to the display panel 100′ to a side far from the display panel 100′, and are substantially parallel to each other. In other words, in the backlight module 100a, the diffuser plate 132 is closest to the display panel 100′, and the reflector plate 133 is farthest from the display panel 100′. As seen from the uppermost view of the display panel 100′, it is considered that the light-emitting part 110a is disposed on an upper side of the reflector plate 133, the light guide plate 131a is disposed on an upper side of the light-emitting part 110a, and the diffuser plate 132 is disposed on an upper side of the light guide plate 131a.

In some embodiments, the optical adjustment layer 130a may further include a light intensifying plate 134, wherein the light intensifying plate 134 may be disposed on an upper side of the diffuser plate 132, i.e., between the display panel 100′ and the diffuser plate 132. In other words, in embodiments having a light intensifying plate 134, the component of the backlight module 100a closest to the display panel 100′ may be the light intensifying plate 134, although the present disclosure is not limited thereto.

Specifically, the light guide plate 131a is configured to refract and/or reflect the light provided by the light emitting part 110a, so that light can be uniformly emitted from the exit surface of the light guide plate 131a. In other words, after the light source provided by the light-emitting part 110a passes through the light guide plate 131a, the light emitted toward the display panel 100′ can be emitted more evenly to each region of the display panel 100′ than when the light guide plate 131a is not present. In this embodiment, the exit surface of the light guide plate 131a is the surface on the side adjacent to the display panel 100′, and the light-entering surface of the light guide plate 131a is the surface on the side opposite to the exit surface, that is, the surface on the side adjacent to the light-emitting part 110a. In other words, the backlight module 100a of this embodiment has a direct-type configuration.

The light guide plate 131a of this embodiment may be constructed of any transparent material, such as glass or plastic material (e.g., PMMA, MS, PS, etc.), wherein a plurality of optical microstructures may be included in the light guide plate 131a, although the present disclosure is not limited thereto.

The diffuser plate 132 serves to optically disperse the received light through scattering and refraction so that the light can be further dispersed and evenly distributed throughout the display panel 100′. In the configuration of this embodiment, one side of the diffuser plate 132 is disposed on the exit surface of the light guide plate 131a and the other side is disposed in correspondence with the display panel 100′, so that the light emitted from the exit surface of the light guide plate 131a is further more evenly dispersed into each region of the display panel 100′ after passing through the diffuser plate 132.

The diffuser plate 132 of this embodiment may be implemented using a plastic sheet with roughened surface or other transparent material, although the present disclosure is not limited thereto. The diffuser plate 132 may be attached/assembled with the light guide plate 131a by gluing or other bonding means, although the present disclosure is again not limited thereto.

The reflector plate 133 serves to optically reflect the received light so that the light not directed toward the display panel 100′ can be reflected into the light directed toward the display panel 100′, thereby improving the light source utilization of the light-emitting part 110a. In the configuration of this embodiment, the light-emitting part 110a is disposed on the reflecting surface of the reflector plate 133, wherein a portion of light emitted from the light-emitting part 110a through the light guide plate 131a is emitted toward a direction other than parallel to the z-axis (i.e., not toward the display panel 100′).

The reflector plate 133 of this embodiment may be implemented with an aluminum foil or a reflection material having a metal plating film, wherein the reflector plate 133 may be connected/assembled with the light guide plate 131a by pasting or other bonding means, although the present disclosure is not limited thereto as well. It should be noted that although the reflector plate 133 of this embodiment is illustrated as a sheet shape, the present disclosure is not limited thereto. In some embodiments, the reflector plate 133 may be extended to the side of the light-emitting part 110a in response to the packaging structure of the backlight module 100a, thereby improving the reflection efficiency.

In embodiments of the backlight module 100a that include the light intensifying plate 134, the light intensifying plate 134 is configured to increase the number and angle of incidence of the light rays through optical effects of refraction and reflection so that the received light rays can be further diffused towards the display panel 100′, thereby increasing the brightness and viewing angle of the overall light source. In the configuration of this embodiment, the light intensifying plate 134 is disposed on the diffuser plate 132, and is positioned between the display panel 100′ and the diffuser plate 132.

The light intensifying plate 134 of this embodiment may be implemented with a transparent material coated with a high refractive index material, although the present disclosure is not limited thereto. The light intensifying plate 134 may be attached/assembled with the diffuser plate 132 by gluing or other bonding means, although the present disclosure is again not limited thereto.

More specifically, in the backlight module 100a, the light source emitted from the light-emitting part 110a is emitted from the exit surface thereof by the optical action of the light guide plate 131a, and sequentially supplied to the display panel 100′ through the diffuser plate 132 and the light intensifying plate 134. In addition, the light diffused from the periphery of the light-emitting part 110a and/or the light guide plate 131a is reflected back to the light guide plate 131a by the reflector plate 133, and the light is emitted to the display panel 100′ through a light path similar to that described above. Referring next to FIG. 20B, the backlight module 100b includes a light-emitting part 110b and an optical adjustment layer 130b, wherein the optical adjustment layer 130b includes a light guide plate 131b, a diffuser plate 132, and a reflector plate 133. In this embodiment, the diffuser plate 132, the light guide plate 131b, and the reflector plate 133 are arranged in order on the z-axis from a side close to the display panel 100′ to a side far from the display panel 100′, and are substantially parallel to each other. The light-emitting part 110b is positioned on a side of the light guide plate 131b, in which a light-emitting direction of the light-emitting part 110b is not parallel to the normal directions of the planes of the diffuser plate 132, the light guide plate 131b, and the reflector plate 133. More specifically, the light-emitting direction of the light-emitting part 110b of this embodiment may be substantially perpendicular to the normal directions of the planes of the diffuser plate 132, the light guide plate 131b, and the reflector plate 133. In the backlight module 100b, the diffuser plate 132 is closest to the display panel 100′, and the reflector plate 133 is farthest from the display panel 100′. As seen in the uppermost view of the display panel 100′, it is considered that the light guide plate 131b is disposed on an upper side of the reflector plate 133, the diffuser plate 132 is disposed on an upper side of the light guide plate 131b, and the light-emitting part 110b is disposed on the side of the light guide plate 131b.

In some embodiments, the optical adjustment layer 130b may also include a light intensifying plate 134, wherein the light intensifying plate 134 may be disposed on an upper side of the diffuser plate 132, i.e., between the display panel 100′ and the diffuser plate 132. In other words, in embodiments having a light intensifying plate 134, the component of the backlight module 100b closest to the display panel 100′ may be the light intensifying plate 134, although the present disclosure is not limited thereto.

Specifically, the light guide plate 131b is configured to make the light source provided by the light emitting part 110b be emitted uniformly from the exit surface of the light guide plate 131b through the optical action of refraction and/or reflection. In other words, after the light source provided by the light-emitting part 110b passes through the light guide plate 131b, the light emitted toward the display panel 100′ can be emitted more evenly to each region of the display panel 100′ than without the light guide plate 131b. In this embodiment, the exit surface of the light guide plate 131b is a surface on the side closer to the display panel 100′; the incident surface of the light guide plate 131b is a side surface perpendicular/non-parallel to the exit surface, that is, a surface on a side closer to the light-emitting part 110b. In other words, the backlight module 100b of this embodiment is of an edge-type configuration, as compared to the previous embodiment of FIG. 20A. Note that although FIG. 20B illustrates that the light-emitting part 110b is disposed on the right side of the light guide plate 131b, the present disclosure is not limited thereto. In other embodiments, the light-emitting part 110b may be disposed on other sides of the light guide plate 131b (e.g., left side, top side, and bottom side in the drawing).

The above description of the light guide plate 131a of the embodiment of FIG. 20A can be referred to for the structural composition/connection arrangement embodiment of the light guide plate 131b of this embodiment, and the description will not be repeated here.

The diffuser plate 132 serves to optically disperse the received light through scattering and refraction so that the light can be further dispersed and evenly distributed throughout the display panel 100′. In the configuration of this embodiment, one side of the diffuser plate 132 is disposed on the exit surface of the light guide plate 131b and the other side is disposed in correspondence with the display panel 100′, so that the light emitted from the exit surface of the light guide plate 131b is further more evenly dispersed to each region of the display panel 100′ after passing through the diffuser plate 132.

Reference can be made to the above description of the embodiment of FIG. 20A for the structural composition/connection arrangement of the diffuser plate 132 of this embodiment, and the description thereof will not be repeated here.

The reflector plate 133 is configured to optically reflect the received light so that the light not directed toward the display panel 100′ can be reflected into the light directed toward the display panel 100′, thereby improving the light source utilization of the light-emitting part 110b. In the configuration of this embodiment, the light guide plate 131b is disposed on the reflector plate 133, wherein the surface of the light guide plate 131b opposite to the exit surface faces the reflecting surface of the reflector plate 133, so that a portion of light emitted from the light guide plate 131b that is not directed toward the display panel 100′ is reflected to the light guide plate 131b.

Reference can be made to the above description of the embodiment of FIG. 20A for the structural composition/connection arrangement of the reflector plate 133 of this embodiment, and the description thereof will not be repeated here.

In embodiments of the backlight module 100b that include the light intensifying plate 134, the light intensifying plate 134 is configured to increase the number and angle of incidence of the light rays through optical effects of refraction and reflection so that the received light rays can be further diffused towards the display panel 100′, thereby increasing the brightness and viewing angle of the overall light source. In the configuration of this embodiment, the intensifying plate 134 is disposed on the diffuser plate 132, and is positioned between the display panel 100′ and the diffuser plate 132.

Reference can be made to the above description of the embodiment of FIG. 20A for the structural composition/connection arrangement of the light intensifying plate 134 according to this embodiment, and the description thereof will not be repeated here.

More specifically, in the backlight module 100b, the light source emitted from the light-emitting part 110b is emitted from the exit surface thereof by the optical action of the light guide plate 131b, and sequentially supplied to the display panel 100′ through the diffuser plate 132 and the light intensifying plate 134. The light diffused from the periphery of the light-emitting part 110b and/or the light guide plate 131b is reflected back to the light guide plate 131b by the reflector plate 133, and the light is emitted to the display panel 100′ through a light path similar to that described above.

As compared with the direct-type backlight module 100a in FIG. 20A, the light-emitting part 110b of the backlight module 100b of this embodiment is positioned on the side of the light guide plate 131b rather than overlapping with the light guide plate 131b/the reflector plate 133, so that the thickness of the backlight module 100b can be effectively reduced.

In the backlight module 100a and 100b described above, the light guide plate 131a/131b may be made of a plastic material, for example. Embodiments of the present disclosure propose a new plastic light guide plate structure design that achieves reinforcement of overall rigidity by forming a transparent support structure on the surface of the light guide plate 131a/131b, thereby making the backlight module 100a/100b no longer require an additional rigid reinforcement plate to prevent deformation of the light guide plate 131a/131b, so that the cost of the backlight module 100a/100b can be significantly reduced; there is no influence on the light emission characteristics of the backlight module 100a/100b. The design of the plastic light guide plate structure described above is further illustrated in the following examples.

Referring next to FIG. 20C, the backlight module 100c includes the light-emitting part 110c and the optical adjustment layer 130c, wherein the optical adjustment layer 130c of this embodiment may include only the light guide plate 131c and the reflector plate 133, as compared to the aforementioned FIGS. 20A and 20B. Specifically, therefore, the backlight module 100c of this embodiment can omit the configuration of the diffuser plate, and the optical adjustment layer 130c includes only the light guide plate 131c and the reflector plate 133, since an upper surface (i.e., the exit surface or the surface on the side close to the display panel 100′) of the light guide plate 131c of this embodiment is specially surface-treated so that the exit surface of the light guide plate 131c has the optical properties of the diffuser plate (e.g., 132).

In some embodiments, the optical adjustment layer 130c may also include a light intensifying plate 134, wherein the light intensifying plate 134 is disposed on an upper side of the light guide plate 131c, i.e., between the display panel 100′ and the light guide plate 131c, and one side of the light intensifying plate 134 faces the exit surface of the light guide plate 131c, and the opposite side of the light intensifying plate 134 faces the display panel 100′. In other words, in embodiments having a light intensifying plate 134, the component of the backlight module 100c closest to the display panel 100′ may be the intensifying plate 134, although the present disclosure is not limited thereto.

More specifically, the light guide plate 131c of this embodiment is formed of a glass material having material characteristics of transparency, brittleness, and hardness, wherein the upper surface of the light guide plate 131c is surface-treated to have optical properties of a diffuser plate. Therefore, the diffuser plate 132 as described in FIGS. 20A and 20B may be omitted in the backlight module 100c of this embodiment.

Referring next to FIG. 20D, the backlight module 100d includes the light-emitting part 110d and the optical adjustment layer 130d, wherein the optical adjustment layer 130d of this embodiment may include only the light guide plate 131d and the diffuser plate 132, as compared to the aforementioned FIGS. 20A and 20B. Specifically, the other side surface of the light guide plate 131d opposite to the exit surface is specially surface-treated so that the light guide plate 131d can have the optical properties of the reflector plate (e.g., 133), so that the backlight module 100d of this embodiment can omit the configuration of the reflector plate, and the optical adjustment layer 130d includes only the light guide plate 131d and the diffuser plate 132.

In some embodiments, the optical adjustment layer 130d may also include a light intensifying plate 134, wherein the light intensifying plate 134 may be disposed on an upper side of the diffuser plate 132, i.e., between the display panel 100′ and the diffuser plate 132. In other words, in embodiments having a light intensifying plate 134, the component of the backlight module 100d closest to the display panel 100′ may be the light intensifying plate 134, although the present disclosure is not limited thereto.

More specifically, this embodiment also adopts a light guide plate 131d made of glass, and the light guide plate 131d is surface-treated on its other side surface opposite to the exit surface so that the surface has the optical properties of the reflector plate. Therefore, the reflector plate 133 as described in FIGS. 20A and 20B may be omitted in the backlight module 100d of this embodiment. Referring next to FIG. 20E, a backlight module 100e includes a light-emitting part 110e and an optical adjustment layer 130e, wherein the optical adjustment layer 130e of this embodiment may include only a light guide plate 131e, as compared to the aforementioned FIGS. 20A and 20B. Specifically, an upper surface (i.e., the exit surface or the surface on the side close to the display panel 100′) and a lower surface (i.e., the surface on the other side opposite to the exit surface) of the light guide plate 131e of this embodiment are respectively subjected to special surface treatments, so that the light guide plate 131e can have the optical properties of both a diffuser plate (e.g., 132) and a reflector plate (e.g., 133). Therefore, the configuration of the diffuser plate and the reflector plate can be omitted in the backlight module 100e of this embodiment, and the optical adjustment layer 130e only includes the light guide plate 131e.

In some embodiments, the optical adjustment layer 130e may also include a light intensifying plate 134 which is disposed on the upper side of the light guide plate 13le, i.e., between the display panel 100′ and the light guide plate 131e. One side of the light intensifying plate 134 is directed toward the exit surface of the light guide plate 131e, and the opposite side of the light intensifying plate 134 is directed toward the display panel 100′. In other words, in embodiments having a light intensifying plate 134, the component of the backlight module 100e closest to the display panel 100′ may be the intensifying plate 134, although the present disclosure is not limited thereto.

More specifically, the light guide plate 131e of this embodiment is similar to the combination of the aforementioned embodiments of FIGS. 20C and 20D, in which the upper surface of the light guide plate 131e made of glass is surface-treated and has the optical properties of the diffuser plate, and the lower surface thereof is surface-treated and has the optical properties of the reflector plate. Therefore, the diffuser plate 132 and the reflector plate 133 as described in FIGS. 20A and 20B may be omitted in the backlight module 100e of this embodiment.

By the above-described configuration of FIGS. 20C to 20E, the manufacturing process of the backlight module 100c/100d/100e can be further simplified, thereby improving the production efficiency. At the same time, since the arrangement of the diffuser plate and/or the reflector plate is omitted, the effect of light uniformity and durability considerations that may be caused by the connection between the components may be improved at the same time.

For example, if the light guide plate and diffuser plate/reflector plate are assembled by bonding, the optical properties of the backlight module may be affected by air foam during bonding. Furthermore, it is also possible to cause uneven pressure between the parts due to uneven coating of the adhesive at the time of bonding (more severe in the case of large-sized panels), and also cause a problem of deterioration in optical performance. By omitting the arrangement of the diffuser plate and the reflector plate, both of the above problems can be improved at the same time.

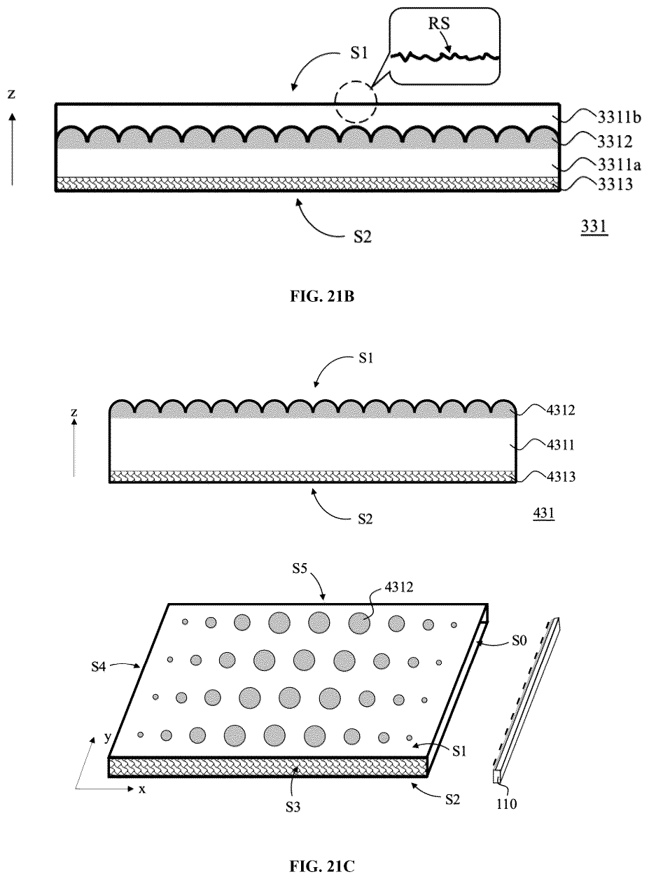

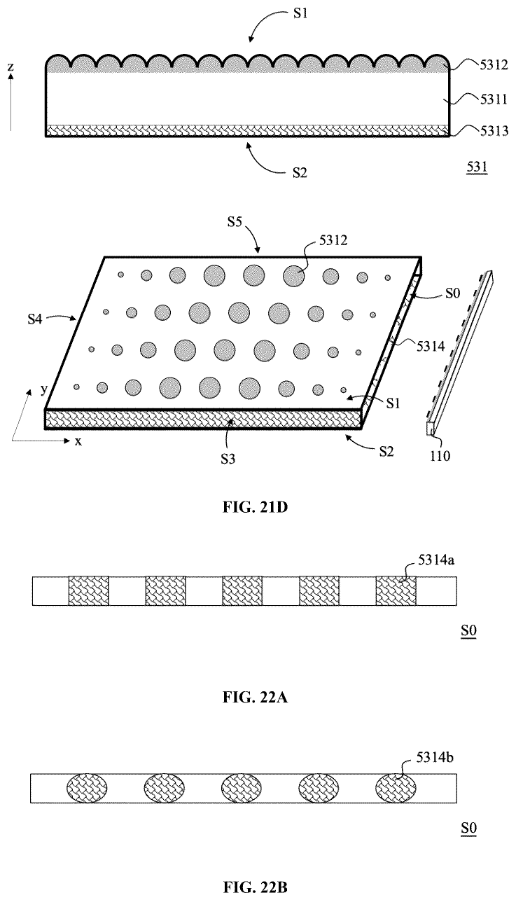

Specific structural examples of the glass-light guide plate described above with reference to the embodiment of FIGS. 20C-20E are further described below with reference to FIGS. 21A-21D, which are schematic views of configurations of the light guide plate according to various embodiments of the present disclosure. Referring first to FIG. 21A, the light guide plate 231 includes a body part 2311, an optical microstructure 2312, and a reflecting part 2313, wherein the optical microstructure 2312 is formed on one side of the body part 2311, and the reflecting part 2313 is formed on the opposite side of the body part 2311. The surface of the light guide plate 231 on the side where the optical microstructures 2312 are formed is the first surface S1, which is directed toward the display panel 100′ (i.e., toward the light intensifying plate 134), and the surface of the light guide plate 231 on the side opposite to the body part 2311 where the reflecting part 2313 is formed is the second surface S2. In this embodiment, the first surface S1 is the exit surface of the light guide plate 231.

In particular, the first surface S1 of the light guide plate 231 (i.e., the surface of the optical microstructures 2312) is frosted to have a rough structure RS thereon, resulting in a reduced gloss level of the first surface S1, such that light passing through the first surface S1 is scattered and refracted, thus having the optical characteristics of a diffuser plate. In some embodiments, the gloss level of the frosted first surface S1 may be, for example, less than 20; in some preferred embodiments, the gloss level of the first surface S1 may be less than 1, for example between 0.85 and 0.9, although the present disclosure is not limited thereto.

More specifically, since the light guide plate 231 is made of glass, the rough structure RS can be formed on the first surface S1 by a frosting process such as sand blasting, grinding wheel, chemical etching, wet grinding, and texture printing. For example, in some embodiments, by soaking the first surface S1 of the light guide plate 231 with hydrofluoric acid, a rough structure RS as shown in FIG. 21A may be formed on the surface/first surface S1 of the optical microstructures 2312 without damaging the optical microstructures 2312. In this way, it is possible to reduce the gloss level of the first surface S1/exit surface by roughening the surface of the optical microstructure 2312 while ensuring the light guiding properties of the light guide plate 231, thereby imparting the diffusing and refracting optical properties of the diffuser plate on the first surface S1.

In some embodiments, the body part 2311 and the optical microstructures 2312 of the light guide plate 231 may be integrally formed.

In some embodiments, in addition to the above-described frosting method may be used to form the rough structures RS on the first surface S1, laser cutting and/or 3D printing may be used to form the rough structures RS, although the present disclosure not being limited thereto.

On the other hand, the second surface S2 of the light guide plate 231 is subjected to a coating treatment so that the second surface S2 is covered with a reflective film to form the reflecting part 2313. The reflecting part 2313 reflects light toward the first surface S1 of the light guide plate 231, wherein the material of the reflective film may be a high-gloss level metal material such as aluminum or silver, although the present disclosure is not limited thereto. After the coating treatment described above, the reflecting part 2313 formed on the light guide plate 231 has optical properties of a reflector plate, and thus can replace the reflector plate 133 shown in FIGS. 20A and 20B.

In some embodiments, the gloss level of the reflecting part 2313 may be, for example, greater than 95.

The light guide plate 231 of this embodiment can be applied to the backlight module 100e as described in FIG. 20E. Furthermore, if the above-described frosting treatment or other surface roughening treatment is only carried on the first surface S1 for the light guide plate 231 of this embodiment so as to reduce the gloss level to have optical properties of a diffuser plate, it can be used in the backlight module 100c as described in FIG. 20C; if the coating process is only carried out on the second surface S2 for the light guide plate 231 of this embodiment so as to increase the gloss level to have optical properties of a reflector plate, it can be used in the backlight module 100d as described in FIG. 20D.

Please refer to FIG. 21B, the light guide plate 331 includes body parts 3311a and 3311b, an optical microstructure 3312, and a reflecting part 3313, wherein the optical microstructure 3312 is formed between the body parts 3311a and 3311b, and the optical microstructure 3312 and the reflecting part 3313 are formed on opposite sides of the body part 3311a. The surface of the body part 3311b on the side facing away from the optical microstructure 3312 is the first surface S1, which is directed toward the display panel 100′ (i.e., toward the light intensifying plate 134), and the surface of the light guide plate 331 on the opposite side of the body part 3311a, which is formed with the reflecting part 3313, is the second surface S2. In this embodiment, the first surface S1 is the exit surface of the light guide plate 331.

Specifically, this embodiment is similar to the previously described embodiment of FIG. 21A, with the main difference that the optical microstructure 3312 of this embodiment is formed between two layers of body parts 3311a and 3311b (i.e., in the glass material), and thus the rough structure RS of this embodiment is formed on the body part 3311b instead of on the surface of the optical microstructure 3312.

In this embodiment, the first surface S1 of the light guide plate 331 (i.e., the upper surface/surface of the body part 3311b on the side remote from the optical microstructure 3312) is frosted to have a rough structure RS, thereby causing the gloss level of the first surface SI to decrease, so that the light passing through the first surface S1 is scattered and refracted, thus having the optical characteristics of a diffuser plate. Similarly, in some embodiments, the gloss level of the frosted first surface S1 may be, for example, less than 20; in some preferred embodiments, the gloss level of the first surface S1 may be less than 1, for example between 0.85 and 0.9, although the present disclosure is not limited thereto.

On the other hand, the above description of the embodiment of FIG. 21A can be referred to the formation and arrangement of the reflecting part 3313, and the description thereof will not be repeated here.

From the point of view of the light guide plate 231 and 331 as a whole, the light guide plate 231/331 can be regarded as including an incident surface, a first surface S1 and a second surface S2. The first surface S1, which acts as an exit surface of the light guide plate 231/331, will be substantially perpendicular to the entrance face, and the second surface S2 is located on the opposite side of the exit surface. Therein, the gloss level of the first surface S1 will be less than 20 and the gloss level of the second surface S2 will be greater than 80. In some embodiments, the gloss level of the first surface S1 will be less than 1 and the gloss level of the second surface S2 will be greater than 95. In some embodiments, the gloss level of the first surface S1 is between 0.85 and 0.9 and the gloss level of the second surface S2 may be greater than 95.

Similar to that described in the previous embodiment, the light guide plate 331 of this embodiment can be applied to the backlight module 100e described in FIG. 20E. Furthermore, if the above-described frosting treatment or other surface roughening treatment is only carried out on the first surface S1 for the light guide plate 331 of this embodiment so as to reduce the gloss level to have optical properties of a diffuser plate, it can be used in the backlight module 100c as described in FIG. 20C; if the coating process is only carried out on the second surface S2 for the light guide plate 331 of this embodiment so as to increase the gloss level to have optical properties of a reflector plate, it can be used in the backlight module 100d as described in FIG. 20D.

Referring to FIG. 21C, the light guide plate 431 of this embodiment includes a body part 4311, an optical microstructure 4312, and a reflecting part 4313, wherein the cross-sectional structure of this embodiment is illustrated as similar to that of the embodiment of FIG. 21A as a schematic illustration, although the present disclosure is not limited thereto. The light guide plate 431 in this example may have a structure as shown in FIG. 21B.

This embodiment is substantially the same as the aforementioned embodiment of FIG. 21A and FIG. 21B, with the main difference that the reflecting part 4313 of this embodiment extends to at least part of the side surfaces of the light guide plate 431 in addition to being formed on the second surface S2.

Specifically, the side surfaces described herein are, for example, surfaces S3 to S5 of the light guide plate 431 other than the incident surface S0 that are substantially perpendicular (or non-parallel) to the first surface S1 and/or the second surface S2. As seen in FIG. 21C, the side surfaces include, for example, a lower side surface S3, a left side surface S4, and an upper side surface S5 of the light guide plate 431.

In this embodiment, the reflective film on the reflecting part 4313 extends from the second surface S2 to at least one of the side surfaces S3 to S5. In some embodiments, the reflective film will cover the second surface S2 and all of the side surfaces S3-S5. With the above-described configuration of the reflecting part 4313, not only the light towards the second surface S2 will be reflected back to the direction of the display panel 100′, but also the light in other directions can be reflected by the reflective films on the side surfaces S3 to S5, so that the utilization rate of the light source can be further improved, and thus the brightness of the backlight module can be further improved.

The light guide plate 431 of this embodiment can be applied to the backlight module 100d as described in FIG. 20D (the first surface S1 is not subjected to the surface roughening treatment), or to the backlight module 100e as described in FIG. 20E (the first surface S1 is subjected to the surface roughening treatment), the present disclosure not being limited thereto.

Referring to FIG. 21D, the light guide plate 531 of this embodiment includes a body part 5311, an optical microstructure 5312, and a reflecting part 5313. This embodiment is similar to the previous embodiment of FIG. 21C, and reference can be made to the description of the previous embodiment for the description of the configuration of this embodiment, which will not be repeated here. The main difference between this embodiment and the previously described embodiment of FIG. 21C is that the light guide plate 531 of this embodiment further includes reflective film structures 5314 arranged at intervals on its incident surface S0.

Specifically, the reflective film structures 5314 on the incident surface S0 are formed corresponding to the positions of the light-emitting elements LEDs on the light-emitting part 110, wherein the reflective film structures 5314 are formed in the interval regions of adjacent light-emitting elements LEDs to avoid blocking the light path of light-emitting elements LEDs. With the configuration forming the reflective film structures 5314 arranged at intervals in the interval regions of adjacent light-emitting elements LEDs, the light guide plate 531 can effectively improve the light-emitting dark regions between light-emitting elements LEDs so that the light emission of the backlight module is more uniform.

The light guide plate 531 of this embodiment is equally applicable to the backlight module 100d described in FIG. 20D or the backlight module 100e described in FIG. 20E, and the present disclosure is not limited thereto. It should be noted that the above-described embodiments of FIGS. 21C and 21D illustrate an example in which the incident surface S0 is the right surface of the light guide plate 431/531 (i.e., the light-emitting part 110 is disposed on the right side of the light guide plate 431/531), although the present disclosure is not limited thereto. In other embodiments, the light-emitting part 110 may be disposed on any one or more side surfaces according to design requirements, wherein the side surface on which the light-emitting part 110 is disposed is regarded as the incident surface.

An example of the arrangement of the reflective film structures 5314 on the incident surface S0 is further described below with reference to FIGS. 22A and 22B. Referring first to FIG. 22A, the reflective film structure 5314a of this embodiment may be formed in a rectangular pattern and located in an interval region between two adjacent light-emitting elements structures. In other words, the width of the reflective film structure 5314a is selected based on the distance between adjacent light-emitting elements, while the height of the reflective film structure 5314 is determined based on the thickness of the light guide plate 531.

Referring next to FIG. 22B, the reflective film structures 5314b of this embodiment may be formed in a circular/elliptical pattern, and are also located in an interval region between two adjacent light-emitting elements structures. In other words, the diameter/major axis length of the reflective film structure 5314b is selected based on the distance between adjacent light-emitting elements.

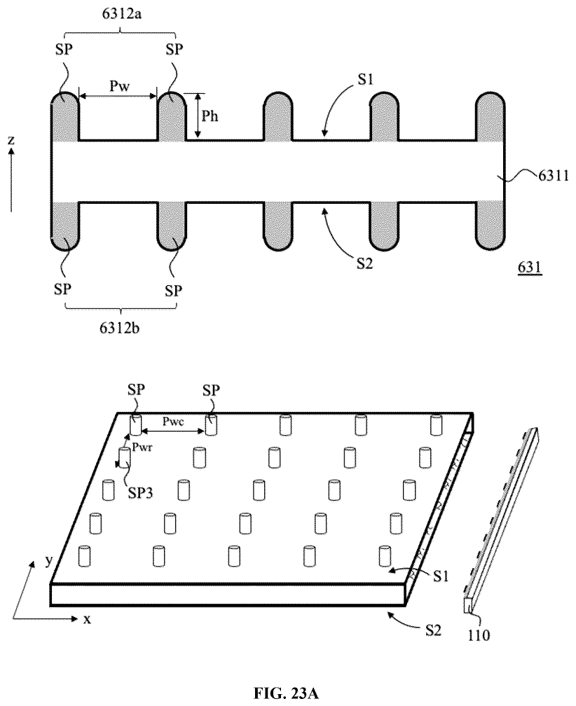

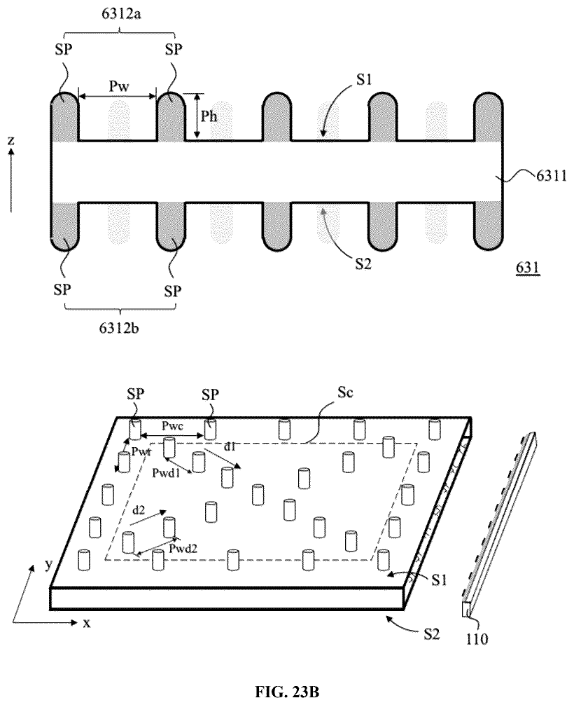

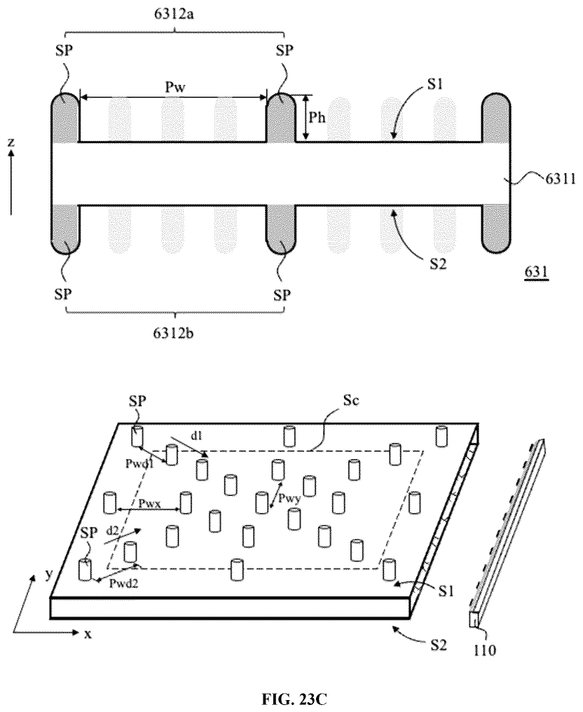

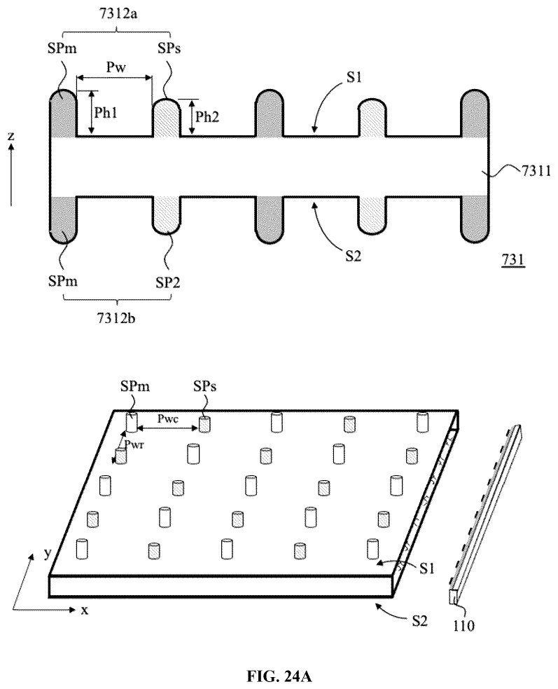

FIGS. 23A to 23C are embodiments having a first type of light guide plate structure, which can be applied to the configurations of the backlight module 100a and 100b described in the embodiments of FIGS. 20A and 20B above. Referring first to FIG. 23A, where an upper portion of FIG. 23A illustrates a side view of the light guide plate 631 and a lower portion of FIG. 23A illustrates a top view of the light guide plate 631. The light guide plate 631 of this embodiment includes a body part 6311 and reinforcing parts 6312a and 6312b, wherein the reinforcing parts 6312a and 6312b are formed on opposite sides of the body part 6311, respectively. The surface of the light guide plate 631 on the side where the reinforcing part 6312a is formed is the first surface S1, which is directed toward the display panel 100′ (i.e., toward the light intensifying plate 134); the surface on the opposite side of the body part 6311 is the second surface S2, which is directed toward the reflector plate 133. In this embodiment, the first surface S1 is the exit surface of the light guide plate 631. Specifically, the reinforcing parts 6312a and 6312b each include a plurality of columnar support units SP having a light-transmitting property and a certain degree of rigidity. Taking the reinforcing part 6312a as an example, the support units SP have a height Ph and are sequentially arranged to be spaced apart on the first surface S1 with a distance Pw between adjacent support units SP. The height Ph of the support units SP may be, for example, between 2 μm and 3 μm, although the present disclosure is not limited thereto.

More specifically, in this embodiment, the distance Pw of the support units SP of two adjacent columns may be a fixed distance Pwc, and the distance Pw of the support units SP of two adjacent rows may be a fixed distance Pwr. In other words, the support units SP in each row are sequentially arranged with a fixed distance Pwc, and the support units SP in each column are sequentially arranged with a fixed distance Pwr, thereby forming an array configuration on the first surface S1.

Although this embodiment illustrates the support units SP configured in a 5×5 array as an example, the present disclosure is not limited thereto. In some embodiments, at least two support units SP in each row/column are disposed at a peripheral region of the light guide plate 631. The peripheral region may be, for example, a region having a vertical distance between 0.01 mm to 0.5 mm from an edge of the body part 6311, although the present disclosure is also not limited thereto.

In some embodiments, the fixed distances Pwc and Pwr may be designed according to the dimensions of the light guide plate 631, which may be the same or different, which is also not limited in the present disclosure.

In some embodiments, the transparency of the support unit SP may be, for example, greater than or equal to 99%, preferably 99.9%, and the elastic recovery rate (ER) of the support unit SP is greater than 95%, although the present disclosure is not limited thereto. In some embodiments, the support unit SP may be, for example, a Photo Spacer formed on the body part 6311 by a photolithography process, and may be implemented with one or a combination of the following materials: Polymer, Oligomer, Photo Initiator, Curing Agent, Surfactant, and solvent.

In some embodiments, the polymer may, for example, include an acryl polymer, which is mainly used to improve mechanical properties of the support unit SP and development characteristics during lithography. The oligomer may, for example, include an acryl multifunctional monomer, which is mainly used to adjust mechanical characteristics and cross-linking density of the support unit SP, and may also be used to influence development characteristics. The photo initiator is mainly used to control the photosensibility, the crosslinking density, and the crosslinking formation control during the formation of the support unit SP. The curing agent may, for example, comprise a thermal cross-linking monomer, primarily to increase mechanical strength after thermal baking. The surfactant may be used to adjust the surface tension and coating characteristics of the support unit SP before curing. The solvent is, for example 1, 2-propylene glycol methyl ether acetate (PGMEA), Cyclohexanone or 3-Methoxybutyl Acetate, and is mainly used to adjust the volatilization speed, photoresist leveling interval and compatibility with other solvents during lithography.

Referring next to FIG. 23B, this embodiment is substantially the same as the previously described embodiment of FIG. 23A, and similar parts are described with reference to the above embodiments and will not be repeated here. The main difference between the embodiment of FIG. 23B and the embodiment of FIG. 23A is that the support units SP are arranged differently in this embodiment. In this embodiment, the support units SP are formed on the first surfaces S1 and S2 of the body part 6311 in an “X”-shaped arrangement within the central region Sc. In the peripheral region other than the central region Sc, the support units SP are sequentially arranged at a fixed interval Pwc in the x-direction and sequentially arranged at a fixed interval Pwr in the y-direction in a manner similar to those in FIG. 23A.

Viewed from another perspective, the support units SP of this embodiment are sequentially arranged at a fixed interval Pwd1 in the first direction d1, and sequentially arranged at a fixed interval Pwd2 in a second direction d2 perpendicular to the first direction d1, wherein the support units SP arranged in the first direction d1 share the same support unit SP at a center point with the support units SP arranged in the second direction d2, thereby forming an “X”-shaped arrangement.

Referring next to FIG. 23C, this embodiment is substantially the same as the previous embodiment of FIG. 23A, and similar parts are described with reference to the previous embodiment, and the description thereof will not be repeated here. The main difference between the embodiment of FIG. 23C and the embodiment of FIG. 23A is that the support units SP of this embodiment are formed on the first surfaces S1 and S2 of the body part 6311 in a “X”-shaped arrangement.

Viewed from another perspective, the support units SP of this embodiment are sequentially arranged at a fixed interval Pwd1 in the first direction d1, sequentially arranged at a fixed interval Pwd2 in a second direction d2 perpendicular to the first direction d1, and sequentially arranged at fixed intervals Pwx and Pwy in the X-direction and the y-direction, respectively, wherein the support units SP arranged in the first direction d1, the support units SP arranged in the second direction d2, and the support units SP arranged in the X-direction share the same support unit SP at a center point, thereby constituting a “X”-shaped arrangement.

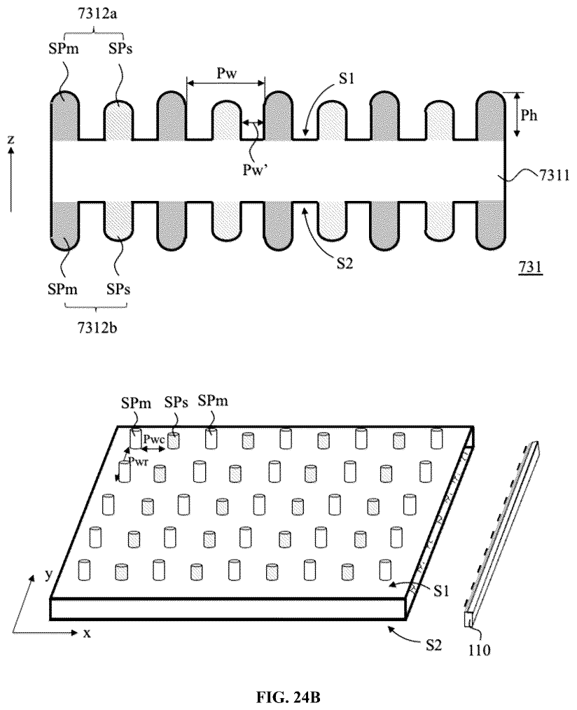

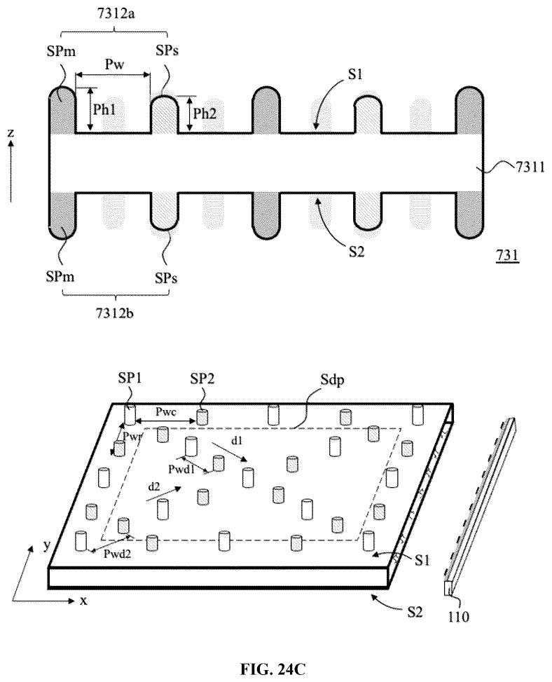

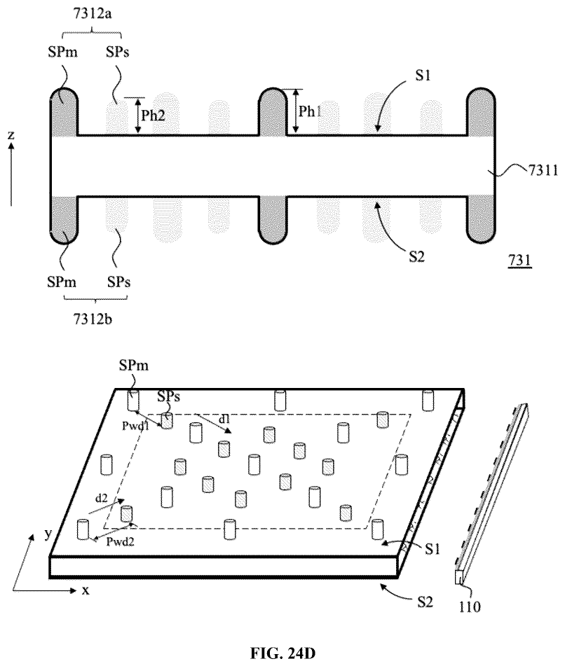

FIGS. 24A to 24D are embodiments having a second type of light guide plate structure, which can be applied to the configurations of the backlight module 100a and 100b described in the embodiment of FIGS. 20A and 20B above. Referring first to FIG. 24A, where an upper portion of FIG. 24A illustrates a side view of the light guide plate 731 and a lower portion of FIG. 24A illustrates a top view of the light guide plate 731. The light guide plate 731 of this embodiment includes a body part 7311 and reinforcing parts 7312a and 7312b, wherein the reinforcing parts 7312a and 7312b are formed on opposite sides of the body part 7311, respectively. The surface of the light guide plate 731 on the side where the reinforcing part 7312a is formed is the first surface S1, which is directed toward the display panel 100′ (i.e., toward the light intensifying plate 134); the surface of the light guide plate 731 on the opposite side of the body part 7311 is the second surface S2, which faces the reflector plate 133. In this embodiment, the first surface S1 is the exit surface of the light guide plate 731. Specifically, the reinforcing parts 7312a and 7312b include a plurality of columnar first support units SPm and second support units SPs each having a light transmitting property and a degree of rigidity. Taking the reinforcing part 7312a as an example, the first support units SPm have a height Ph1, and the second support units SPs have a height Ph2, wherein the height Ph1 would be greater than the height Ph2, and the first support units SPm and the second support units SPs would be formed on the first surface S1 at intervals. The distance between adjacent first support units SPm and second support units SPs is Pw. The height of the first support units SPm may be, for example, between 2 μm and 3 μm, and the height Ph2 of the second support units SPs may be, for example, between 1.5 μm and 2.5 μm, although the present disclosure is not limited thereto.

In this embodiment, the distance Pw of the support units SP of two adjacent columns may be a fixed distance Pwc, and the distance Pw of the support units SP of two adjacent rows may be a fixed distance Pwr. In other words, the support units SP in each row are sequentially arranged with a fixed distance Pwc, and the support units SP in each column are sequentially arranged with a fixed distance Pwr, thereby forming an array configuration on the first surface S1. In this embodiment, any one of the support units SPm/SPs will have a different height than an adjacent support unit does, wherein the so-called “adjacent support unit” is the closest support unit in the x direction or y direction as an example. For example, for any first support unit SPm, the second support units SPs are arranged above, below, left and right thereof.

Specifically, since the height Ph2 of the second support units SPs is smaller than the height Ph1 of the first support units SPm, when the first support units SPm are deformed/indented by being compressed by a stress, the second support units SPs can provide further support to prevent the body part 7311 of the light guide plate 731 from being compressed and bent when the first support units SPm are deformed by a force to a certain extent. In other words, by the arrangement of the first support unit SPm and the second support unit SPs, different support heights Ph1 and Ph2 can be provided on the light guide plate 731 so that the first support unit SPm and the second support unit SPs provide a support force with a break when the light guide plate 731 is pressed to prevent a bad display.

More specifically, since each of the support units SPm/SPs is subjected to stress, the support point on the body part 7311 is relatively subjected to force, and a slight deformation occurs, so that the display effect may be affected. Therefore, compared to the embodiment of FIG. 23A, this embodiment replaces some of the first support units SPm with the second support units SPs having a lower height. That is, by the configuration of the first support unit SPm and the second support unit SPs having the height difference, the number of support units SPm/SPs actually subjected to force in a general state (i.e., a state in which the stress applied to the light guide plate 731 by the front and rear members can be supported by the first support units SPm alone) is reduced, and the second support units SPs provide additional support force in a stressed state (i.e., a state in which the first support units SPm are subjected to the stress that causes deformation to the extent that the stress is applied to the second support units SP), thereby achieving an optimized performance between the display effect and the structural protection.

Referring next to FIG. 24B, this embodiment is substantially the same as the previous embodiment of FIG. 24A, and similar parts are described with reference to the previous embodiment, and the description thereof will not be repeated here. The main difference between the embodiment of FIG. 24B and the embodiment of FIG. 24A is that the arrangement configuration of the first support units SPm and the second support units SPs of this embodiment is different. In this embodiment, the first support units SPm are arranged as shown in FIG. 23A, so that the distance between two adjacent first support units SPm is Pw. The second support units SPs will be formed between adjacent first support units SPm and have substantially the same distance Pw′ from the adjacent first support units SPm. In other words, the distance Pw′ will be substantially slightly less than half the distance Pw.

Viewed from another perspective, the first support units SPm and the second support units SPs of this embodiment are sequentially arranged with a fixed interval Pwr in the x-direction or the y-direction (this embodiment is illustrated as y-direction arrangement as an example, although the present disclosure is not limited thereto), wherein the first support units SPm of each column are staggered with the second support units SPs of each column such that adjacent first support units SPm and second support units SPs have a fixed distance Pwc therebetween.

Referring next to FIG. 24C, the configuration of the support unit of this embodiment is substantially the same as that of the previous embodiment of FIG. 23B, so that similar parts will be described with reference to the previous embodiment, and the description thereof will not be repeated here. The main difference between the embodiment of FIG. 24C and the embodiment of FIG. 23B is that this embodiment makes use of the first support units SPm and the second support units SPs having different heights to make an “X”-shaped arrangement in which both the first support units SPm and the second support units SPs are staggered at intervals in the first direction d1 and the second direction d2, for achieving the effects described above in the embodiment of FIG. 24A.

Referring next to FIG. 24D, the configuration of the support unit of this embodiment is substantially the same as that of the previous embodiment of FIG. 23C, so that similar parts will be described with reference to the previous embodiment and will not be repeated here. The main difference between the embodiment of FIG. 24D and the embodiment of FIG. 23C is that this embodiment makes use of the first support units SPm and the second support units SPs having different heights to make a “X” shaped arrangement, in which the first support units SPm and the second support units SPs are staggered at intervals in the x-direction, the y-direction, the first direction d1, and the second direction d2, for achieving the effects described above in the embodiment of FIG. 24A.

From another perspective, this embodiment provides the first support unit SPm at the center of the body part 7311, and the second support unit SPs around its periphery as a step support.

It should be noted here that while the embodiments described above with respect to FIGS. 23A-24D have been described primarily with respect to the reinforcing part 7312a on the first surface S1, those skilled in the art will appreciate that similar structural configurations may also be applied to the reinforcing part 7312b on the second surface S2. In addition, the reinforcing parts 7312a and 7312b may have the same or different support structures, previously described herein.

In addition to this, it can be seen from the above-described embodiment of FIGS. 23A-24D that the support units are formed at least in the central region (particularly at the center) and in the four corners of the body part for providing relatively stable structural support.

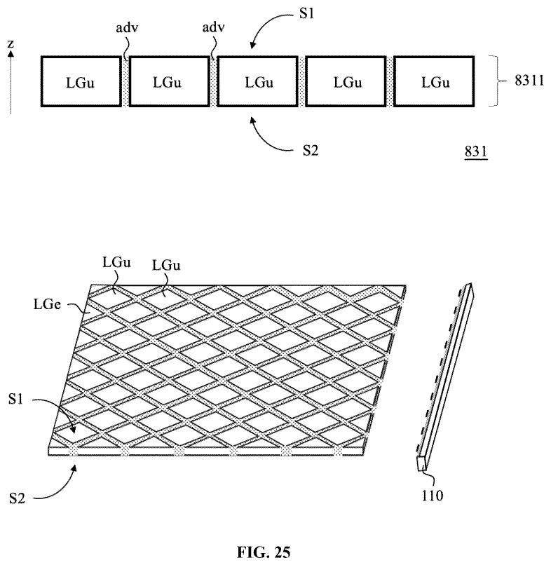

FIG. 25 is an embodiment having a third type of light guide plate structure, which can be applied to the configuration of the backlight modules 100a to 100e described in the embodiment of FIGS. 20A to 20E above. Referring to FIG. 25, where the upper portion of FIG. 25 depicts a side view of the light guide plate 831 and the lower portion of FIG. 25 depicts a top view of the light guide plate 831. The light guide plate 831 of this embodiment includes a body part 8311, wherein the body part 8311 is consisting of a plurality of light guide units LGu, and adjacent light guide units LGu are mutually adhered and secured together at an adhering part adv such that the mutually adhered plurality of light guide units LGu form a substantially continuous first surface S1 (i.e., the first surface S1 of the light guide plate 831) and a second surface S2 (i.e., the second surface S2 of the light guide plate 831) opposite the first surface S1. The first surface S1 is directed towards the display panel 100′ (i.e. towards the light intensifying plate 134) and the second surface S2 is directed towards the reflector plate 133. In this embodiment, the first surface S1 is the exit surface of the light guide plate 831.

It should be noted here that the substantially continuous first/second surface S1/S2 means that the upper/lower surface of the respective light guide units LGu will lie substantially in the same plane when the light units LGu are attached to each other by the adhering part adv. That is, the height drop between the joined light guide units LGu is within a tolerance range without exhibiting a bumpy visual perception.

In particular, the light guide unit LGu may be a standard module having a parallelogram structure (i.e. each module has the same dimensions within tolerances). Forming the light guide plate 831 by joining a plurality of light guide units LGu can effectively break the directivity of the light emitting part 110, so that light can be more uniformly diffused over the entire body part 8311 and emitted from the exit surface. Therefore, it is possible to obtain a more uniform surface light source using the backlight module of the light guide plate 831, thereby effectively improving the light source uniformity of the backlight module as a whole. In the meantime, since the light guide plate 831 does not cause the light source to be additionally shielded so that the light intensity decreases, the luminous efficiency of the backlight module can be increased to a large extent and the overall power consumption can be reduced.

In addition to this, since the adhering part adv can be implemented by optically clear adhesive (OCA) or other gluing material with a certain degree of viscoelasticity, the light guide plate 831 joined by the light guide units LGu, even when pressed, can absorb the stress of the pressing through the adhering part adv without the risk of warping as in a conventional one-sided light guide plate. The risk of deformation of the light guide plate due to thermal expansion and moisture expansion can also be effectively reduced/eliminated.

On the other hand, since the light guide plate 831 of an arbitrary size can be manufactured by increasing or decreasing the number of joined light guide units LGu, there is no need to make adjustments of molds and manufacturing processes for size requirements of backlight module in different products, which can effectively simplify the manufacturing process of the light guide plate 831 and reduce manufacturing costs and cycles. Further, since the light guide plate 831 is consisting of a plurality of small modules, if an individual block fails, maintenance and replacement can be performed for the failed block without replacing the entire light guide plate 831, so that the cost and expense of maintenance can be effectively reduced.

In some embodiments, the plurality of light guide units LGu may have a rhombus structure, wherein a first diagonal length of each light guide unit LGu is between 10 mm and 100 mm, and a second diagonal length is between 17.32 mm and 173.2 mm, although the present disclosure is not limited thereto.

In some embodiments, to constitute a rectangular light guide plate 831, a non-parallelogram (or non-rhombus) light guide unit LGe is included at the edge of the body part 8311. As shown in FIG. 25, the light guide unit LGe at the edge of the body part 8311 may, for example, have a triangular structure corresponding to the size of the light guide unit LGu of a parallelogram, to constitute a rectangular light guide unit 831 with the light guide plate LGu having a parallelogram (or rhombus) structure at the edges and corners.

In some embodiments, the LED of the light-emitting part may be attached at the side or bottom of the light guide plate 831 in order to guide light into the light guide plate 831 and achieve a backlight effect; therein, the LED may be attached on the light guide unit LGe of the edge, although the present disclosure is not limited thereto.

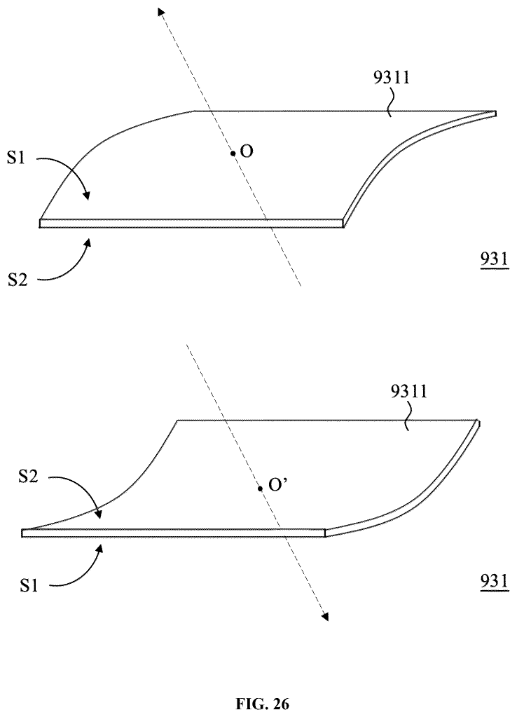

FIG. 26 is an embodiment having a fourth type of light guide plate structure, which can be applied to the configuration of the backlight module 100a to 100e described in the embodiments of FIGS. 20A to 20E above. Referring to FIG. 26, where the upper portion of FIG. 26 depicts a top view of the light guide plate 931 and the lower portion of FIG. 26 depicts a bottom view of the light guide plate 931. The light guide plate 931 of this embodiment includes a body part 9311 having a curved surface structure, wherein the body part 9311 has a positive curvature on the center point O of the first surface S1, and the body part 9311 has a negative curvature on the center point O′ of the second surface S2 with respect to the first surface S1. In other words, the body part 9311 is provided as a raised structure in the central region such that the shortest distance between at least one point of the first surface S1 on the central region and the display panel 100′ (or the light intensifying plate 134) will be smaller than the shortest distance between at least one point on the peripheral region and the display panel 100′; similarly, the shortest distance between at least one point of the second surface S2 on the central region and the reflector plate 133 may be greater than the shortest distance between at least one point on the peripheral region and the reflector plate 133.

In some embodiments, the curvature of the body part 9311 may be set to be greater than 1500 R (i.e., the radius of curvature is 1500 mm), although the present disclosure is not limited thereto. Further, in some embodiments, the LED of the light-emitting part may be attached at the edge or bottom of the body part 9311, which is also not limited in the present disclosure.

With the structure of the curved light guide plate 931 shown in FIG. 26, the light source projected to the central region of the body part 9311 can be influenced by the curved surface and have cross interference, so that the light is uniformly diffused to the peripheral region of the body part 9311, thereby achieving higher conversion efficiency of the light source.

In addition to this, the configuration of the curved light guide plate 931 can also achieve a special light source effect backlight module to improve proprietary performance.

It should be noted here that those skilled in the art will appreciate that each light guide plate embodiment presented in the present disclosure can be applied not only in a backlight module alone, but also in a common light guide plate design simultaneously with reference to the above description. For example, the facet-taking light guide plate 931 shown in FIG. 26 may also have optical microstructure (e.g., 2312) and reflecting part (e.g., 2313) as illustrated in FIGS. 21A-21D, which is not limited in the present disclosure. In other words, although the present disclosure is not exhaustive of all possible combinations of embodiments, one of ordinary skill in the art in view of the above description should be able to derive possible permutations of embodiments within the reasonable scope, so that any combination of embodiments of the present disclosure is supported by the present disclosure.

The design of the quantum dot film part for the backlight module in the display device 10/30 will be further explained below.

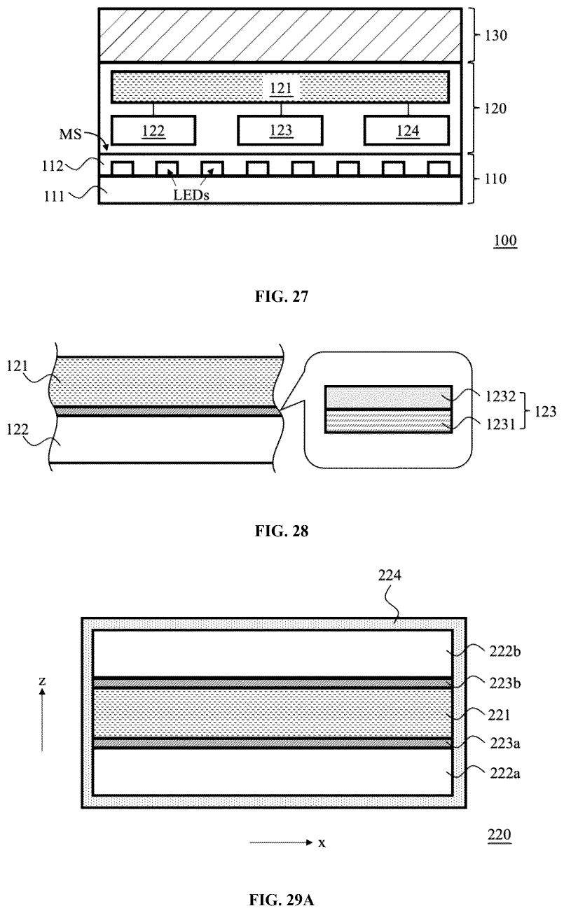

The configuration of the backlight module 100 of FIG. 1A according to an embodiment of the present disclosure may be as shown in FIG. 27, wherein FIG. 27 is a schematic diagram of a backlight module according to an embodiment of the present disclosure. Referring to FIG. 27, in this embodiment, the light-emitting layer 110 includes light-emitting elements LEDs, a substrate 111, and a protective layer 112. The light-emitting elements LEDs are disposed on the substrate 111 and emit light in the direction of the quantum dot film 120. A protective layer 112 overlies the light-emitting elements LEDs.

The quantum dot film 120 includes an active layer 121, a support layer 122, a bonding layer 123, and a waterproof layer 124. The active layer 121 may include a base material (not shown) and quantum dots (not shown) doped in the base material, wherein the base material may be, for example, a light-transmissible macromolecular polymer material such as a resin material, and the quantum dots may be, for example, semiconductor quantum dots synthesized in nanocrystalline semiconductor materials such as II-VI semiconductor materials, III-V semiconductor materials, or other combination materials, although the present disclosure is not limited thereto. When the quantum dots are irradiated with light, they excite a color light having a wavelength different from that of the irradiated light. For example, the quantum dots can be illuminated with blue light to excite green and red light.

The support layer 122 is disposed on the exit surface MS of the light-emitting layer 110 and serves to carry/fix the active layer 121 such that the material of the active layer 121 can be attached/coated on the support layer 122. The support layer 122 may be formed, for example, of an organic polymer and/or an inorganic material having light-transmitting properties and some supportive properties. The organic polymer can be, for example, Polyvinylidene Chloride (PVdC), Cyclic Olefin Copolymer (COC), High Density Polyethylene (HDPE), Polyethylene terephthalate (PET), Polyimide (PI), Polyethersulfone (PES), Polyethylene Naphthalate (PEN), Polycarbonate (PC), or a combination of the foregoing materials. The inorganic material may be, for example, a metal oxide (e.g., SiOx, SixNy, etc.).

In some embodiments, the support layer 122 may be a polymeric barrier film formed from PVdC and COC materials, which may provide a degree of water-oxygen barrier.

The bonding layer 123 is used to provide a bonding force so that the active layer 121 and the support layer 122 can be effectively and reliably adhered/secured, wherein the bonding layer 123 may be formed with, for example, an Optical Clear Adhesive (OCA) or a surface treatment agent (Primer). In some embodiments, the bonding layer 123 may also include a dielectric material to improve the insulating properties of the bonding layer 123, as shown in FIG. 28.

FIG. 28 shows a schematic view of a bonding layer of a quantum dot film according to an embodiment of the present disclosure. Referring to FIGS. 27 and 28 together, a bonding layer 123 is disposed between the active layer 121 and the support layer 122. The bonding layer 123 of this embodiment includes an adhesive layer 1231 and an insulating layer 1232, wherein the adhesive layer 1231 may be formed based on an Optical Clear Adhesive or a surface treatment agent, and the insulating layer 1232 may be formed based on a dielectric material. The dielectric material may be, for example, silicon nitride, silicon oxide, or other metal oxide, although the present disclosure is not limited thereto.

It should be noted here that although it is illustrated for the bonding layer 123 in the drawing that the adhesive layer 1231 and the insulating layer 1232 are arranged sequentially, the present disclosure is not limited thereto. In some embodiments, the material of insulating layer 1232 may also be doped into adhesive layer 1231 such that there is no significant delamination between adhesive layer 1231 and insulating layer 1232.

In addition, although the bonding layer 123 is illustrated as having a certain thickness in the drawings, it is illustrated only in a scale for convenience of description and does not represent a relationship between thicknesses of layers in an actual product. Since the bonding layer 123 may be a layer of Optical Clear Adhesive coated on the support layer 122, the bonding layer 123 is not necessarily visually visible on the cross-sectional structure of the actual quantum dot film 120, and may need to be confirmed by electron microscopy at a higher magnification. In fact, if it is observed in the quantum dot film 120 that the sandwich structure formed by the support layer 122 and the active layer 121 can be attached efficiently and reliably, those skilled in the art will recognize that there is necessarily a bonding layer 123 between the support layer 122 and the active layer 121, and therefore, the presence or absence of the bonding layer 123 is not a judgment of whether it is visually visible or not in an actual product alignment.

Referring again to FIG. 27, a waterproof layer 124 is directly or indirectly coated on at least a portion of the surface of the active layer 121 to prevent the active layer 121 from being properly affected by moisture, thereby extending the working life of the active layer 121. Specifically, the waterproof layer 124 may be implemented using a thin film of a polymer material with protection. For example, the waterproof layer 124 may be implemented using Poly-para-xylylene (Parylene). The Parylene has characteristics such as high and low temperature resistance, corrosion resistance, acid and base resistance, water and moisture resistance, transparency, and high insulating strength, therefore the effect of moisture on the active layer 121 can be effectively insulated when the Parylene covers the active layer 121 as the waterproof layer 124.

In conventional applications, the barrier ability of the quantum dot film to water and oxygen is mainly provided by the material properties against the support layer and the bonding layer, making the choice of materials in design relatively limited and the cost difficult to reduce. In addition, sandwich structures are commonly used in the industry for quantum dot film manufacturing. With this structure, it is also difficult to completely protect the active layer by the arrangement of the support layer and the bonding layer alone, so that the conventional quantum dot film is still susceptible to environmental problems such as moisture, humidity and the like, resulting in a shortened working life.

The quantum dot film 120 proposed in the embodiments of the present application can provide a preliminary water-blocking effect by the support layer 122 and the bonding layer 123, and the waterproof layer 124 covering the active layer 121 further blocks moisture from the active layer 121, making the active layer 121 less susceptible to moisture. In addition, since the waterproof layer 124 substantially increases the water resistance of the quantum dot film 120, more choices can be made for the materials of the support layer 122 and the bonding layer 123 to meet design considerations while compromising cost requirements.

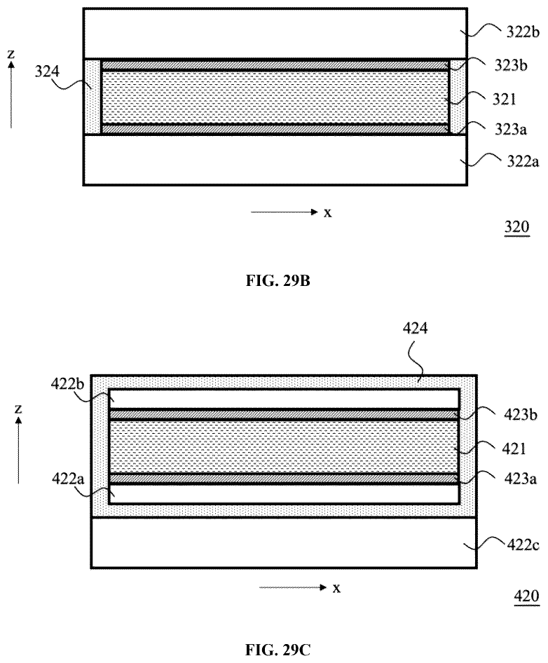

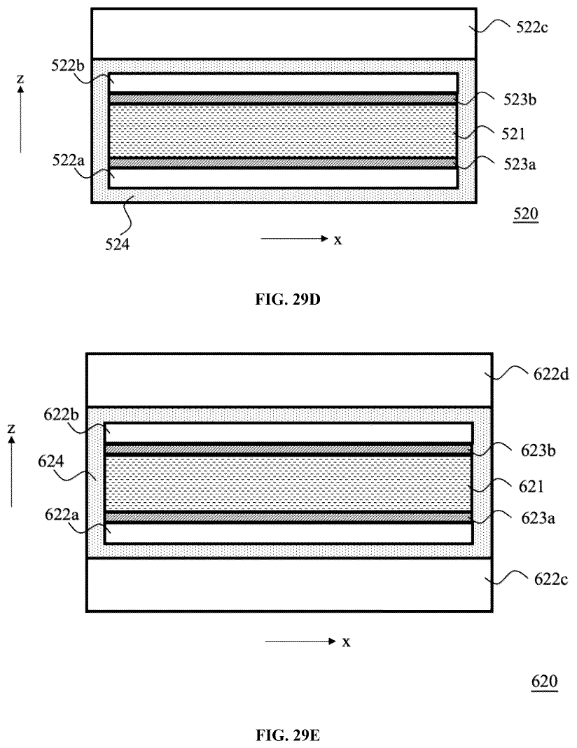

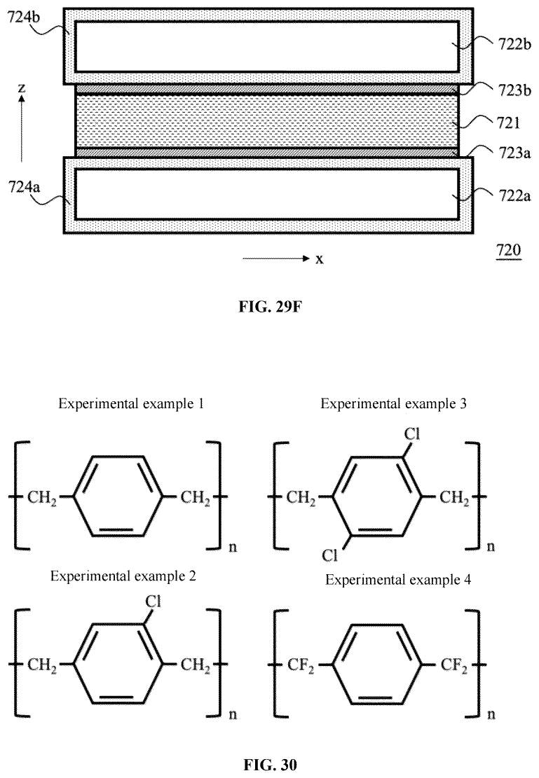

The structural arrangement of the waterproof layer 124 under various embodiments will be described in more detail below with reference to FIGS. 29A-29F, which are cross-sectional structural diagrams of the quantum dot film according to various embodiments of the present disclosure.

Referring first to FIG. 29A, the quantum dot film 220 of this embodiment includes an active layer 221, support layers 222a and 222b, bonding layers 223a and 223b, and a waterproof layer 224. In this embodiment, the support layers 222a and 222b are disposed on opposite sides of the active layer 221, respectively, and are connected to the active layer 221 by bonding layers 223a and 223b, respectively. Referring to FIG. 29A, the lower surface of the active layer 221 is connected/attached to the upper surface of the support layer 222a through the bonding layer 223a; and the upper surface of the active layer 221 is connected/attached to the lower surface of the support layer 222b through a bonding layer 223b. In other words, the support layers 222a and 222b and the bonding layers 223a and 223b form a sandwich structure on opposite sides of the active layer 221.

The waterproof layer 224 covers the exposed surfaces of the active layer 221, the support layers 222a and 222b, and the bonding layers 223a and 223b. Although not shown in the schematic cross-sectional view of FIG. 29A, the waterproof layer 224 also wraps the sandwich structure in the y-axis direction. In addition, the exposed surfaces of the active layer 221, the support layers 222a and 222b, and the bonding layers 223a and 223b in the x-z plane may also be covered with the waterproof layer 224.

In other words, the waterproof layer 224 in this example covers the entire sandwich structure formed by the active layer 221, the support layers 222a and 222b, and the bonding layers 223a and 223b.

Further, although the active layer 221, the support layers 222a and 222b, and the bonding layers 223a and 223b of this embodiment are illustrated as having the same width (i.e., the same length in the x-axis direction), the present disclosure is not limited thereto. In other embodiments, the active layer 221, the support layers 222a and 222b, and the bonding layers 223a and 223b may also have different widths.

Referring to FIG. 29B, the quantum dot film 320 of this embodiment includes an active layer 321, support layers 322a and 322b, bonding layers 323a and 323b, and a waterproof layer 324. This embodiment is similar to FIG. 29A with respect to the arrangement of the active layer 321, the support layers 322a and 322b, and the bonding layers 323a and 323b. The support layers 322a and 322b are disposed on opposite sides of the active layer 321 and connected to the active layer 321 through the bonding layers 323a and 323b, respectively, except that the width of the support layers 322a and 322b of this embodiment is larger than the width of the active layer 321 and the bonding layers 323a and 323b.

In this embodiment, the waterproof layer 324 covers the sidewalls of the active layer 321 and the bonding layers 323a and 323b to prevent moisture from intruding into the active layer 321 from the exposed sidewalls. In other words, the waterproof layer 324 of this embodiment covers only a partial region (i.e., at the sidewalls) of the active layer 321, as compared to the embodiment of FIG. 29A that completely wraps the sandwich structure.

Please refer to FIG. 29C, the quantum dot film 420 of this embodiment includes an active layer 421, support layers 422a, 422b, and 422c, bonding layers 423a and 423b, and a waterproof layer 424. This embodiment is substantially the same as the aforementioned embodiment of FIG. 29A, and is different from the embodiment of FIG. 29A in that the quantum dot film 420 of this embodiment further includes a support layer 422c provided on a side near the light-emitting layer.

In other words, the sandwich structure coated with the waterproof layer 424 and consisting of the active layer 421, the support layers 422a and 422b, and the bonding layers 423a and 423b is provided on the support layer 422c, and the quantum dot film 420 is connected to the light-emitting layer through the support layer 422c. This allows the water resistance of the quantum dot film 420 on the side closer to the light-emitting layer to be increased even further, and also allows the quantum dot film 420 to be further away from the heat source from being affected.

Additionally, although not shown in FIG. 29C, in some embodiments, a bonding layer may also be formed on the support layer 422c to bond with the waterproof layer 424.

Please refer to FIG. 29D, the quantum dot film 520 of this embodiment includes an active layer 521, support layers 522a, 522b, and 522c, bonding layers 523a and 523b, and a waterproof layer 524. This embodiment is substantially the same as the previously described embodiment of FIG. 29C, and is different from the embodiment of FIG. 29C in that the support layer 522c of this embodiment is provided on a side adjacent to the optical adjustment layer.

In other words, the support layer 522c is provided on a sandwich structure covered with the waterproof layer 524 and consisting of the active layer 521, the support layers 522a and 522b, and the bonding layers 523a and 523b, and the quantum dot film 520 is connected to the optical adjustment layer through the support layer 522c. In this way, the water barrier of the quantum dot film 520 on the side adjacent to the optical adjustment layer is even more enhanced.

Referring to FIG. 29E, the quantum dot film 620 of this embodiment includes an active layer 621, support layer layers 622a, 622b, 622c, and 622d, bonding layers 623a and 623b, and a waterproof layer 624. This embodiment is substantially the same as the previously described embodiment of FIGS. 29C and 29D, and differs from the embodiment of FIGS. 29C and 29D in that it includes both a support layer 622c disposed on a side adjacent to the light-emitting layer and a support layer 622d disposed on a side adjacent to optical adjustment layer.

In other words, the sandwich structure coated with the waterproof layer 624 and consisting of the active layer 621, the support layer 622a and 622b, and the bonding layers 623a and 623b is disposed between the support layer 622c and 622d, wherein the quantum dot film 620 is connected to the light-emitting layer through the support layer 622c and connected to the optical adjustment layer through the support layer 622d.

Referring to FIG. 29F, the quantum dot film 720 of this embodiment includes an active layer 721, support layers 722a and 722b, bonding layers 723a and 723b, and waterproof layers 724a and 724b. This embodiment is substantially the same as the previously described embodiment of FIG. 29A, except that the waterproof layer 724a and 724b of this embodiment are formed on the support layers 722a and 722b, respectively, and the support layers 722a and 722b with the waterproof layers 724a and 724b attached thereto are formed into a sandwich structure with the active layer 721 through corresponding bonding layers 723a and 723b.

In other words, the waterproof layers 724a and 724b of this embodiment are indirectly covered on the lower surface (i.e., the surface on the side near the light-emitting layer) and the upper surface (i.e., the surface on the side near the optical adjustment layer) of the active layer 721 by the bonding layers 723a and 723b, respectively. Such a configuration may be considered to utilize waterproof layers 724a and 724b to further enhance the water resistance of support layers 722a and 722b.

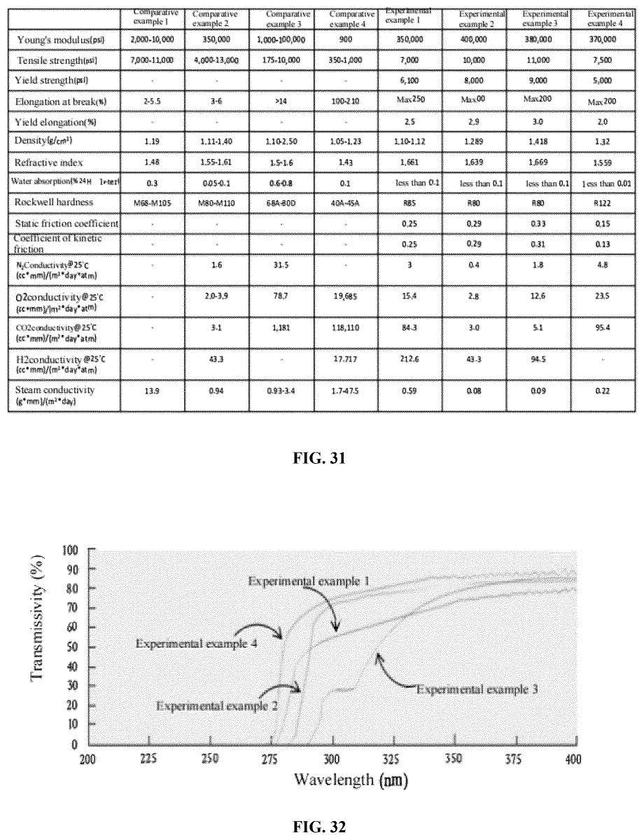

FIGS. 30-33 below illustrate the characteristics of the waterproof layer 124 made with different material embodiments. Reference is first made to FIG. 30 and FIG. 31, where FIG. 30 illustrates the chemical structure of a waterproof layer material of a quantum dot film according to various embodiments of the present disclosure, and FIG. 31 illustrates a tabulation of mechanical properties of a waterproof layer material according to various embodiments of the present disclosure.

The chemical structures of the waterproof layer materials of Experimental Examples 1 to 4 are shown in FIG. 30, which are respectively: Experimental Example 1) Poly-p-xylylene (Parylene N) or N-type Parylene, Experimental Example 2) Poly-monochloro-p-xylylene (Parylene C) or C-type Parylene, Experimental Example 3) Poly-dichloro-p-xylylene (Parylene D) or D-type Parylene, and Experimental Example 4) HT-type Parylene (Parylene HT).

The mechanical properties of the above Experimental Examples 1-4 and Comparative Examples 1-4, which are Acrylic (AR), Epoxy Resin (ER), Polyurethane (PU), and Silicone (SR), in order, are listed in FIG. 31. As can be seen from the mechanical properties of FIG. 31, forming a waterproof layer with the materials of Experimental Examples 1-4 has lower moisture and gas permeability and high insulating strength compared to Comparative Examples 1-4.

FIG. 32 shows the light transmittance of Experimental Examples 1-4 at different wavelengths, respectively. From FIG. 32, it can be found that the materials of Experimental Examples 1 to 4 all have good light transmittance at wavelengths over 400 nm.

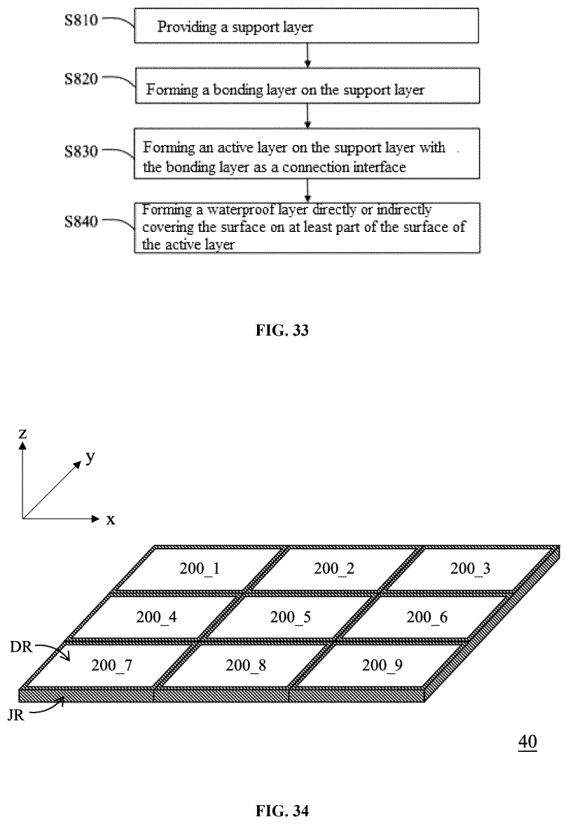

FIG. 33 is a flow chart showing the steps of a method of manufacturing a quantum dot film according to an embodiment of the present disclosure. Referring to FIG. 33, the manufacturing method of the quantum dot film according to this embodiment is suitable for manufacturing the quantum dot film as described in the aforementioned FIGS. 29A to 29F. In the step flow of this embodiment, first, a support layer is provided (step S810), and then a bonding layer is formed on the support layer (step S820). The step of forming a bonding layer on the support layer may be, for example, coating an Optical Clear Adhesive (OCA) or a surface treatment agent (Primer) on the support layer. After forming the bonding layer, an active layer is formed on the support layer with the bonding layer as a connection interface (step S830). Next, a waterproof layer directly or indirectly covering the surface is formed on at least part of the surface of the active layer (step S840).

In this embodiment, the above steps are illustrated as being performed sequentially, although the present disclosure is not limited thereto. The above steps may be replaced or repeated in order depending on the structural configuration of the quantum dot film to be applied. For example, in the case of manufacturing the quantum dot film 220 as shown in FIG. 29A, support layers 222a and 222b for connecting the lower surface and the upper surface of the active layer 221 are respectively provided in step S810, and then an adhesive material such as an Optical Clear Adhesive (OCA) or a surface treatment agent (Primer) is applied to the surfaces of the support layers 222a and 222b facing the active layer 221 to form the bonding layers 223a and 223b, respectively in step S820. In step S830, the active layer 221 material may be coated on the bonding layer 223a and/or 223b by sandwich coating, and the active layer 221 is sandwiched between the support layers 222a and 222b to form a sandwich structure.

The intermediate product after step S830 may be cut to conform to the size of the end product, and the cut sandwich structure may be subjected to step S840 to coat the surface of the sandwich structure with the waterproof layer 224, thereby forming the structure shown in FIG. 29A.

For another example, in the case of manufacturing the quantum dot film 720 of FIG. 29F, support layers 722a and 722b for connecting the lower surface and the upper surface of the active layer 721 are provided in step S810, respectively, and the flow proceeds to step S840 to form waterproof layers 724a and 724b on the surfaces of the support layers 722a and 722b, respectively. Thereafter, steps S820 and S830 are performed to combine the support layers 722a and 722b coated with the waterproof layers 724a and 724b and the active layer 721 into a sandwich structure.

The manufacturing flow of the other quantum dot film 320-620 can be derived from the above description and will not be repeated here.

The design of the spliced display device made up by the splice display panel 100′ is further explained below.

FIG. 34 shows a schematic diagram of a spliced display device according to an embodiment of the present disclosure. The display device 40 is formed by splicing a plurality of display panels. In this embodiment, a 3×3 spliced assembly is illustrated, that is, the display device 40 includes 9 display panels 200_1 to 200_9, although the present disclosure is not limited thereto. The spliced display panels 200_1 to 200_9 are synchronously driven to cooperatively display portions of a complete image, thereby composing a larger image to achieve a large-sized picture display effect. The display device 40 of this embodiment may be any electronic apparatus having a display function, such as a television, a screen, an LED billboard, or the like, the present disclosure is not limited thereto.

In this embodiment, at least part of the non-display region of each display panel 200_1 to 200_9 is used as the joint region JR (as in the diagonal region of FIG. 34) to splice with the adjacent display panel 200_1 to 200_9. The display device 40 also includes a joint unit (not shown) disposed at the joint region JR for reducing visual effects caused by seams at the junctions of the joint unit 200_1 to 200_9, making the junctions of the display panel 200_1 to 200_9 less perceptible. The joint unit may be implemented with specific substrate designs, additional LED bars, or specific optical structures, as will be further described in the following embodiments.

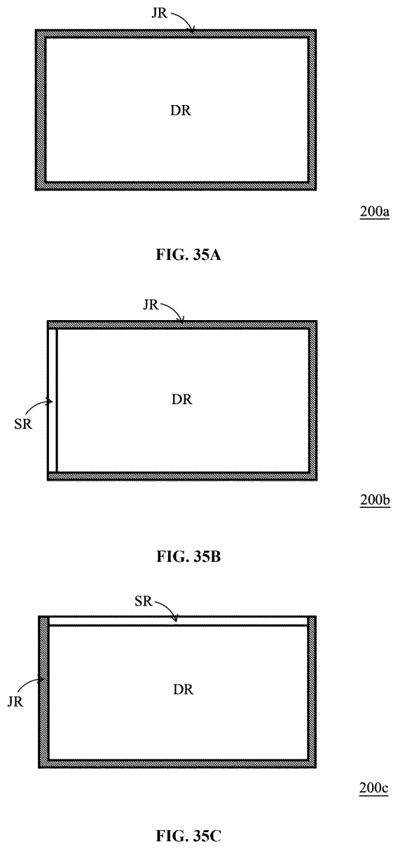

Each display panel 200_1 to 200_9 of this embodiment can be implemented in the configuration of FIGS. 35A to 35D according to design requirements, wherein FIGS. 35A to 35D are schematic configurations of the display panel for the display device 40 of FIG. 34 according to various embodiments.

Referring first to FIG. 35A, in this embodiment, the surrounding region of the display panel 200a is defined as the joint region JR, i.e., the non-display region of this embodiment is designed as the joint region JR for configuring the joint unit. Therefore, the display panel 200a of this embodiment can be suitably used as any one of the display panel 200_1 to 200_9 in the spliced display device 40 of FIG. 34.

Referring again to FIG. 35B, in this embodiment, three of the sides of the display panel 200b are defined as the joint region JR, and only the left short side non-display region SR is not defined as the joint region JR. In other words, in the display panel 200b of this embodiment, the joint units are disposed only on three sides defined as the joint region JR of the display panel 200b. The display panel 200b of this embodiment can be suitably used as the display panel 200_4 or 200_6 in the spliced display device 40 of FIG. 34.

Referring to FIG. 35C, in this embodiment, three sides of the display panel 200c are defined as the joint region JR, and only the non-display region SR of the upper long side is not defined as the joint region JR. In other words, in the display panel 200c of this embodiment, the joint unit is disposed only on three sides defined as the joint region JR in the display panel 200c. The display panel 200c of this embodiment is applicable as the display panel 200_2 or 200_8 in the spliced display device 40 of FIG. 34.

Referring to FIG. 35D, in this embodiment, the adjacent two sides of the display panel 200d are defined as the joint region JR, and the non-display region SR of the opposite other two sides are not defined as the joint region JR. In other words, in the display panel 200d of this embodiment, the joint unit is disposed only on adjacent long and short sides defined as the display panel JR in the joint region 200c. The display panel 200d of this embodiment is applicable as the display panel 200_1, 200_3, 200_7, or 200_9 in the spliced display device 40 of FIG. 34.

In addition, although not shown in the above embodiments, in some embodiments only one side of the display panel may be defined as the joint region JR, i.e. the joint unit is provided on only a single side of the display panel. Such a configuration may be suitable for use in a 2×1 spliced display device, although the present disclosure is not so limited.

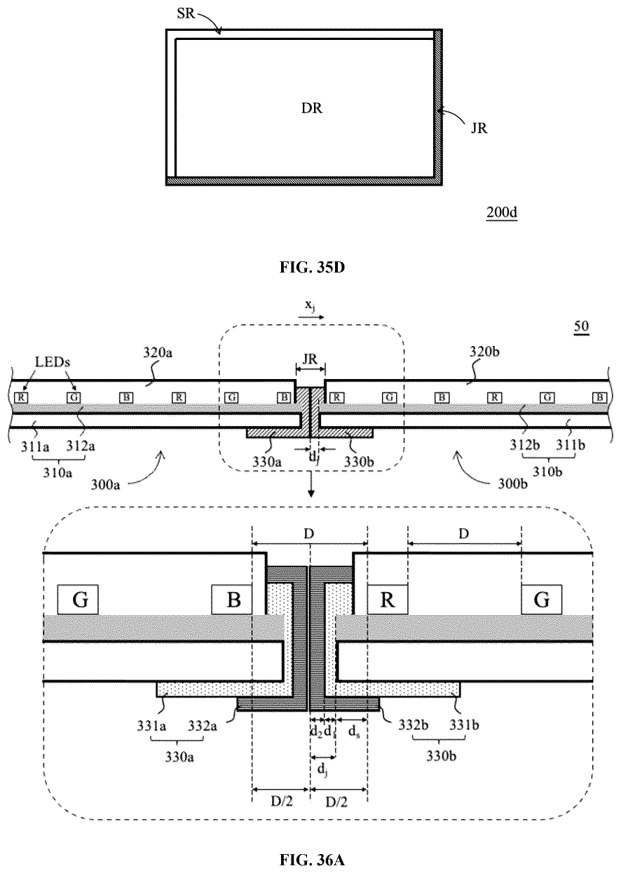

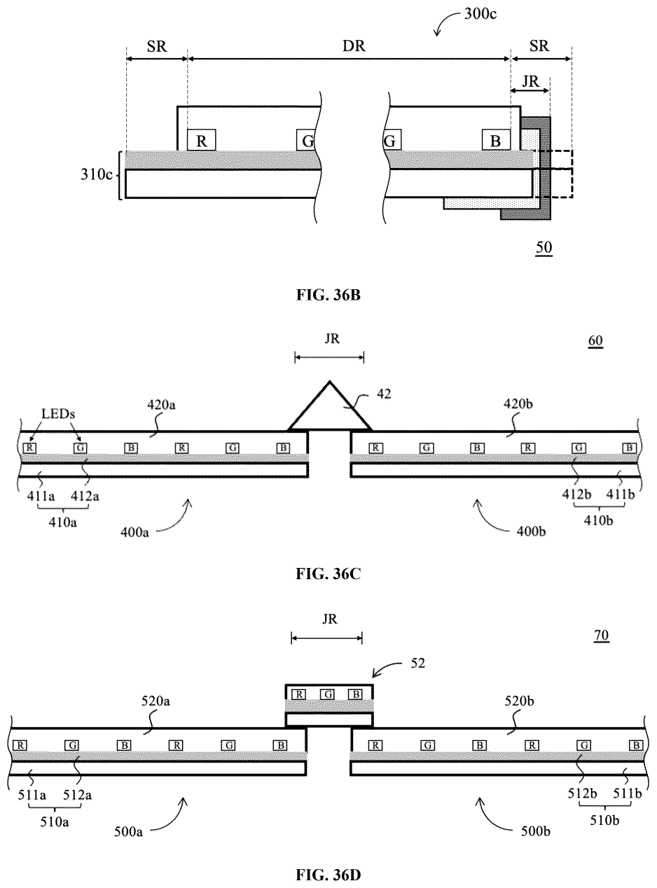

Below, different embodiments of the joint unit are illustrated with FIGS. 36A to 36D. Reference is now made to FIG. 36A, which illustrates a configuration of a display device according to an embodiment of the present disclosure. FIG. 36A illustrates a partially enlarged configuration schematic view at the splice of two adjacent joint display panels 300a and 300b in the display device 50, wherein the display panels 300a and 300b have similar/identical configurations, and this embodiment is illustrated with short-edge splicing as an example, although the present disclosure is not limited thereto.

The display panel 300a/300b includes light-emitting elements LEDs, a substrate 310a/310b, an element protection layer 320a/320b, and a joint unit 330a/330b, where the substrate 310a/310b includes an insulating layer 311a/311b and a line layer 312a/312b.

Here, the display panel 300b will be described, and the display panel 300a will be configured with reference to the following description, and the description thereof will not be repeated. The joint unit 330b is disposed at an edge of the substrate 310b and covers a sidewall of the substrate 310b and an edge-exposed region of the line layer 312b (i.e., a region not covered by the element protection layer 320b) to form a splice structure extending a thickness/distance dⱼ from the substrate 310b toward the adjacent substrate 310a. The thickness dⱼ of the splice structure described in this embodiment is defined as the shortest distance from the sidewall of the substrate 310b at the joint region JR to the edge of the joint unit 330b.

On the other hand, the width of the substrate 310b at the joint region JR is limited/reduced so that the distance dₛ between the edge of the substrate 310b to the closest light-emitting elements LEDs is defined within a certain range, wherein the distance dₛ is selected to have a corresponding relationship according to the distance between the light-emitting elements LEDs. For example, when the distance of adjacent light-emitting elements LEDs is D, the distance dₛ of the substrate 310b plus the distance dⱼ of the joint unit 330b may be designed to be D/2. With the above arrangement, when the adjacent display panel 300a and 300b are spliced, it is possible to maintain the same distance between the closest two light-emitting elements LEDs on the two display panels 300a and 300b as the adjacent light-emitting elements LEDs in the display panel 300a/300b, so that no significant joint gap is generated.

In view of the partially enlarged structure of FIG. 36A, with the above configuration, the distance D between the red light-emitting element R at the edge of the display panel 300b and the blue light-emitting element B at the edge of the display panel 300a is the same as the distance between the red light-emitting element R and the green light-emitting element G in the light-emitting element 300b. In this way, the elimination of the splice seam is achieved.

More specifically, the joint unit 330a/330b may include, for example, an extended conducting layer 331a/331b and a sidewall protective layer 332a/332b. The extended conducting layer 331a/331b is electrically connected to the corresponding line layer 312a/312b, and extends through the sidewall of the substrate 310a/310b to the back side of the insulating layer 311a/311b (i.e., the side not in contact with the line layer 312a/312b), such that other circuitry (not shown) may be electrically connected to the light-emitting elements LEDs of the display panel 300a/300b through the extended conducting layer 331a and 331b and the corresponding line layer 312a and 312b, wherein the extended conducting layer 331a/331b has a thickness d₁ on the sidewalls of the substrate 310a/310b, i.e. the thickness of the extended conducting layer 331a/331b in the joint direction xⱼ is d₁.

The sidewall protective layer 332a/332b covers at least part of the region of the extended conducting layer 331a/331b so that the adjacent extended conducting layers 331a and 331b are not accidentally shorted, wherein the sidewall protective layer 332a/332b covers, for example, at least a side wall of the extended conducting layer 331a/331b, i.e. a side of the extended conducting layer 331a/331b close to the adjacent substrate 310a/310b, and has a thickness d₂, i.e. the thickness of the sidewall protective layer 332a/332b in the joint direction xⱼ is d₂. In some embodiments, the sidewall protective layer material may be implemented, for example, with acryl material and resin.

In this embodiment, the sum, (d₁+d₂), of the thicknesses of the extended conducting layer 331a/331b and the sidewall protective layer 332a/332b in the splicing direction xⱼ would be equal to the thickness dⱼ of the joint unit 330a/330b. It should be noted here that the thickness d₁ of the extended conducting layer 331a/331b in the joint direction xⱼ described above refers to the shortest distance between the extended conducting layer 331a/331b and the substrate 310a/310b in the joint direction xⱼ; while the thickness d₂ of the sidewall protective layer 332a/332b in the joint direction xⱼ refers to the shortest distance between the sidewall protective layer 332a/332b and the extended conducting layer 331a/331b in the joint direction xⱼ, the present disclosure is not limited thereto.

Also illustrated with the display panel 300b, with the configuration of the above embodiment, the thicknesses d₁ and d₂ of the extended conducting layer 331b and the sidewall protective layer 332b in the splicing direction xⱼ can be designed to match the distance dₛ of the substrate 310b such that the sum of the thicknesses d₁ and d₂ and the distance dₛ is substantially equal to half of the distance D between the light-emitting elements LEDs (i.e., D/2). This allows the distance of the light-emitting elements LEDs on the two sides of the joint region to be the same as the distance D of the light-emitting element LEDs in the display panel 300b, thereby eliminating the visual impact of seams.

FIG. 36B further illustrates a structural configuration of display device 50 in which a display panel 300c is on a different edge. Referring to FIG. 36B, this embodiment illustrates the structural difference of the non-display region SR defined as the joint region JR and the non-display region SR not defined as the joint region JR. With the generally non-display region SR at the left edge of the display panel 300c, the edge of its substrate 310c and the light-emitting element LED/column (e.g., R) closest to the edge may have a wider distance to maintain electrical connection reliability of the light-emitting elements LEDs. In contrast, in the right non-display region SR, since the portion of the non-display region SR needs to be provided with a joint unit for splicing with an adjacent display panel, the original width (at the dotted line) of the substrate 310c of the non-display region SR is reduced to a distance that meets the above requirements. Thus, for a display panel 300c having both a non-display region SR defined as a joint region JR and that not defined as joint region JR, the arrangement of the light-emitting elements LEDs may have an asymmetrical configuration in appearance, that is, there may be the appearance that part of the edge columns/rows of light-emitting elements LEDs are farther from the edge of the substrate 310c and another part of the edge columns/rows of light-emitting elements LEDs are closer to the edge of the substrate 310c.

FIG. 36C is a schematic view showing the configuration of the display device according to another embodiment of the present disclosure, wherein the embodiment takes an optical microstructure as the joint unit of the display device 60 as an example. Referring to FIG. 36C, a partial enlarged configuration schematic diagram of a joint of two adjacent spliced display panels 400a and 400b in the display device 60, wherein the display panels 400a and 400b have similar/identical configurations, and this embodiment is also illustrated with short-edge splicing as an example, although the present disclosure is not limited thereto.

In this embodiment, the display device 60 further includes an optical microstructure 42 as a joint unit. The optical microstructure 42 is disposed at the joint region JR between the display panels 400a and 400b and serves to refract adjacent light rays so that the refracted light rays pass over the joint region JR, thereby reducing the visual impact of the splice. In other words, the joint unit of this embodiment is to make the line at the junction of the display device 60 appear less conspicuous by the refraction of light through the microstructure processing.

FIG. 36D is a schematic view showing a configuration of a display device according to another embodiment of the present disclosure, wherein the embodiment is a joint unit illustrating a lamp as the display device 70 as an example. Referring to FIG. 36D, a partial enlarged configuration diagram of a joint of two adjacent spliced display panels 500a and 500b in the display device 70, wherein the display panels 500a and 500b have similar/identical configurations, and this embodiment is also illustrated with short-edge splicing as an example, although the present disclosure is not limited thereto.

In this embodiment, the display device 70 further includes a light bar 52 as a joint unit. The light bar 52 is disposed at the joint region JR between the display panels 500a and 500b and is used to control the emission of light to reduce the visual impact of the splice.

Specifically, for the embodiment joint unit illustrated in FIGS. 36A-36D above, the embodiment depicted in FIGS. 36A and 36B is because the light-emitting element distance at the seam is equalized to the light-emitting element distance within the panel by way of structural configuration, further, the effect of the splice is eliminated, so the embodiment of FIGS. 36A and 36B can achieve the elimination of the splice by simply setting the substrate within the required specifications and adding simple structures (e.g., extended conducting layer 331b and sidewall protective layer 332b). Compared to the embodiment of FIGS. 36C and 36D, the embodiment of FIGS. 36A and 36B does not require the addition of additional devices such as optical microstructures 42 or light bars 52, which is a significant advantage in manufacturing cost.

In addition, there is no way for the pixels to emit light orderly at the joint region JR, either in the embodiment of FIG. 36C or FIG. 36D where the joint unit is subjected to secondary construction, therefore it only makes the lines at the joint region less visible, and its post-joint effect still has the problem of visible splicing seams or optical chromatic aberration in a front view. In contrast, the embodiment of FIGS. 36A and 36B does not have this problem and provides a more display effect.

Overall, by changing the distance from the edge of the light-emitting element to the edge of the substrate in the joint region JR according to the size of the LED chip in combination with the size of the pixel defined by the resolution requirement of the product, the thickness of the extended conducting layer on the side edge and the thickness of the protective layer on the side wall, and the consideration of the manufacturing process tolerance of all productions, the above-mentioned embodiments of FIGS. 36A and 36B perfectly solve the problem that one display panel of the spliced display device transits to another display panel, so that the joint line in the joint region can hardly be observed by users, and there will be no color deviation and discontinuity caused by light bars, so as to achieve a perfect stitching display effect, and there is no need for additional components and assembly costs.

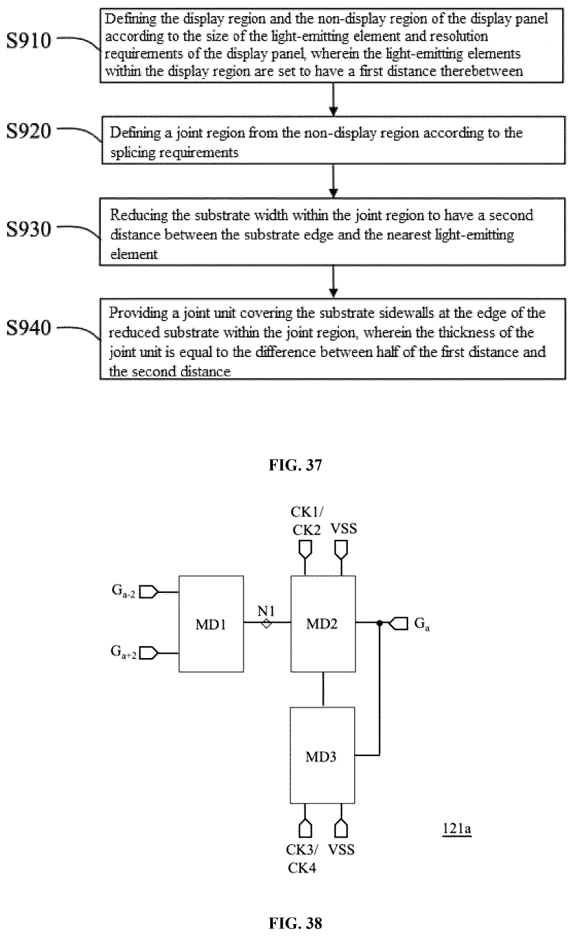

FIG. 37 is a flow chart showing the steps of a method of manufacturing a display panel in accordance with an embodiment of the present disclosure. Referring to FIG. 37, the manufacturing method of the display panel according to this embodiment is suitable for manufacturing the display panel as described in FIGS. 34 to 36B. In the process flow of this embodiment, the display region (e.g., DR) and the non-display region (e.g., SR) of the display panel are first defined according to the size of the light-emitting element and resolution requirements of the display panel to be manufactured, wherein the light-emitting elements within the display region are set to have a first distance therebetween (step S910). The size of the light-emitting element may be, for example, between 2 μm and 5 μm, although the present disclosure is not limited thereto. The first distance may be related to display panel size, light-emitting element size, and resolution requirements, and may be, for example, between 40 μm and 100 μm, although the present disclosure is not limited thereto.

Next, a joint region (such as JR) is defined from the non-display region according to the splicing requirements of the display panel (step S920). Similar to the previous embodiment of FIGS. 35A to 35D, the display panel may have different configurations of joint region JR depending on the joint position.

After the joint region is defined, the substrate width within the joint region is reduced to have a second distance between the substrate edge and the nearest light-emitting element (step S930). In step S930, the substrate may achieve width reduction by cutting and/or grinding manufacturing processes, wherein the second distance is related to manufacturing process tolerance in subsequent manufacturing processes in practical applications, which may be, for example, between 10 μm and 20 μm, although the present disclosure is not limited thereto.

Next, a joint unit (e.g., 330a/330b) covering the substrate sidewalls is provided at the edge of the reduced substrate within the joint region, wherein the thickness of the joint unit at substrate sidewalls is equal to the difference between half of the first distance and the second distance (step S940). The relationship between the thickness, the first distance, the second distance of the above joint unit can be expressed with the following formula:

dⱼ=D/2−dₛ;
wherein dⱼ is a thickness of the joint unit, D is the first distance, and dₛ is the second distance. In some embodiments, the thickness dⱼ of the joint unit may be, for example, between 10 μm and 30 μm, although the present disclosure is not limited thereto.

It should be noted here that if the present disclosure defines the relationship between the thickness, the first distance, the second distance of the above joint unit in claims, those skilled in the art will appreciate that all three of the above are intended to lie within the enforceable range, and that numerical combinations that do not fall within the enforceable range do not fall within the scope of the claims and therefore do not present supportive or unenforceable problems. For example, if the first distance D is equal to 40 μm, the sum of the thickness dⱼ of the joint unit and the second distance dₛ is 20 μm. At this time, although a possible implementation range of the second distance Ds may be, for example, between 10 μm and 20 μm according to the above description, a person skilled in the art may understand that in this configuration, the second distance dₛ would not be 20 μm because this would cause the thickness dⱼ of the joint unit to fall within an unfeasible interval.

It should also be noted that steps S930 and S940 described above, although illustrated as being performed sequentially, the present disclosure is not limited thereto. In some embodiments, the method of manufacturing the display panel may proceed with step S940 followed by step S930, i.e., determining the thickness of the joint unit followed by determining the width of the substrate to be reduced.

In some embodiments, step S940 may include forming an extended conducting layer (e.g. 331a/331b) covering substrate sidewalls and at least part of the insulating layer at the edge of the substrate, and then forming a sidewall protective layer (e.g., 332a/332b) covering at least a partial region of the extended conducting layer, wherein the extended conducting layer has a first thickness on a sidewall of the substrate and the sidewall protective layer has a second thickness on a sidewall of the extended conducting layer, the sum of the first thickness and the second thickness being equal to the thickness of the joint unit.

Specifically, after determining the size and resolution of the product, the product design development department defines the specifications and size of the LED at the product development stage. In the manufacturing method of this embodiment, it is possible to increase manufacturing process tolerance that can be tolerated by the subsequent manufacturing process by selecting an LED chip that meets the smallest size particle required by the product specification. Furthermore, by concentrating the metal circuit region on the display panel line layer as much as possible or close to the LED chip, the non-display region can be freed up to maximize the specification and tolerance of the joint region cutting and grinding region. After determining the thickness of the extended conducting layer (e.g., d₁) and the thickness of the sidewall protective layer (e.g., d₂) required at the time of splicing, that is, the distance (e.g., dₛ) from the region where the substrate needs to be cut on the splicing side to the outermost LED chip is calculated such that the total length of the thickness (e.g., d₁) of the extended conducting layer on the splicing side and the thickness (e.g., d₂) of the sidewall protective layer plus the distance from the side of the LED to the side of the substrate (e.g., dₛ) is equal to half of the distance (e.g., D) of two LEDs, which is mathematically expressed as: dₛ+d₁+d₂=D/2.

When display panels manufactured by the above-described display panel manufacturing method are spliced, the LED distance at the joint region will theoretically be the same as the distance in the display panel, resulting in a perfect splicing result. This eliminates the need for additional microstructures or light bars to make the joint units. The choice of materials for the extended conducting layer of the joint region and the sidewall protective layer compromises the electrical requirements and the subsequent lighting requirements of the LEDs at the joint region, so that the dimming can compromise the brightness and color requirements. In some embodiments, the sidewall protective layer may be selected to be structurally scratch-resistant, wear-resistant, and protect the extended conducting layer to avoid problems of separation or broken lines.

The drive part of the display device 10-70 is further described below.

The functional module configuration of each scanning unit 121_1-121_m in the scanning drive circuit 120′ described in this embodiment may be as shown in FIG. 38, which is a schematic diagram of a scanning drive circuit according to some embodiments of the present disclosure. Referring to FIG. 38, the scanning unit 121a of this embodiment may represent a scanning unit connected to the ath scanning line (i.e., a may be any natural number between 1 and m). In this embodiment, the scanning unit 121a includes a first module MD1, a second module MD2, and a third module MD3.

The first module MD1 is electrically connected with the scan output ends Gₐ₋₂ of the scanning units of the first two stages and the scan output ends Gₐ₊₂ of the scanning units of the latter two stages, and generates a drive signal on the node N1 based on scanning signals of the scan output ends Gₐ₋₂ and Gₐ₊₂. The second module MD2 is electrically connected with the first module MD1 through the node N1, and decides the pull-up time point of the scanning signal outputted from the scan output end Gₐ according to the drive signal on the node N1, the clock signals CK1/CK3, and the reference signal VSS. The third module MD3 is electrically connected with the second module MD2 and the scan output end Gₐ, and decides a pull-down time point of the scanning signal outputted from the scan output end Gₐ according to the clock signal CK3/CK4 and the reference signal VSS.

In some embodiments, the clock signals CK1-CK4 have different phases. In some embodiments, the clock signals CK1 and CK2 are reverse in phase with each other, and the clock signals CK3 and CK4 are reverse in phase with each other. In some embodiments, the phase of the clock signal CK3 lags the phase of the clock signal CK1 by approximately 90 degrees, the phase of the clock signal CK2 lags the phase of the clock signal CK3 by approximately 90 degrees, and the phase of the clock signal CK4 lags the phase of the clock signal CK2 by approximately 90 degrees.

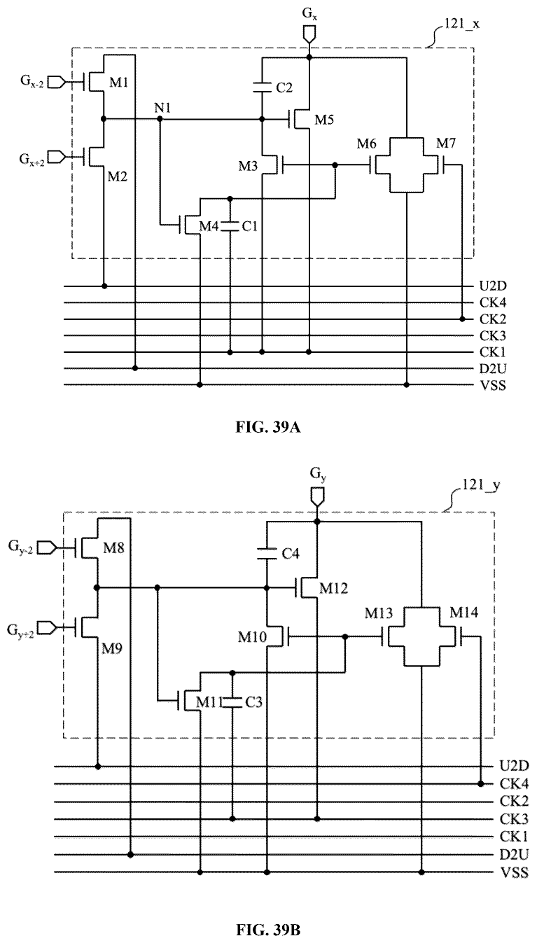

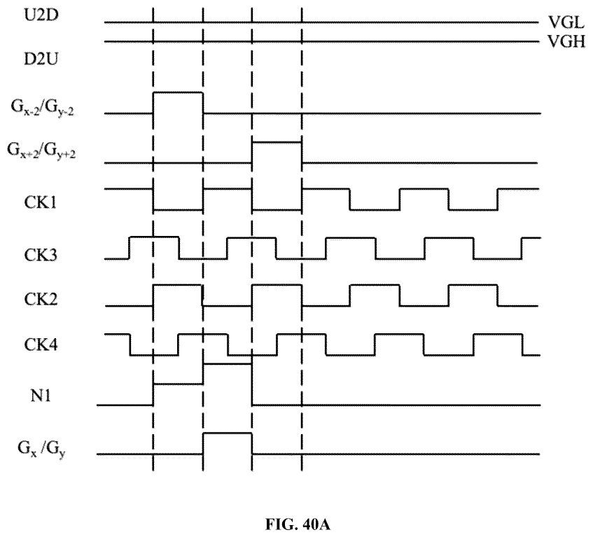

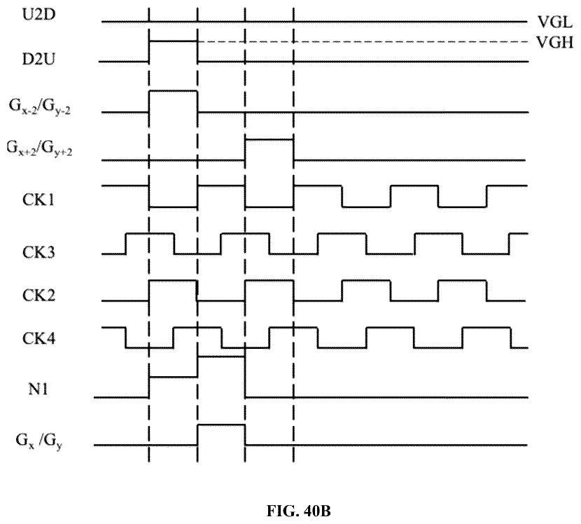

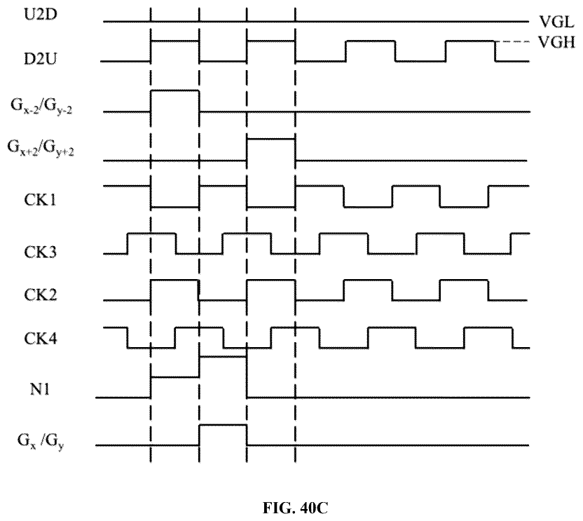

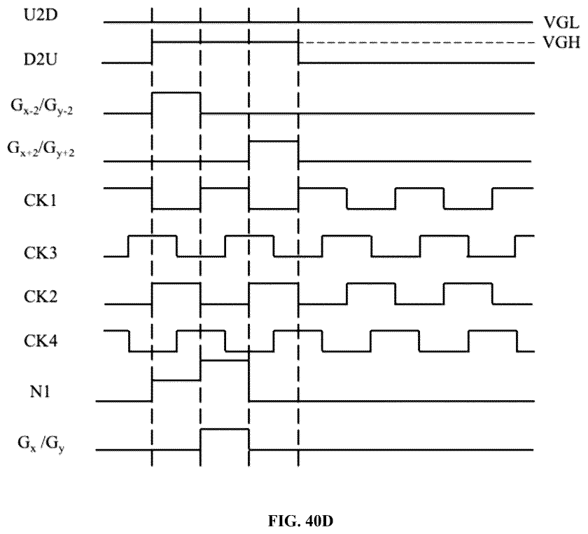

In some embodiments, the circuit configuration of the scanning drive circuit 120′ may be as shown in FIGS. 39A and 39B, and FIG. 40A illustrates signal waveform diagrams of the scanning drive circuit of FIGS. 39A and 39B, where FIG. 39A is a circuit configuration illustrating the scanning unit 121_x, and FIG. 39B is a circuit configuration illustrating the scanning unit 121_y.

Referring first to FIGS. 39A and 40A together, the scanning unit 121_x of this embodiment includes transistors M1-M7 and capacitors C1 and C2, wherein the transistors M1 and M2 may constitute the first module MD1 as described in FIG. 38, the transistors M3-M5 and capacitors C1 and C2 may constitute the second module MD2 as described in FIG. 38, and the transistors M6 and M7 may constitute the third module MD3 as described in FIG. 38. In other words, the first module MD1 of FIG. 38 may for example include transistors M1 and M2, the second module MD2 may for example include transistors M3-M5 and capacitances C1 and C2, and the third module MD3 may for example include transistors M6 and M7, although the present disclosure is not limited thereto.

In this embodiment, the transistors M1-M7 have a first end, a second end, and a control end, respectively, and the transistors M1-M7 may be, for example, N-type transistors or P-type transistors, the present disclosure not being limited thereto. If the transistor is an N-type transistor, the first end may for example be a drain, the second end may for example be a source, and the control end may for example be a gate; if the transistor is a P-type transistor, the first end may for example be a source, the second end may for example be a drain, and the control end may for example be a gate.

The first end of the transistor M1 is configured to receive the first scan control signal D2U, the second end of the transistor M1 is electrically connected to the node N1, and the control end of the transistor M1 is configured to receive the scan output ends Gₓ₋₂ of the scanning units of the previous two stages. The first end of the transistor M2 is electrically connected to the second end of the transistor M1, the second end of the transistor M2 is configured to receive the second scan control signal U2D, and the control end of the transistor M2 is configured to receive the scan output ends Gₓ₊₂ of the scanning units of the latter two stages.

The first end of the transistor M3 is electrically connected to the second end of the transistor M1 and the first end of the transistor M2 via the node N1, and the second end of the transistor M3 is configured to receive the clock signal CK1. The first end of the transistor M4 is electrically connected to the control end of the transistor M3, the second end of the transistor M4 is configured to receive the reference signal VSS, and the control end of the transistor M4 is electrically connected to the node N1. The reference signal VSS of this embodiment is taken as a reference low level as an example. The first end of the transistor M5 is electrically connected to the scan output end Gx of the scanning unit 121_x, the second end of the transistor M5 is configured to receive the clock signal CK1, and the control end of the transistor M5 is electrically connected to the first end of the transistor M3 and the node N1. The first end of the capacitor C1 is electrically connected to the control end of the transistor M3 and the first end of the transistor M4, and the second end of the capacitor C1 is configured to receive the clock signal CK1. The first end of the capacitor C2 is electrically connected to the first end of the transistor M5 and the scan output end Gx, and the second end of the capacitor C2 is electrically connected to the first end of the transistor M3, the control end of the transistor M5, and the node N1.

The first end of the transistor M6 is electrically connected to the scan output Gx, the second end of the transistor M6 is configured to receive the reference signal VSS, and the control end of the transistor M6 is electrically connected to the control end of the transistor M3, the first end of the transistor M4, and the first end of the capacitor C1. The first end of the transistor M7 is electrically connected to the first end of the transistor M6 and the scan output end Gx, the second end of the transistor M7 is configured to receive the reference signal VSS, and the control end of the transistor M7 is configured to receive the clock signal CK2.

Referring next to FIG. 39B, the scanning unit 121 y of this embodiment includes transistors M8-M14 configured similarly to transistors M1-M7 of the previously described embodiment of FIG. 39A, and capacitors C3 and C4 configured similarly to capacitors C1 and C2 of the previously described embodiment of FIG. 39A. The difference between this embodiment and the aforementioned embodiment of FIG. 39A is that the transistors M10-M12 mainly operate with reference to the clock signal CK3, and the transistor M14 operates with reference to the clock signal CK4, and the other connection relationships can be referred to the description of the aforementioned embodiment, and the detailed description thereof will not be repeated here.

FIG. 40A is a signal waveform diagram of the scanning drive circuit of FIGS. 39A and 39B. Referring first to FIG. 39A, FIG. 39B and FIG. 40A, in this embodiment, the first scan control signal D2U is stably maintained at the DC high level VGH, the second scan control signal U2D is stably maintained at the DC low level VGL, and the clock signals CK1, CK3, CK2 and CK4 are frequency signals sequentially delayed by a 90-degrees phase, and the duty ratio is about 0.5, although the present disclosure is not limited thereto.

Through the circuit configuration and signal input described above, the scanning unit 121_x may generate a scanning signal on the scan output Gₓ that is substantially 180 degrees behind the signal on the scan output end Gₓ₋₂ and substantially 180 degrees ahead of the signal on the scan output end Gₓ₊₂ to drive the corresponding odd scanning lines, and the scanning unit 121 y may generate a scanning signal on the scan output G_{y} that is substantially 180 degrees behind the signal on the scan output end G_{y-2} and substantially 180 degrees ahead of the signal on the scan output end G_{y+}2 to drive the corresponding even scanning lines.

However, since in the above-described driving architecture of FIGS. 39A and 39B, a DC voltage needs to be supplied to control the operation of the transistor, application of the DC voltage to the transistor for a long period of time easily shifts the characteristics of the transistor, thereby causing a problem in that the display panel exhibits an abnormality in a long-term use or in a burn-in test. For example, as seen in FIGS. 39A and 39B, the transistor M1/M8 continuously receives the DC voltage from the first scan control signal D2U during operation, and the current-voltage curve (I-V curve) of the transistor M1/M8 gradually shifts to the right as the operation time is extended, so that the leakage current of the transistor M1/M8 gradually increases, which causes display abnormality over time.

In addition, with the configuration of FIGS. 39A and 39B described above, at least seven or more signal lines must be provided on the display panel to provide control signals and clock signals (e.g., U2D, D2U, CK1-CK4, VSS, etc.) necessary for the operation of the scanning unit 121_x/121_y. This limits the non-display region size of the display panel, making narrow bezel designs difficult to implement. In order to be able to solve the above problems to effectively improve the quality of the display panel, extend the service life of the display panel under the GOP package architecture, and further realize the design of narrow bezel, the embodiments of the present disclosure propose an improved control method of the scanning drive circuit and a new circuit design.

Referring now to FIGS. 39A, 39B, and 40B, FIG. 40B illustrates a signal waveform diagram of a control method of the scanning drive circuit according to an embodiment of the present disclosure. The main difference between this embodiment and the control method of the previous embodiment of FIG. 40A is that the first scan control signal D2U of this embodiment is a pulse signal synchronized with the signal on the scan output ends Gₓ₋₂ of the first two stages of scanning units.

When controlled by the signal waveform as shown in FIG. 40B, the transistors M1/M8 are applied with the first scan control signal D2U at a high level in the first end only when the control end receives a signal at a high level; in addition, the first end of the transistors M1/M8 is maintained at a low level during the display period of one frame. With this control, the time during which the transistors M1/M8 are subjected to the direct current voltage can be greatly shortened, thereby making the transistors M1/M8 less susceptible to characteristic shift, so that the lifetime of the display panel can be further extended.

FIG. 39A, FIG. 39B, and FIG. 40C, wherein FIG. 40C illustrates a signal waveform of a control method of the scanning drive circuit according to another embodiment of the present disclosure. The main difference between this embodiment and the control method of the previously described embodiment of FIG. 40B is that the first scan control signal D2U is a pulse signal, here, for example, a pulse signal synchronized with the clock signal CK2.

Similarly, when controlled by the signal waveform as shown in FIG. 40C, the transistors M1/M8 receive the DC voltage for each frame only half of that of FIG. 40A (taking a pulse signal with a duty ratio of 0.5 as an example, although the present disclosure is not limited thereto), and thus the transistors M1/M8 are not affected by the high level of the DC voltage most of the time. It should be noted here that the first scan control signal D2U of this embodiment may also be a pulse signal which is not synchronized with the clock signal CK2, as long as it is a pulse signal which is maintained at a high level when the control end of the transistor M1/M8 receives a signal at a high level so that the transistor M1/M8 can operate normally.

Please then refer to FIG. 39A, FIG. 39B, and FIG. 40D in conjunction, wherein FIG. 40D illustrates a signal waveform of a control method of the scanning drive circuit according to another embodiment of the present disclosure. The main difference between this embodiment and the control method of the aforementioned FIG. 40B embodiment is that the first scan control signal D2U is a pulse signal partially overlapping the clock signal CK2 during one pulse. In this embodiment, the first scan control signal D2U transitions to a high level at substantially the same time as the signal at scan output end Gₓ₋₂/G_{y-2}, and transitions to a low level at substantially the same time as the signal at scan output Gₓ₊₂/G_{y+2} transitions to a low level. In other words, the pulse period of the first scan control signal D2U is about three times the pulse period of the signal on the scan output end Gₓ₋₂/G _{y-2}, although the present disclosure is not limited thereto.

Similarly, when controlled by the signal waveforms as shown in FIG. 40D, the transistors M1/M8 receive the direct current voltage for only the length of time during the three pulses of the clock signals CK1-CK4 in each frame, so that the transistors M1/M8 are not affected by the high level of the direct current voltage for most of the time.

In short, according to the above-described embodiment of FIG. 40B to FIG. 40D, as long as the level of the first scan control signal D2U received by the first end of the transistors M1/M8 changes at least once during each frame, the signal level is lowered from the high level to the low level. In addition, during a period when the signal received by the control end of the transistor M1/M8 is at a high level, the first scan control signal D2U received by the first end of the transistor M1/M8 is maintained at a high level as well, so that the above-mentioned reduction in the influence of the transistor M1/M8 on the direct current voltage for a long time can be achieved.

In some embodiments, the period during which the first scan control signal D2U is maintained at the high level for each frame period (i.e., the pulse period) does not exceed 30%. In some embodiments, the period during which the first scan control signal D2U is maintained at the high level for each frame period is 1%-10%. However, the present disclosure is not limited thereto.

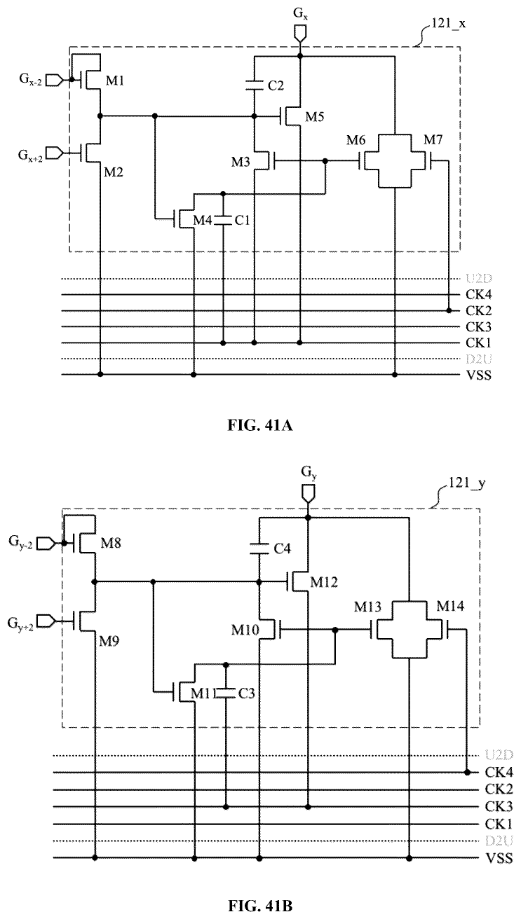

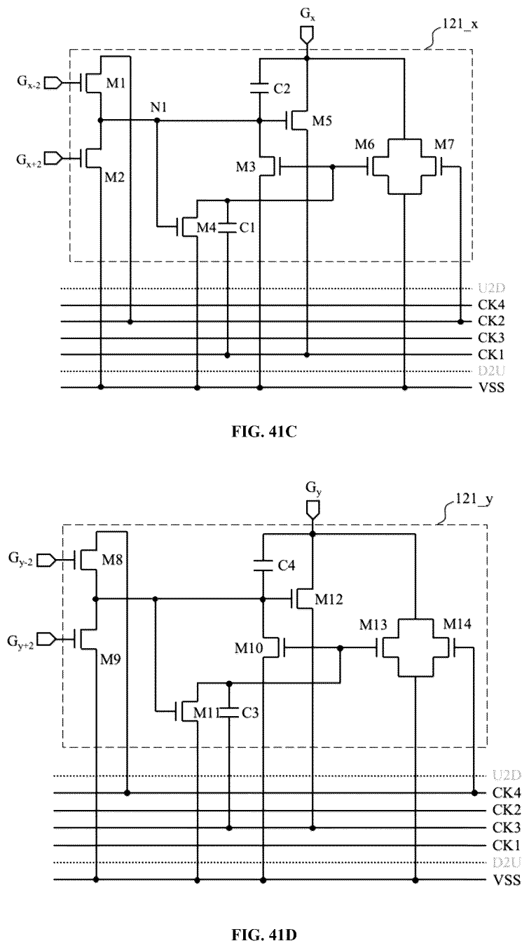

FIGS. 41A and 41B are circuit schematic diagrams of a scanning drive circuit, according to some embodiments of the disclosure, which may be used to implement the control method of FIG. 40B described above. Referring first to FIG. 41 A, the scanning unit 121_x of this embodiment includes transistors M1-M7 and capacitors C1 and C2, wherein the transistors M1 and M2 may constitute the first module MD1 as described in FIG. 41, the transistors M3-M5 and capacitors C1 and C2 may constitute the second module MD2 as described in FIG. 41, and the transistors M6 and M7 may constitute the third module MD3 as described in FIG. 41. In other words, the first module MD1 of FIG. 41 may for example include transistors M1 and M2, the second module MD2 may for example include transistors M3-M5 and capacitors C1 and C2, and the third module MD3 may for example include transistors M6 and M7. Although the present disclosure is not limited thereto.

In this embodiment, transistors M1-M7 are configured similarly to transistors M1-M7 of the previously described embodiment of FIG. 39A, and capacitors C1 and C2 are configured similarly to capacitors C1 and C2 of the previously described embodiment of FIG. 39A. Therefore, similar or identical parts can be referred to the above description of FIG. 39A, and a description thereof will not be repeated here.

The main difference between this embodiment and the previous embodiment of FIG. 39A is that the first end of transistor M1 is electrically connected to its control end to replace the original first scan control signal D2U with the scanning signals at the scan output ends Gx-2 of the first two stages. In addition, the second end of the transistor M2 is electrically connected to the signal line having the reference signal VSS for replacing the original second scan control signal U2D with the reference signal VSS.

From another perspective, the transistor M1 is equivalently formed as a diode element by the connection arrangement of FIG. 41A, so that when the control end of the transistor M1 is applied with a scanning signal at an enable level (e.g., high level), the transistor M1 can directly pass the enable level to its second end.

Referring next to FIG. 41B, the scanning unit 121_y of this embodiment includes transistors M8-M14 and capacitors C3 and C4, wherein the transistors M8 and M9 may constitute the first module MD1 as described in FIG. 38, the transistors M10-M12 and capacitors C3 and C4 may constitute the second module MD2 as described in FIG. 38, and the transistors M13 and M14 may constitute the third module MD3 as described in FIG. 38. In other words, the first module MD1 of FIG. 38 may for example include transistors M8 and M9, the second module MD2 may for example include transistors M10-M12 and capacitors C3 and C4, and the third module MD3 may for example include transistors M13 and M14. Although the present disclosure is not limited thereto.

In this embodiment, transistors M8-M14 are configured similarly to transistors M8-M14 of the previously described embodiment of FIG. 39B, and capacitors C3 and C4 are configured similarly to capacitors C3 and C4 of the previously described embodiment of FIG. 39B. Therefore, similar or identical parts can be referred to the above description of FIG. 39B, and a description thereof will not be repeated here.

Similar to the embodiment of FIG. 41A, the main difference between this embodiment and the previous embodiment of FIG. 39B is that the first end of transistor M8 is electrically connected to its control end to replace the original first scan control signal D2U with the scanning signal at scan output ends G_{y-2} of the first two stages. In addition, the second end of the transistor M9 is electrically connected to the signal line having the reference signal VSS for replacing the original second scan control signal U2D with the reference signal VSS. Viewed from another perspective, the transistor M8 is equivalently formed as a diode element by a connection arrangement such as that of FIG. 41B, so that when the control end of the transistor M8 is applied with a scanning signal at an enable level (e.g., high level), the transistor M8 can directly pass the enable level to its second end.

More specifically, as shown in FIG. 40A, since the first scan control signal D2U has a direct current high level, and the second scan control signal U2D has a direct current low level, the transistors M1/M8 can receive a DC high level on their first end as long as they are turned on (i.e., when the control end receives an enabled scanning signal), i.e., do not affect the operation of the transistors M1/M8; similarly, for the transistor M2/M9, electrically connecting its second end with the reference signal VSS has the same effect as connecting it with the second scan control signal U2D. Thus, by electrically connecting the first end of the transistor M1/M8 to its control end, to take the scanning signals of the scan output ends Gₓ₋₂/G_{y-2} of the first two stages as the first scan control signal D2U, and electrically connecting the second end of the transistor M2/M9 to the signal line transmitting the reference signal VSS can omit the signal lines transmitting the first scan control signal D2U and the second scan control signal U2D, thereby enabling the non-display region width of the display panel to be further reduced.

FIGS. 41C and 41D are circuit schematic diagrams of a scanning drive circuit according to further embodiments of the present disclosure, which may be used to implement the control method of FIG. 40C described above. Referring first to FIG. 41C, the scanning unit 121 x of this embodiment includes transistors M1-M7 and capacitors C1 and C2, wherein the transistors M1 and M2 may constitute the first module MD1 as described in FIG. 38, the transistors M3-M5 and capacitors C1 and C2 may constitute the second module MD2 as described in FIG. 38, and the transistors M6 and M7 may constitute the third module MD3 as described in FIG. 38. In other words, the first module MD1 of FIG. 38 may for example include transistors M1 and M2, the second module MD2 may for example include transistors M3-M5 and capacitors C1 and C2, and the third module MD3 may for example include transistors M6 and M7. Although the present disclosure is not limited thereto.

In this embodiment, transistors M1-M7 are configured similarly to transistors M1-M7 of the previously described FIG. 39A embodiment, and capacitors C1 and C2 are configured similarly to capacitors C1 and C2 of the previously described embodiment of FIG. 39A. Therefore, similar or identical parts can be referred to the above description of FIG. 39A, and a description thereof will not be repeated here.

The main difference between this embodiment and the aforementioned embodiment of FIG. 39A is that the first end of the transistor M1 is electrically connected to the signal line of the clock signal CK2 to replace the first scan control signal D2U which was originally at a DC high level with the clock signal CK2. In addition, the second end of the transistor M2 is electrically connected to the signal line having the reference signal VSS for replacing the original second scan control signal U2D with the reference signal VSS.

Referring next to FIG. 41D, the scanning unit 121_y of this embodiment includes transistors M8-M14 and capacitors C3 and C4, wherein the transistors M8 and M9 may constitute the first module MD1 as described in FIG. 38, the transistors M10-M12 and capacitors C3 and C4 may constitute the second module MD2 as described in FIG. 38, and the transistors M13 and M14 may constitute the third module MD3 as described in FIG. 38. In other words, the first module MD1 of FIG. 38 may for example include transistors M8 and M9, the second module MD2 may for example include transistors M10-M12 and capacitors C3 and C4, and the third module MD3 may for example include transistors M13 and M14. Although the present disclosure is not limited thereto.

In this embodiment, transistors M8-M14 are configured similarly to transistors M8-M14 of the previously described embodiment of FIG. 39B, and capacitances C3 and C4 are configured similarly to capacitances C3 and C4 of the previously described FIG. 39B embodiment. Therefore, similar or identical parts can be referred to the above description of FIG. 39B, and a description thereof will not be repeated here.

Similar to the embodiment of FIG. 41A, the main difference between this embodiment and the previous embodiment of FIG. 39B is that the first end of the transistor M8 is electrically connected to the signal line of the clock signal CK4 to replace the first scan control signal D2U which was originally at a DC high level with the clock signal CK4. In addition, the second end of the transistor M9 is electrically connected to the signal line having the reference signal VSS for replacing the original second scan control signal U2D with the reference signal VSS.

More specifically, with the above-described configuration, it is possible to apply a direct-current high level to the first end of the transistor M1/M8 by the clock signal CK2/CK4 when the transistor M1/M8 is turned on (i.e., when the control end receives an enabled scanning signal), i.e., without affecting the operation of the transistor M1/M8; similarly, for the transistor M2/M9, electrically connecting its second end with the reference signal VSS has the same effect as connecting it with the second scan control signal U2D. Thus, by electrically connecting the first end of the transistors M1/M8 to the signal line of the clock signal CK2/CK4, with the clock signals CK2/CK4 as the first scan control signal D2U and the second end of the transistors M2/M9 electrically connected to the signal line transmitting the reference signal VSS, the signal lines for transmitting the first scan control signal D2U and the second scan control signal U2D can be omitted, thereby enabling the non-display region width of the display panel to be further reduced.

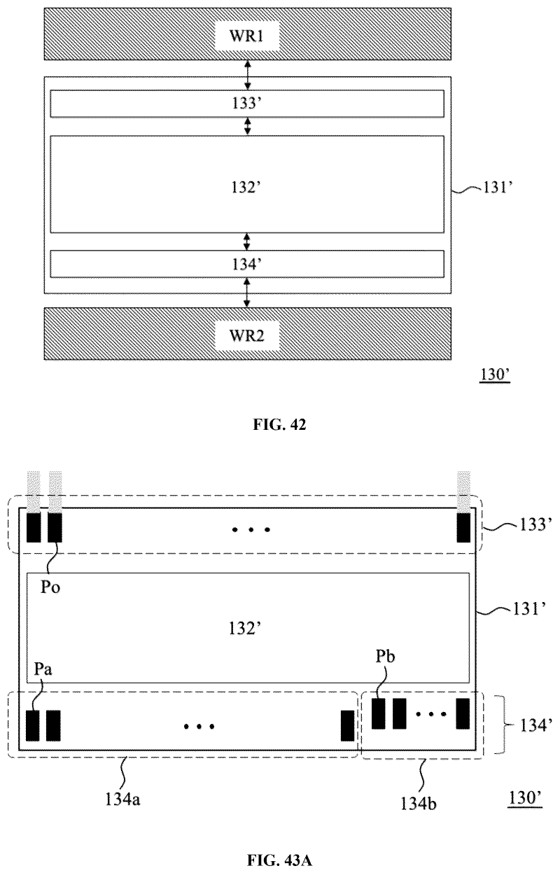

The configuration of the data drive circuit 130′ may be as shown in FIG. 42, which is a schematic diagram of a data drive circuit according to an embodiment of the present disclosure. Referring to FIG. 42, the data drive circuit 130′ of this embodiment includes a drive circuit board 131′, a functional part 132′, a first electric connection part 133′, and a second electric connection part 134′. The functional part 132′, the first electric connection part 133′ and the second electric connection part 134′ are all provided on a drive circuit board 131′, i.e. the drive circuit board 131′ may for example be a substrate of the data drive circuit 130′. The functional part 132′ is located between the first electric connection part 133′ and the second electric connection part 134′ and includes circuitry to implement the function of generating drive signal. The first electric connection part 133′ is coupled to the first transmission part WR1 and serves as a signal output interface of the functional part 132′ to transmit the drive signal generated by the functional part 132′ to the pixel array 112′ (as shown in FIG. 1D) through the first transmission part WR1. The second electric connection part 134′ is coupled to the second transmission part WR2 and serves as a signal input interface for the functional part 132′ to transmit data control signals on the second transmission part WR2 to specific circuits in the functional part 132′.

The first electric connection part 133′ and the second electric connection part 134′ may, for example, respectively include a plurality of connection terminals that can be connected to the transmission lines in the corresponding transmission parts WR1/WR2 to make electrical connection. In some embodiments, a bump press manufacturing process may be employed between the electric connection part 133′/134′ and the corresponding transmission part WR1/WR2 to realize electrical connection, and thus the plurality of connection terminals may be a plurality of bumps, although the present disclosure is not limited thereto.

From the connection configuration of the display panel 100′ and the data drive circuit 130′, in general, the non-display region SR of the display panel 100′ on the side where the data drive circuit 130′ is provided will have a larger width, which is mainly determined by the dimensions of the first transmission part WR1, the data drive circuit 130′, the second transmission part WR2, and the flexible circuit board 140′ (as shown in FIG. 1D), and also determines the bezel width of the display device 100. Here, the width of the bezel at the bottom of the display device 100 is substantially equal to the sum of the width of the transmission parts WR1 and WR2 on the substrate 111′ (as shown in FIG. 1D), the width of the data drive circuit 130′, and the width of the portion of the flexible circuit board 140′ attached to the substrate 111′. The width in this embodiment refers to the length on the y-axis.

In order to ensure reliability of signal transmission, the first transmission part WR1, the second transmission part WR2, and the connection terminals on the flexible circuit board 140′ all have specific specification requirements. For example, the connection terminals of the flexible circuit board 140′ attached to the substrate 111′ may be, for example, rectangular pads whose length and width ensure the reliability of the electrical signal transmission and also affect the bonding strength between the flexible circuit board 140′ and the substrate 111′. To shorten the length of the pads, in order to achieve the same/similar conductive properties, it is necessary to use a more conductive adhesive for the pads, which results in increased costs.

In addition, the length, width, and turning angle of the transmission line of the transmission part WR1/WR2 may have certain requirements depending on the size of the display panel 100′, the size and number of connection terminals, and the relative positions of the elements at both ends of the transmission part WR1/WR2 to ensure transmission reliability. For example, routing specifications for transmission lines prohibit lines from being routed at right or acute angles to avoid charge concentration effects at the tips of the traces from affecting signal transmission.

Furthermore, the size of the data drive circuit 130′ and the relative positional arrangement between the data drive circuit 130′ and the flexible circuit board 140′ also affect the routing and length of the second transmission part WR2. For example, since the width of the integrated data drive circuit 130′ will generally be less than the width of the flexible circuit board 140′, as a result, the lateral distance between the connection terminals near the edge (leftmost or rightmost) of the second electric connection part 134′ and the corresponding pads on the flexible circuit board 140′ is large, causing the transmission lines of the second transmission part WR2 to not be routed in the shortest path, and additional line segments are necessary to ensure that the routing is in compliance with specifications. The above situation is also one of the main reasons why the size of the second transmission part WR2 cannot be reduced.

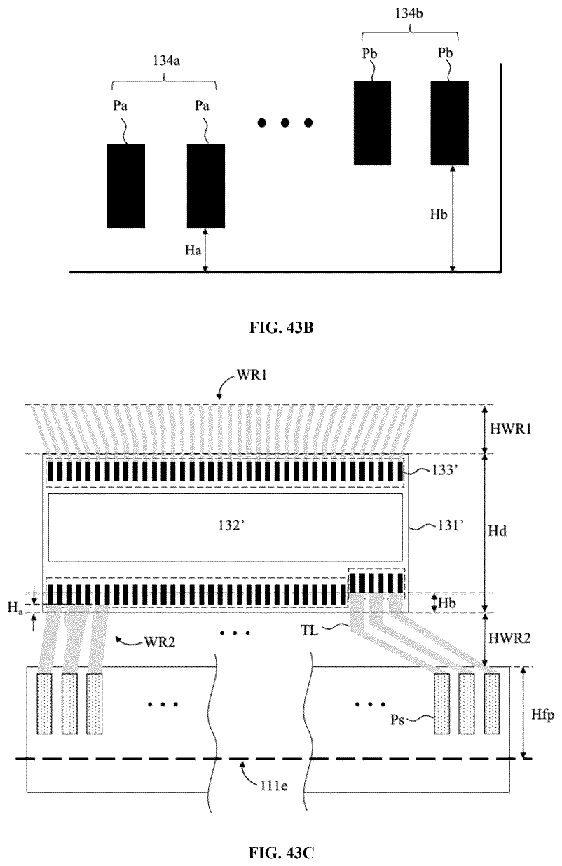

These limitations are responsible for the difficulty in achieving narrow bezel designs under COG package architectures. In order to be able to solve the above problem to realize a design of a narrow bezel under a COG package architecture, an embodiment of the present disclosure proposes a configuration of a data drive circuit 130′ as shown in FIGS. 43A to 43C, wherein FIGS. 43A to 43C are schematic diagrams of configurations of a data drive circuit according to an embodiment of the present disclosure.

Referring first to FIGS. 43A and 43B, in this embodiment, the first electric connection part 133′ of the data drive circuit 130′ includes a plurality of connection terminals Po, and the second electric connection part 134′ includes a first connection unit 134a and a second connection unit 134b, wherein the first connection unit 134a and the second connection unit 134b include a plurality of connection terminals Pa and Pb, respectively.

In the first electric connection part 133′, the plurality of connection terminals Po are arranged sequentially in the horizontal direction on the upper side of the drive circuit board 131′; in contrast, in the second electric connection part 134′, the connection terminals Pa and Pb in the first connection unit 134a and the second connection unit 134b are arranged sequentially in the horizontal direction on the lower side of the drive circuit board 131′. The connection terminal Pa in the first connection unit 134a and the connection terminal Pb in the second connection unit 134b are configured to have different distances (or distances from the substrate) from the edge of the drive circuit board 131′.

As shown in FIG. 43B, in this embodiment, the distance Ha between the connection terminal Pa and the edge of the drive circuit board 131′ is smaller than the distance Hb between the connection terminal Pb and the edge of the drive circuit board 131′, i.e., the connection terminal Pa in the first connection unit 134a is closer to the edge of the drive circuit board 131′ than the connection terminal Pb in the second connection unit 134b is. The distance described in this embodiment refers to the shortest distance from the side of the connection terminal Pa/Pb close to the edge of the drive circuit board 131′ to the edge of the drive circuit board 131′.

With the above arrangement, since the connection terminal Pb is retracted closer to the functional part 132′, the second transmission part WR2 can have a larger wiring space, so that the wiring length of the second transmission part WR2 on the substrate can be effectively shortened.

Specifically, the relative arrangement between the data drive circuit 130′ and the transmission lines of the first and second transmission parts WR1 and WR2 may be as shown in FIG. 43C, wherein the wiring width of the first transmission part WR1 on the substrate is HWR1, the width of the driver board 131′ is Hd, the wiring width of the second transmission part WR2 on the substrate is HWR2, and the width of the portion of the flexible circuit board 140′ attached to the substrate is Hfp, the sum of which defines the limit of the minimum bezel width.

Since the connection terminal Pb of the second connection unit 134b is correspondingly connected to the bonding pad Ps on the rightmost side of the flexible circuit board 140′, a certain distance (e.g., Hb +HWR2) needs to be guaranteed for the wiring therebetween in order to comply with the wiring specification. In this embodiment, since the second transmission part WR2 connecting the second connection unit 134b can form the transmission line TL with a region from the connection terminal Pb to the edge of the drive circuit board 131′ (i.e., a region of the distance Hb), the wiring width HWR2 caused by the transmission line TL on the substrate can be relatively shortened. In other words, since a partial line segment of the transmission line TL overlaps with a region of the drive circuit board 131′, a portion exposed outside the drive circuit board 131′ can be relatively reduced, thereby realizing reduction of the bezel width.

It should be noted herein that, although the drawings illustrate that the connection terminals Pa in the first connection unit 134a have the same/approximate distance Ha and the connection terminals Pb in the second connection unit 134b have the same/approximate distance Hb, although the present disclosure is not limited thereto. In some embodiments, part or all of the connection terminals Pa/Pb in the first connection unit 134a and the second connection unit 134b may also have different distances.

Furthermore, although only a single second connection unit 134b is depicted in the drawings and is located to the right of the first connection unit 134a, the present disclosure is not so limited. In some embodiments, the second connection unit 134b may be plural, and may be configured on the left side of the first connection unit 134a, or staggered with the first connection unit 134a.

In other words, all configurations, in which at least two connection terminals having different distances are included in the data drive circuit 130′, the connection terminals having a larger distance can provide a larger wiring space for the transmission line, thereby shortening the width of the line on the substrate, fall into the protection scope of the present disclosure. The following embodiments will further illustrate a number of different example configurations.

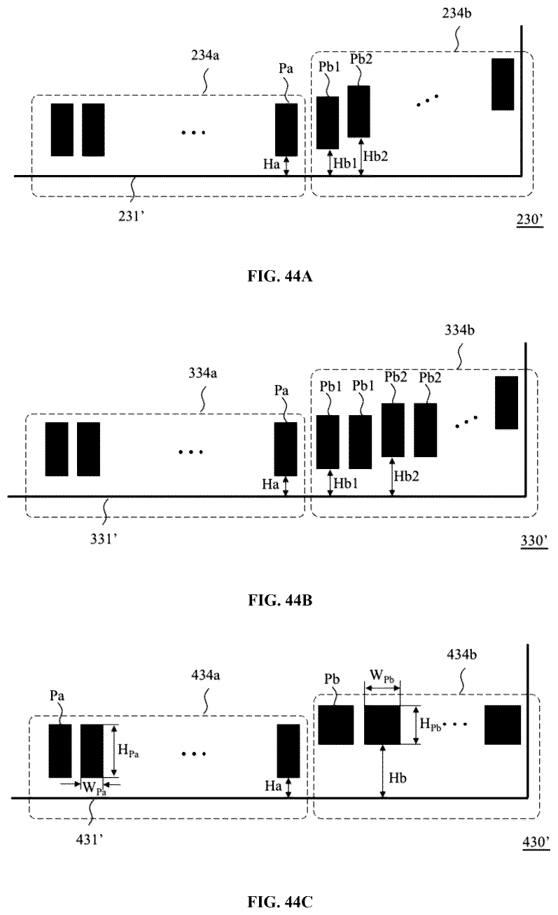

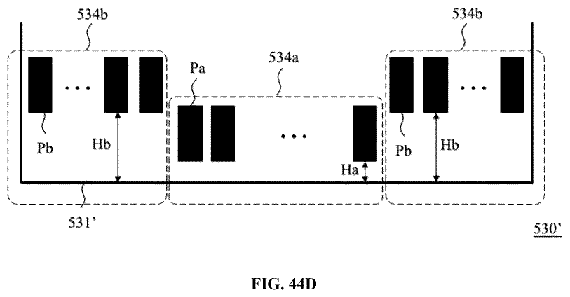

FIGS. 44A to 44D are partially enlarged schematic views of the electric connection part of the data drive circuit according to different embodiments of the present disclosure. Referring first to FIG. 44A, in this embodiment, the data drive circuit 230′ includes a drive circuit board 231′, a first connection unit 234a, and a second connection unit 234b. In the first connection unit 234a, the distance between the connection terminal Pa to the edge of the drive circuit board 231′ is Ha. In the second connection unit 234b, the distance between each connection terminal Pb to the edge of the drive circuit board 231′ is different, and sequentially increases from left to right. For example, the distance between the connection terminal Pb1 located on the right side of the connection terminal Pa and the edge of the drive circuit board 231′ is Hb1, where the distance Hb1 is greater than the distance Ha; the distance between the connection terminal Pb2 located on the right side of the connection terminal Pb1 and the edge of the drive circuit board 231′ is Hb2, wherein the distance Hb2 is greater than the distance Hb1. In other words, in this embodiment, the second connection unit 234b includes at least two connection terminals Pb1 and Pb2, and the distance Hb2 from the connection terminal Pb2 to the edge of the drive circuit board 231′ is greater than the distance Hb1 from the connection terminal Pb1 to the edge of the drive circuit board 231′.

Referring to FIG. 44B, in this embodiment, the data drive circuit 330′ includes a drive circuit board 331′, a first connection unit 334a, and a second connection unit 334b. This embodiment is substantially the same as the configuration of the aforementioned embodiment of FIG. 44A, with the only difference that in the second connection unit 334b, the connection terminals may be divided into a plurality of groups, in which connection terminals of different groups have different substrate distances, and connection terminals within the same group have the same substrate distance. As shown in FIG. 44B, the two connection terminals Pb1 are in the same group, and the two connection terminals Pb2 may be in another group, in which the substrate distance of the connection terminals Pb1 is Hb1, and the substrate distance of the connection terminals Pb2 is Hb2 that is larger than Hb1.

Referring to FIG. 44C, in this embodiment, the data drive circuit 430′ includes a drive circuit board 431′, a first connection unit 434a, and a second connection unit 434b. This embodiment is substantially the same as the configuration of the previously described embodiment of FIGS. 43A to 43C, and differs only in that the connection terminal Pa and the connection terminal Pb differ in their terminal sizes in addition to the substrate distance. For example, the connection terminals Pa and Pb of this embodiment may be rectangular bumps, wherein the length HPa of the connection terminal Pa would be greater than the length HPb of the connection terminal Pb, and the width WPa of the connection terminal Pa would be less than the width WPb of the connection terminal Pb. As such, in addition to increasing the substrate distance by retracting the position of the connection terminal Pb, it is also possible to further increase the substrate distance by reducing the bump length and simultaneously increasing the bump width to ensure that the conductivity is not affected.

In some embodiments, the connection terminal Pb may also achieve the effect of improving the substrate distance only by reducing the bump length. That is, the tip of the connection terminal Pb may be substantially aligned with the connection terminal Pa in this embodiment, but the length HPb of the connection terminal Pb is shorter to cause the substrate distance Hb to be larger than the substrate distance Ha.

Referring to FIG. 44D, in this embodiment, the data drive circuit 530′ includes a drive circuit board 531′, a first connection unit 534a, and a plurality of second connection units 534b. This embodiment is different from the previous embodiment in that the connection terminals at both left and right sides of the drive circuit board 531′ are configured as the connection terminals Pb of the second connection unit 534b, and the terminals at the middle region are configured as the connection terminals Pa of the first connection unit 534a. In other words, the substrate distance Hb of the connection terminals Pb on both left and right sides of the drive circuit board 531′ is larger than the substrate distance Ha of the connection terminals in the middle region. Thus, the problem that the connection terminals on the two sides of the data drive circuit 530′ have difficulty in wiring can be solved.

Although the above exemplifies possible example configurations in different embodiments, respectively, the present disclosure is not limited thereto. Other possible configurations can be directly and unambiguously understood by those skilled in the art upon reference to the above-described embodiments. For example, those skilled in the art will appreciate that the configurations of the embodiments of FIG. 44A and FIG. 44D may be combined such that the connection terminals Pb in each second connection unit 534b in FIG. 44D are sequentially arranged in the manner of FIG. 44A. For another example, those skilled in the art will appreciate that the configurations of the embodiments of FIGS. 44A and 44C may be combined so that the connection terminal Pb in the second connection unit 534b in FIG. 44A has a dimensional configuration as in FIG. 44C.

In other words, arrangements that would be understood and contemplated by one of ordinary skill in the art with reference to FIGS. 43A to 44D and the associated descriptions above are within the scope of the present disclosure disclosed and intended to be described herein.

In view of the above, according to the display device, the LED module and the manufacturing method thereof proposed by some embodiments of the present disclosure, the protective layer may be disposed to be higher than or equal to the upper electrode of the light-emitting element and form an opening structure. Under this configuration, the surface flatness of the LED module is determined by the protective layer, and thus is not affected by the LED size and process; secondly, the design of the opening structure can compensate for the problem that the height of each LED is different due to the size and the process, while also ensuring that the upper electrode lead can be electrically connected to the upper electrode of each LED through the opening, so that the upper electrode lead formed on the protective layer has a uniform line width, ensuring the electric signal transmission characteristic of each LED. According to the display device, the LED module and the manufacturing method thereof in other embodiments of the present disclosure, a force toward the substrate may be applied to the light-emitting elements during the manufacturing process so that light-emitting elements are displaced differently in response to the individual dimensions/heights and have different substrate distances, thereby causing the upper electrodes of the light-emitting elements to be kept in the same plane. In this configuration, the size differences of the individual LEDs are compensated by different distances from the substrate, which are not affected by the LED size and process, and therefore a flat module surface can be obtained. Thus, the upper electrode leads formed on the protective layer can each have a uniform line width, ensuring electric signal transmission characteristics of each LED. Because the upper surfaces of all the light-emitting elements can be maintained substantially at the same level without high-low differences, the subsequent manufacturing process is not affected by the flatness of the LED module, thereby effectively improving manufacturing process yield and confidence.

In addition, the quantum dot film proposed by the embodiments of the present disclosure can provide a preliminary water blocking effect through the support layer and the bonding layer, and can further block moisture from the active layer by using the waterproof layer covering the active layer, making the active layer less susceptible to moisture, greatly improving the reliability of the backlight module and the display. In addition, since the waterproof layer substantially increases the water resistance of the quantum dot film, more choices can be made in the design of the quantum dot film for the materials of the support layer and the bonding layer to meet design considerations while compromising cost requirements.

Further, in the light guide plate and the backlight module thereof proposed by some embodiments of the present disclosure, structural reinforcement of the light guide plate is achieved by forming a pillar-shaped support unit structure on the body part of the light guide plate. The cost of the overall backlight module can be effectively controlled since no additional stiffening plates need to be provided. Further, by configuring the first support unit and the second support unit having a height difference, it is possible to form a segment gap support on the light guide plate to achieve an optimized efficiency between the display effect and the structural protection.

Further, in the light guide plate and backlight module thereof proposed by some embodiments of the present disclosure, constituting the light guide plate by a standard module having a parallelogram structure can effectively reduce the directivity of the light source, so that the light can be more uniformly diffused over the entire light guide plate and the backlight module can obtain a more uniform surface light source. In addition, the light guide plate joined by the light guide units, even when pressed, can absorb the stress of the pressing through the adhering part without the risk of warping as in the conventional one-sided light guide plate. The risk of deformation of the light guide plate due to thermal expansion and moisture expansion can also be effectively reduced/eliminated. On the other hand, it is also possible to effectively simplify the manufacturing process of the light guide plate and reduce the manufacturing cost and cycle, as well as reduce the cost and expense of maintenance.

Further, in the light guide plate and the backlight module thereof proposed by some embodiments of the present disclosure, by providing the light guide plate with the curved surface structure, it is possible to make the light source in the central region more uniformly diffused to the peripheral region, and thus higher conversion efficiency of the light source can be achieved.

In addition, the display panel, the display device and the manufacturing method thereof proposed by the embodiments of the present disclosure preferably eliminate the visual impact of the splicing seam without visible splicing streaks or optical chromatic aberrations by making the distance between the light-emitting elements at the seam equal to the distance between the light-emitting elements within the panel by the structural configuration of the joint units. Furthermore, there is a significant advantage in terms of manufacturing costs, since there is no need to add additional components such as optical microstructures or light bars.

In addition, the display device and the data drive circuit thereof proposed by the embodiments of the present disclosure can solve the problem that the edge of the drive circuit has difficulty in wiring by increasing the wiring space of the transmission line through differential configuration of the connection terminals while achieving the effect of reduction in the width of the bezel. In addition, the quality of the display panel can be effectively increased and the lifetime of the display panel can be increased under the GOP package architecture.

Although the present disclosure has been disclosed with the above embodiments, however, it is not intended to limit the present disclosure, and any person skilled in the art may make various changes and modifications to the above-described embodiments without departing from the spirit and scope of the present disclosure. Accordingly, the scope of the present disclosure is defined by the appended claims.

1. A display device, comprising:
a display panel comprising a first substrate and a pixel array;
a scanning drive circuit disposed on the first substrate and electrically connected with the pixel array to generate a plurality of scanning signals to turn on the pixel array row by row, and
a data drive circuit disposed on the first substrate and electrically connected with the pixel array to provide a data drive signal in conjunction with the turn-on timing of the pixel array so that the display panel presents a corresponding image in response to the data drive signal,
wherein the scanning drive circuit comprises a plurality of stages of first scanning units for electrically connected with one of odd-numbered rows of scanning lines and even-numbered rows of scanning lines in the pixel array, and a plurality of stages of second scanning units for electrically connected with the other of the odd-numbered rows of scanning lines and the even-numbered rows of scanning lines in the pixel array,
wherein at least one of the plurality of first scanning unit comprises:
a first module for receiving scanning signals from the first two stages and the last two stages of the first scanning units and for generating a drive signal at a first node based thereon;
a second module electrically connected with the first module via the first node, and deciding a pull-up time point of a scanning signal on a scan output end based on the drive signal, a first clock signal, and a reference signal; and
a third module electrically connected with the second module and the scan output end, and deciding a pull-down time point of the scanning signal on the scan output end based on a second clock signal and the reference signal,
wherein the first module comprises a first transistor and a second transistor, the first transistor and the second transistor having a first end, a second end, and a control end, respectively,
wherein a signal received by the first end of the first transistor changes in level at least once during each frame, and the signal received by the first end of the first transistor is maintained at a high level during a period when a signal received by the control end of the first transistor is at a high level.

2. The display device according to claim 1, wherein the first end and the control end of the first transistor are electrically connected together to receive the scanning signals of the first two stages of the first scanning units.

3. The display device according to claim 1, wherein the data drive circuit is electrically connected to the pixel array by a first transmission part, and the display device further comprises:
a connecting module having one end disposed on the first substrate and electrically connected with the data drive circuit through a second transmission part; and
a control circuit coupled to the other end of the connecting module, and electrically connected to the data drive circuit through the connecting module and the second transmission part,
wherein the data drive circuit comprises:
a drive circuit board;
a functional part disposed on the drive circuit board;
a first electric connection part disposed on the drive circuit board and located at one side of the functional part, wherein the first electric connection part is electrically connected with the functional part and the first transmission part; and
a second electric connection part disposed on the drive circuit board and located at the other side of the functional part, wherein the second electric connection part is electrically connected with the functional part and the second transmission part,
wherein the second electric connection part comprises a first connection terminal and a second connection terminal, and a distance between the second connection terminal to an edge of the drive circuit board is greater than a distance between the first connection terminal to the edge of the drive circuit board.

4. The display device according to claim 1, wherein the first substrate has a display region and a non-display region surrounding the display region, and the display device further comprises:
a plurality of light-emitting elements arranged in an array arrangement within the display region of the first substrate, wherein adjacent ones of the light-emitting elements have a first distance therebetween and the non-display region is at least partially defined as a joint region; and
a joint unit disposed on the first substrate in the joint region to cover at least a portion of a sidewall of the first substrate, wherein the sidewall has a second distance from a nearest light-emitting element,
wherein a thickness of the joint unit on the sidewall of the first substrate plus the second distance is equal to a half of the first distance.

5. The display device according to claim 4, wherein the joint unit comprises:
an extended conducting layer electrically connected with a line layer of the first substrate, and covering a sidewall of the first substrate in the joint region, wherein the extended conducting layer has a first thickness on the sidewall of the first substrate; and
a sidewall protective layer covering at least a partial region of the extended conducting layer, wherein the sidewall protective layer has a second thickness on a sidewall of the extended conducting layer,
wherein a sum of the first thickness and the second thickness is equal to a thickness of the joint unit on the sidewall of the first substrate.

6. The display device according to claim 1, wherein the pixel array comprises a plurality of thin-film transistors arranged in an array, where at least one of the thin-film transistors comprises:
a gate;
an insulating layer formed on the gate;
an active layer formed on the insulating layer;
a source formed on one of two ends of the active layer; and
a drain formed on the other of the two ends of the active layer,
wherein the active layer comprises a first semiconductor material layer, a second semiconductor material layer, and a third semiconductor material layer that are sequentially stacked,
the first semiconductor material layer is formed on the insulating layer and has an ordered lattice structure; the second semiconductor material layer is formed on the first semiconductor material layer and has a disordered lattice structure; and the third semiconductor material layer is formed on the two sides of the second semiconductor material layer, has a disordered lattice structure and is doped with N-type ions.

7. The display device according to claim 6, wherein a semiconductor oxide is substantially absent at an interface between the first semiconductor material layer and the second semiconductor material layer.

8. The display device according to claim 6, wherein the first semiconductor material layer is doped with group 3A ions.

9. The display device according to claim 6, wherein a thickness ratio of the second semiconductor material layer to the third semiconductor material layer is between 5:8 and 8:5.

10. The display device according to claim 9, wherein a sum of the thicknesses of the second semiconductor material layer and the third semiconductor material layer is between 1000 Å and 1500 Å.

11. The display device according to claim 10, wherein the second semiconductor material layer has a thickness between 500 Å and 600 Å, and the third semiconductor material layer has a corresponding thickness such that the sum of the thicknesses of the second semiconductor material layer and the third semiconductor material layer is 1300 Å.

12. The display device according to claim 6, wherein the thin-film transistor is formed by the following steps:
forming, on the first substrate, a first metal layer and an insulating layer overlying the first metal layer;
forming an amorphous semiconductor thin film on the insulating layer;
performing a thermal treatment on the amorphous semiconductor thin film to allow the amorphous semiconductor thin film to be converted into the first semiconductor material layer;
forming the second semiconductor material layer and the third semiconductor material layer on the first semiconductor material layer to constitute the active layer;
performing a carrier removal process to the active layer to reduce the quantity of carriers at a sidewall of the active layer;
forming a second metal layer on the active layer; and
performing an etching process to expose the second semiconductor material layer at a channel region and dividing the second metal layer into the source and the drain.

13. The display device according to claim 12, wherein the step of carrier removal process comprises:
patterning the active layer to form the sidewall; and
over-etching the sidewall.

14. The display device according to claim 13, wherein the sidewall is a uniform plane continuously consisting of sides of the first semiconductor material layer, the second semiconductor material layer, and the third semiconductor material layer.

15. The display device according to claim 13, wherein a silicon oxide layer is formed on the sidewall by an oxidation process.

16. The display device according to claim 12, wherein the step of carrier removal process comprises:
patterning the active layer to form a sidewall; and
performing ion implantation to implant group 3A ions at the sidewall.

17. The display device according to claim 1, further comprising an LED module, wherein the LED module is manufactured by:
forming a first line layer on a second substrate;
disposing a plurality of light-emitting elements on the first line layer by an adhering part so that a first electrode of each of the light-emitting elements is electrically connected to the first line layer;
forming a protective layer on the second substrate to cover the plurality of light-emitting elements, wherein a thickness of the protective layer is greater than or equal to a height of the plurality of light-emitting elements;
removing the protective layer covering a second electrode of each of the light-emitting elements to form an opening between each of the plurality of light-emitting elements and the protective layer; and
forming a second line layer on the protective layer, wherein the second line layer is electrically connected to the second electrode of each of the light-emitting elements through the opening.

18. The display device according to claim 1, further comprising an LED module, wherein the LED module is manufactured by:
forming a first line layer on a second substrate;
disposing a plurality of light-emitting elements on the first line layer by an adhering part so that a first electrode of each light-emitting element is electrically connected to the first line layer;
applying a force to the plurality of light-emitting elements toward the second substrate to embed at least a portion of the light-emitting element into the adhering part; filling an insulating material to gaps between the light-emitting elements to form a protective layer; and
forming a second line layer over the protective layer so that the second electrode of each of the plurality of light-emitting elements is electrically connected to the second line layer.

19. The display device according to claim 1, further comprising:
a backlight module to provide a light source toward the display panel, wherein the backlight module comprises a light-emitting layer and an optical adjustment layer located on a light transmission path of the light-emitting layer, the light-emitting layer comprises a plurality of light-emitting elements arranged in an array, and the optical adjustment layer is configured to adjust a direction of received light.

20. The display device according to claim 19, wherein the backlight module further comprises a quantum dot film, wherein the quantum dot film comprises:
an active layer comprising a plurality of quantum dots configured to excite light having a second wavelength based on the received light having a first wavelength;
a support layer configured to carry the active layer;
a bonding layer disposed between the active layer and the support layer for providing a bonding force between the active layer and the support layer such that the active layer is disposed on the support layer through the bonding layer; and
a waterproof layer directly or indirectly covering at least part of the surface of the active layer.

21. The display device according to claim 19, wherein the optical adjustment layer comprises:
a light guide plate comprising an incident surface, a first surface, and a second surface, wherein,
the first surface is substantially perpendicular to the incident surface and serves as an exit surface of the light guide plate, wherein the first surface has a gloss level less than 1; and
the second surface is located on the opposite side of the first surface, wherein the second surface has a gloss level greater than 95.

22. The display device according to claim 19, wherein the optical adjustment layer comprises:
a light guide plate comprising an incident surface, a first surface, and a second surface, wherein,
the first surface is substantially perpendicular to the incident surface and serves as an exit surface of the light guide plate;
the second surface is located on the opposite side of the first surface, wherein the second surface has a gloss level greater than 95; and
a plurality of side surfaces non-parallel to the first surface and connected to the first surface and the second surface, wherein at least one of the plurality of side surfaces has a gloss level greater than 95.

23. The display device according to claim 22, wherein a plurality of reflective film structures are formed on the incident surface, the plurality of reflective film structures being arranged at regular intervals, in which each of the reflective film structures has a gloss level greater than 95.

24. The display device according to claim 19, wherein the optical adjustment layer comprises a light guide plate, and the light guide plate comprises:
a body part having the first surface and the second surface; and
a reinforcing part formed on at least one of the first surface and the second surface, and comprising a plurality of support units having a columnar shape, wherein the plurality of support units have a light transmitting property, have an elastic recovery rate of 95 or more, and are sequentially arranged on the body part,
wherein the plurality of support units comprise at least one support unit formed at a central region of the body part, and support units respectively formed at four corners of the body part.

25. The display device according to claim 24, wherein the plurality of support units comprises a first support unit having a first height and a second support unit having a second height, the first height being greater than the second height.

26. The display device according to claim 19, wherein the optical adjustment layer comprises a light guide plate, and the light guide plate comprising:
a body part comprising a plurality of light guide units having a parallelogram configuration, wherein adjacent ones of the light guide units are mutually adhered and secured together by an adhering part such that the plurality of light guide units that are mutually adhered form a substantially continuous first surface and the second surface opposite to the first surface.

27. The display device according to claim 26, wherein at least part of the plurality of light guide units has a rhombic structure and at least another part has a triangular structure.
